(19) United States
(12) Patent Application Publication
(10) Pub. No.: US 2026/0063700 A1
(43) Pub. Date: Mar. 5, 2026

(54) METHODS FOR DETERMINING REMAINING USEFUL LIFE IN ELECTRONIC DEVICES AND SYSTEMS (RULAS)

(71) Applicant: Nokomis, Inc., Canonsburg, PA (US)

(72) Inventors: Walter J. Keller, III, Bridgeville, PA (US); Kenneth H. Munson, Jr., Murrysville, PA (US)

(73) Assignee: Nokomis, Inc., Canonsburg, PA (US)

(21) Appl. No.: 18/797,127

(22) Filed: Aug. 7, 2024

Related U.S. Application Data
(60) Provisional application No. 63/531,361, filed on Aug. 8, 2023.
(60) Provisional application No. 63/630,846, filed on Mar. 8, 2024.

(51) Int. Cl. G01R 31/26

(52) U.S. Cl. CPC G01R 31/2642; G01R 31/2621

(57) ABSTRACT

Specific algorithmic methods are disclosed herein whereby the accumulated degradation or Remaining Useful Life (RUL) of an electrical semiconductor-based device or subsystem may be determined based on examining unintended RF emissions from the device or a subsystem while it is operating on a periodic, sporadic, or one-time basis. The methods may be then preferably combined to provide an accurate assessment and prediction of degree of its degradation or RUL. These assessments or predictions may be practical for more accurately allocating maintenance or replacement practices, especially for safety-critical systems. These assessments or predictions may be presented in an understandable, useful, comprehensive, more definitive, more detailed, or alternatively simpler format depending on the user's needs.

### CROSS-REFERENCE TO RELATED APPLICATIONS

This non-provisional application claims the benefit of priority, under 35 U.S.C. sctn. 119(c), to a U.S. Provisional patent application Ser. No. 63/630,846 filed on Mar. 8, 2024 and titled “METHODS FOR DETERMINING REMAINING USEFUL LIFE IN ELECTRICAL DEVICES AND SYSTEMS (RULAS)” and to a U.S. Provisional patent application Ser. No. 63/531,361 filed on Aug. 8, 2023 and titled “METHOD FOR ASSESSING CONDITION OF A STRESSED ELECTRONIC DEVICE”, each is hereby incorporated by reference in its entirety. This document incorporates by reference the disclosures and/or teachings of the following documents in their entirety: U.S. Pat. No. 7,515,094 entitled “ADVANCED ELECTROMAGNETIC LOCATION OF ELECTRICAL EQUIPMENT”, U.S. Pat. No. 8,063,813 entitled “ACTIVE IMPROVISED EXPLOSIVE DEVICE (IED) ELECTRICAL SIGNATURE DETECTION”, U.S. Pat. No. 8,537,050 entitled “IDENTIFICATION AND ANALYSIS OF SOURCE EMISSIONS THROUGH HARMONIC PHASE COMPARISON”, U.S. Pat. No. 8,643,539 entitled “ADVANCE MANUFACTURING MONITORING AND DIAGNOSTIC TOOL”, U.S. Pat. No. 9,059,189 entitled “INTEGRATED CIRCUIT WITH ELECTROMAGNETIC ENERGY ANOMALY DETECTION AND PROCESSING”, U.S. Pat. No. 9,642,014 entitled “ACTIVE DETECTION OF DEVICE ANOMALIES FOR PHYSICAL CYBER SECURITY”, U.S. Pat. No. 9,772,363 entitled “AUTOMATED ANALYSIS OF RF EFFECTS ON ELECTRICAL DEVICES THROUGH THE USE OF DEVICE UNINTENDED EMISSIONS”, U.S. Pat. No. 9,851,386 entitled “METHOD AND APPARATUS FOR DETECTION AND IDENTIFICATION OF COUNTERFEIT AND SUBSTANDARD ELECTRONICS”, U.S. Pat. No. 10,235,523 entitled “AVIONICS PROTECTION APPARATUS AND METHOD”, U.S. Pat. No. 10,395,032 entitled “DETECTION OF MALICIOUS SOFTWARE, FIRMWARE, IP CORES AND CIRCUITRY VIA UNINTENDED EMISSIONS”, U.S. Pat. No. 10,475,754 entitled “SYSTEM AND METHOD FOR PHYSICALLY DETECTING COUNTERFEIT ELECTRONICS”, U.S. Pat. No. 11,029,347 entitled “ELECTRONICS EQUIPMENT TESTING APPARATUS AND METHOD UTILIZING UNINTENDED RF EMISSION FEATURES”, U.S. Pat. No. 11,069,952 entitled ELECTRONICS INSITU TESTING APPARATUS AND METHOD UTILIZING UNINTENDED RF EMISSIONS FEATURES”, US. Pub. No. 2022/0099734 entitled “TESTING OF MICROELECTRONICS DEVICE AND METHOD”.

### STATEMENT REGARDING FEDERALLY SPONSORED RESEARCH AND DEVELOPMENT

This invention was made with Government support under Contract No. FA864922P0621 awarded by the U.S. Air Force. The Government has certain rights in the invention.

### TECHNICAL FIELD

The subject matter relates, in general, to degradation of electrical device. The subject matter may relate to determining a degree of degradation of the electrical device. The subject matter may relate to determining degree of aging of the electrical devices. The subject matter may relate to determining a remaining useful life (RUL) of the electrical device. The subject matter may relate to determining RUL by capturing electromagnetic energy emitted from the electrical device.

### BRIEF DESCRIPTION OF DRAWINGS

The accompanying drawings are incorporated in and constitute part of the specification and illustrate various embodiments. In the drawings:

FIG. 1 illustrates unintended emission features which may be used to determine degree of degradation or a remaining useful life (RUL) of a device;

FIG. 2 illustrates RUL bathtub curve;

FIG. 3 illustrates an example chart of observed metric related to degradation predictions vs. amount of cumulative time under degradation environment;

FIG. 4 illustrates devices inside a typical programmable logic control (PLC) which may emit useful unintended emissions to determine PLC or individual devices degradation or aging amount;

FIG. 5 illustrates an example heat map generated based on observed metric related to degradation predictions vs. amount of cumulative time under degradation environment;

FIG. 6 illustrates a more detailed and specific example heat map generated based on a specific observed metric related to degradation predictions vs. amount of cumulative time under degradation environment versus an abstracted emission spectrum artifact named measured value;

FIG. 7A illustrates exemplary elements within a RUL graphical user interface display that may be also have been used for RUL calculation;

FIG. 7B illustrates an exemplary resulting RUL graphical user interface (GUI) display;

FIG. 8 illustrates a failure probability heat map display and its meaning generated by employing the 2-D kernel method;

FIG. 9 illustrates an exemplary software architecture block diagram method of generating RUL from radio frequency (RF) emission features;

FIG. 10 illustrates a section of exemplar RF emission spectrum data points gathered from two separate devices which may be used to generate or inform a RUL system such as the one shown in FIG. 9 software architecture;

FIG. 11 illustrates a possible table or multi-variate matrix of a number of data variable values abstracted from raw RF emissions gathered from devices, sub-assemblies, or systems from which RUL estimates may be generated;

FIG. 12A illustrates an exemplary frequency domain versus dBm amplitude of a substantially perfect square wave versus a degraded square wave;

FIG. 12B illustrates a time domain vs. Volts amplitude of a substantially perfect square wave vs. a degraded square wave;

FIG. 13A illustrates an exemplary numerical table of center frequency peaks and modulation frequencies associated with cross-modulation peaks as a part is aged;

FIG. 13B illustrates a frequency domain vs. amplitude spectrum of a part aged 35 hours as seen in table of FIG. 13A;

FIG. 13C illustrates a frequency domain versus amplitude spectrum of a part aged 12 hours as seen in table of FIG. 13A;

FIG. 14A illustrates an exemplary numerical table of center frequency peaks and associated metrics which may be used to determine aging;

FIG. 14B illustrates an exemplary spectrum of a part aged 31 hours with particular emphasis on the area under the peak curve;

FIG. 14C illustrate an exemplary spectrum of a part aged 0 hours with particular emphasis on the area under the peak curve for visual comparison purposes;

FIG. 15A illustrates exemplary changes in narrowband frequency region spectrum features observed at different part ages;

FIG. 15B illustrates exemplary changes in narrowband frequency region spectrum features observed at different part ages from which the narrowband regions are presented;

FIG. 16A illustrates exemplary spectrum features observed at 6 weeks;

FIG. 16B illustrates exemplary spectrum features observed at 10 weeks;

FIG. 16C illustrates exemplary spectrum features observed at 0 weeks;

FIG. 16D illustrates exemplary spectrum features observed at 3 weeks;

FIG. 17 illustrates and compares possible specific rf spectrum emission features from two devices of the same model which may be aggregated to inform an RUL estimate;

FIG. 18A illustrates power vs. probability distribution for an exemplary part's specifically chosen metric and specific metric value;

FIG. 18B illustrates spectrum content from which the characteristics of FIG. 18A are derived;

FIG. 19 illustrates an exemplary method of updating the Accumulated devices Data database with a new or a recent data automatically or by user discretion;

FIG. 20 illustrates a typical method of actions performed when a new device or batch of devices is to be processed by the subject matter;

FIG. 21 illustrates a 3-D Sparse Matrix of RUL-related values which may be updated and used to accumulate RUL-Related statistics of a batch of devices. A higher dimensional Sparse Matrix of 4-D, 5-D, 6-D or more dimensions is contemplated herein but impractical to illustrate. A device's dimensions may be RUL-related variable data such as illustrated in the columns of FIG. 11 which contains 8 separate values which may be applied as dimensions in a Sparse Matrix of RUL-related values, for example; and

FIG. 22 illustrates a simpler 2-D Sparse Matrix of RUL-related values for conceptual purposes but is less likely to be implemented than higher dimensional Metrics.

### DESCRIPTION OF FIGURE ELEMENTS

100—an example spectrum (Frequency vs. dBm) of unintended emission features useful in determining device condition and RUL.
110—emission feature structure shape area which may change as device condition changes such as device ages or degrades. Change may include broadening, narrowing, skewness change, kurtosis change, height vs. width change, height change, frequency location change, frequency location relative to other features changing, height relative to other featured changing, shape changing, etc.
120—spectral peak feature whose shape, location and/or height may change as device degrades or ages.
122—visibly complex spectral peak feature whose shape, location and/or height may change as device degrades or ages. This is illustrated in the figure as an often-occurring side peak to a higher central peak and device of a pair of peaks approximately equidistant in frequency from a higher central peak. The corresponding peak of the pair is seen at 124 on the other side of the central peak. Typically, a peak pair also have a similar peak height and shape.
124—visibly complex spectral peak feature whose shape, location and/or height may change as device degrades or ages. This is illustrated in the figure as an often-occurring side peak to a higher central peak and device of a pair of peaks approximately equidistant in frequency from a higher central peak. The corresponding peak of the pair is seen at 122 on the other side of the central peak. Typically, a peak pair also have a similar peak height.
128—a smaller dB height visibly complex spectral peak feature whose shape, location and/or height may change as device degrades or ages. This is illustrated in the figure as an often-occurring side peak and further in Hz to a higher central peak 120 and device of a pair of peaks approximately equidistant in frequency from a higher central peak. The corresponding peak of the pair is seen at 129 on the other side of the central peak. It is further in Hz from the highest central peak 120 than peak 122 and typically lower in dBm than 122 and can be seen as a group of exemplary related peaks comprising 128, 122, 120, 124, and 129, all which may arise from an operating device's unintended RF emissions.
129—a smaller dBm visibly complex spectral peak feature whose shape, location and/or height may change as device degrades or ages. This is illustrated in the figure as an often-occurring side peak and further in Hz to a higher central peak 120 and device of a pair of peaks approximately equidistant in frequency from a higher central peak. The corresponding peak of the pair is seen at 128 on the other side of the central peak and higher in frequency than all other specified peaks. It is further in Hz from the highest central peak 120 than peak 124 and typically lower in dBm than 124 and can be seen as a group of exemplary related peaks comprising 128, 122, 120, 124, and 129, all which may arise from an operating device's unintended RF emissions.
130—peak separation frequency difference between a peak pair approximately equidistant from a central peak and whose location or separation distance, height, or shape may change as device degrades or ages.
140—noise floor line, above which total spectrum feature area may be integrated to determine a metric which may change as device degrades or ages.
200—Bathtub curve of typical device degradation over a device lifetime of use
210—Y-axis of probability or quantity of devices failing.
220—X-axis of time past within device operation lifetime.
230—High infant mortality region of bathtub curve.
240—Useful life region of bathtub curve wherein relatively fewer failures may occur.
250—Wear-out life region of bathtub curve wherein failures increasingly occur towards end of life.
300—Exemplary curve of one or multiple abstracted RF emission metric values vs. device lifetime values derived from real-world devices results.
310—Y-axis abstracted RF emission metric value or values results used to predict RUL or estimate a device's accumulated operational lifetime.
320—X-axis exemplary device's time in operation.
330—Device metrics data points derived from a single device taken at a specific frequency multiple times or of multiple separate devices device taken at a specific frequency multiple times or for only one sample.
400—signature content present 400 in the PLC.
410—a sub-content directed to a microcontroller.
420—a sub-content directed to switching power supplies.
430—a sub-content directed to solid state and manual relays.
440—a sub-content directed to non-volatile random access memory (RAM).
450—a sub-content directed to communication.
460—a sub-content 460 directed to display screen.
500—Heat map derived from data points.
510—Y-Axis abstracted RF emission metric values results used to predict RUL or estimate a device's accumulated operational lifetime.
520—X-axis exemplary device's time in operation.
550—Outlier region acquired from a small subset of devices' behavior which may occasionally occur. It may be considered a lower ‘probability density region’ and may be caused by differing device manufacturer lots or a change in manufacturing parameters maintaining and within the devices' operational functional specification parameters but differing from other samples results generally. As an example, a device specification may state that the device operates while drawing between 10 ma and 20 ma of current. The majority of devices may be manufactured with process settings and materials resulting in 90% of the devices drawing 17 ma, well within the specifications. This may result in their specific current draw characteristic being seen in a specific pattern of emissions data and a specific pattern region in the resulting heatmap. A small batch of devices may be made from materials or process settings which result in 90% of the devices only drawing 13 ma. This in turn may result in their differing specific current draw characteristic being seen in a differing specific pattern of emissions data and a differing specific pattern region in the resulting heatmap. Both groups of devices function within manufacturer's specification but may show slightly differing operational results and differing resulting emission spectra causing an outlying group in a heatmap. Note that any devices outside the manufacturer's specifications would typically be rejected at the factory during testing and not be sold or available, thus not contributing to the heatmap. The capability of discerning differing operational characteristics from emissions data may be used to select more desirable devices from a batch of candidate devices to be used in a system to achieve better operational results. Such a device may be embedded deeply within a PCB board, subsystem or system and the device's characteristics may not be directly measurable. Thus, this may be an optimal method of further evaluating the economic value of a new or used device, PCB board, sub-system or system. This evaluation may subsequently result in a buy/no-buy decision or a differing price valuation by the seller or buyer. This evaluation may subsequently result in an accurate assessment that the device will last longer or remain in service longer than most of the other candidate devices and may be a key valuable factor in selecting that device as comprising device of a deployed system using that device, especially for high value application requirements such as public safety, spacecraft, satellites, or military systems. The prediction of reliability of a system may save costs, size, weight, and volume by reducing the need or implementation of redundancy as a means to ensure high probability of operation. Thus, the RUL determining system may not only screen out undesirable, worn-out, or old devices, but may screen out the better, suitable, or best devices for selection. The best device outliers are likely to be rarer than the average devices. The worst devices are also likely to be rarer than the average devices.
560—Regions of occurrences. The heat map (effectively of predicted ‘Z-axis’ values) wherein ‘Z-axis’ values represented as grey or colored regions of varied intensity may be probability, number of devices, actual measured results of number of devices or predicted number of devices, or all of these.
570—Regions illustrating higher probability density or higher ‘Z-axis’ occurrences of metric value vs. hour.
580—Regions of very high or highest ‘Z-axis’ occurrences.
600—Heat map of spectral feature observed of a device vs. time (years of degradation) vs. predicted occurrences. Heat map contains isolines or contour lines for enhanced clarity of value increments of predicted occurrences.
602—Y-axis value which may be total power in some applications. This may be total emission spectrum power received for one or more spectral features above the noise floor received within a frequency region.

Alternatively, in other application instances for other devices it may be used to represent accumulated total power such as total watt hours used by device, it may be peak total power applied before failure, it may be the sum of power applied to a device's power pins if multiple pins exist, or it may simply be continuous power applied to a device. It may be voltage value continuously applied, current value continuously drawn by device at an applied voltage value, or wattage value (current*volts) applied continuously to device under test within testing regimen or known to have been applied to a point in time while device was in use and/or in place functionally. This value may be known by applying a known voltage, current or wattage while under test, measured by outgoing heat or electrical energy resulting from device, measured by removing device from service and measuring power draw from device afterwards, measuring voltage applied to device while in service and then removing device and applying same voltage and measuring current draw at that voltage, or similar or other related power measurement means. It may also represent non-electrical power applied such as mechanical power applied such as mechanical resistance on a motor of a motor controller circuit under test. It may be vibrational power applied to a device, or heat power applied to a device. It may be light, infrared, or other electromagnetic power applied to a device.

Alternatively, in yet other application instances for other devices it may be used to represent Y-Axis emission spectrum artifact measured value. It may be a significant specific peak location indicative of RUL, a specific peak frequency pair separation measurement, an absolute peak height in dBm, a relative peak height in dB relative to another spectral feature such as noise floor level, a total area under a peak curve, or one or more combined other RUL related measurements detailed herein.
604—region of little or no occurrences of results measured and/or thus of low probability of occurrence.
606—Predicted or observed Y-Axis device number of occurrences or probability of occurrence at a specific X-axis, Y-axis coordinate region.
608—isoline more clearly designating spectrum occurrence region values, separating, or defining contours of points of same occurrence value.
610—X-axis time value, may be actual time device has undergone operation and thus degradation or calculated accelerated aging time device has experienced. It may in any unit of time measurement including milliseconds, seconds, minutes, days, years, hours, or etc.
620—Region of low or few results measured and/or thus of low probability of occurrence.
630—Region of high or many results measured and/or thus of high probability of occurrence.
640—Occurrences=42, or may be 0.42% probability for a region for example in other applications of RUL processing.
700—Conceptual design for features which may be shown in a useful RUL Graphical User interface. Also, it illustrates useful features which may be used in determining RUL
710—group of various displayable select spectral elements of RUL significance used to calculate RUL and which may be selected to comprise and to appear as useful information on a RUL GUI screen, possibly along with associated text information accompanying, explaining, informing, and related to spectral elements.
720—individual displayable select spectral elements of RUL significance used to calculate RUL, they may be related in a time sequence of the same frequency region, may be related harmonically, may be related by association with a device within a sub-system, PCB, or system, or may separate specific regions of significance found to influence and calculate RUL for a device.
730—a region of significance for RUL calculation which may be displayed, along with associated details such as frequency, RBW, and/or other displayable RUL-artifact-metrics (RULam). This region may point to a single narrow peak of significance which only has 3 relevant factors-frequency, dB or dBm height, and RBW under which the peak was acquired.
740—a region of significance for RUL calculation which may be displayed, along with associated details such as frequency, RBW, and/or other displayable RUL-artifact-metrics (RULam). This region may contain several interrelated peaks within the same frequency region of significance upon which RULam is calculated and displayed.
742—a region of significance for RUL calculation which may be displayed, along with associated details such as frequency, RBW, and/or other displayable RUL-artifact-metrics (RULam). This region may contain several interrelated peaks within differing frequency regions of significance upon which RULam is calculated and displayed and/or be taken at differing RBWs, differing environmental factors such as differing temperatures, differing input voltage levels, different operational states such as standby or active, differing clock bias levels, or differing clock input P-P voltage levels.
744—a region of significance for RUL calculation which may be displayed, along with associated details such as frequency, RBW, and/or other displayable RUL-artifact-metrics (RULam). This region may contain a complex and/or broad peak structure with associated frequency, RBW, area under the curve, shape, kurtosis, skewness, and/or other measurable or derived factors.
750—A RUL, degradation, or age related graph which may be displayed on a RUL GUI.
760—X-axis RUL time.
770—Y-axis calculated or measured RUL-extracted artifact-metrics, example may be combination of area under curve plus peak separation frequency metric, or simple peak frequency location minus a frequency constant value.
780—aggregated curve of device RUL, degradation, or age.
784—single device ground truth, or alternatively the point in time that a device may be currently at within its predicted Remining Useful Life.
786—Most likely RUL, degradation, or age for a device.
792—RUL-extracted artifact-metrics=11.
794—RUL-extracted artifact-metrics=5.
796—RUL-extracted artifact-metrics=15.
798—RUL-extracted artifact-metrics=20.
800—Heat map, slice of heatmap, and interpretation.
810—Heatmap of measured RUL-extracted artifact-metrics example.
820—X-axis failure time or of age.
830—Y-axis for results metrics calculated from measured RUL-extracted artifact-metrics result values
840—Specific RUL-extracted artifact-metrics slice result in heatmap.
850—Chart of heatmap PDF and slice of Metric Value 840 860—heatmap probability region where 100% of devices are found with associated exhibited Metric-vs-Time values.
860A—Probability slices-all Z-axis of slices including those adjacent 840 seen.
862—specific cross section curve at slice 840 seen in heat map and slice of heat map.
864—most probable RUL for a device if RUL-extracted artifact-metrics result value=6.05.
868—region of highest probability and highest point within region of highest probability, showing most probable metric and most probable RUL.
870—X-axis failure time for slice 840 or alternatively age if time axis represents age.
900—Possible system for acquiring, maintaining, and displaying RUL and associated data.
902—Subsystem returning Date/Time/device age/device aging data-non-spectral data which may include device number, batch number, date or tine data was taken, total accelerated aging data, or the like.
904—Raw Spectrum data—may be broadband RF emissions and/or narrowband, may be in frequency domain or time domain, may be at varied RBWs, may be of one or more devices of the same device number, batch, or multiple devices of multiple device numbers, and/or may have been taken at different times, or under differing environmental conditions including differing operating power, load, or voltage conditions.
906—Raw data loader—may search for and select raw Spectrum Data 904 based on frequency, device data acquired from, and/or other characteristics such as date data acquired, temperature range data was acquired at, equipment used to acquire data, and/or facility where data was acquired. May employ database functionality for data selection such as SQL database search capabilities. Selected raw Spectrum Data may then be sent from it to Metrics Extractor 908.
908—Metrics Extractor Software which combines abstracted data for device and places it in the matrix 920.
909—API Interface which enables SAS software to access and process spectrum data and processing commands obtained from New Raw Data Loader 906.
910—Spectrum Analysis Suite (SAS) spectral feature recognition software which may be extensively used in the ‘Device Analysis Learning Phase’ and/or ‘RUL’ and/or ‘Age Assessment Phase’ 960 and may include modules which recognize patterns in spectrum such as spectral region matching (Curve Fit), peak location harmonic relationships (Harmonic Extraction), non-linear mixing product spectral features patterns detection (NLP), and/or repeated spectrum frequency and/or amplitude changes over a specific time period (Time Correlation).
912—Curve fit detect, extract, and abstract.
914—NON-Linear Products detect, extract, and abstract.
916—Harmonic Extraction detect, extract, and abstract.
918—Time Correlation detect, extract, and abstract.
920—Multi-Variate Matrix of metrics-N-dimensional array or table of elements containing parameters and RUL significant result values and artifacts abstracted from the raw data by the Metrics Extractor 908. It my also be a database performing the same function in a less efficient manner such as less processing-time-efficient.
930—Model Data Extractor-pulls related matching aging data and associated metrics from Historical Matrix or table 990 and current device in Matrix of metrics 920 which corresponds to same device number or type for later assessment, comparison, and aging estimation.
940—Recent data processed and set aside as candidates for integration/updating into accumulated model data database 980 later.
960—Determines RUL, age, degradation, or other factors based on current device's data matrix and accumulated exemplary data for device from 990.
970—RUL and or associated data for device under consideration.
980—Accumulated model data database or devices data, may include raw spectrum acquisitions in time and/or frequency domain, abstracted data metrics from raw data such as number of peaks above 30 dB above noise floor for specific regions, device numbers, associated device serial numbers, device age, device aging conditions, device origin, batch number, RBW, broadband data, narrowband data for devices, integrated data for devices, averaged data for devices, etc.
990—Accumulated model Multi-variate Matrix of Selected or all devices abstracted data Metrics from 980. It more often may typically be a Sparse Matrix of values or value ranges with some Rows, Columns, other dimensions, and/or elements and/or element ranges missing, or values not taken, not existing, and/or not observed. A dimensional row, column or dimension element range example may be peak frequency from 660.000100 MHz to 660.000120 MHz and may be in linear, non-linear, or exponential increments. A further example is a Row of 10 elements corresponding to frequencies acquired from spectrum for a device of 660.000000 MHz to 660.000200 MHz in increments of 20 Hz. It typically contains most or all of past total accumulated baseline data for a plurality of different but relevant devices which may be eventually processed.
996—Operator interface into system.
999—Operator/Observer/User.
1000—Two separate tables of values illustrating possible Frequency and dB levels at that frequency for two separate devices ‘A’ and ‘B’, typically of same device number, said frequency being a RUL significant indicator of RUL or device degradation. The devices typically behave functionally the same as seen within their same common specification sheet detailing valid operational parameter ranges from the manufacturer. They may or may not be from the same manufacturing lot or even from the same manufacturer.
1010—Frequency values of RUL-significant data from device A, illustrated in Hz and selected to acquire a corresponding Amplitude value 1020 at that frequency. The data is illustrated being taken at 1 Hz RBW and the data points are separated by 1 Hz.
1020—Amplitude values of RUL-significant data from device A, illustrated in dB or dBm, but may in Volts, microvolts, microwatts, etc. and associated with and found at the corresponding frequency values of 1010.
1030—Frequency values of RUL-significant data from device B, illustrated in Hz and selected to acquire a corresponding Amplitude value 1040 at that frequency. The data is illustrated being taken at 1 Hz RBW and the data points are separated by 1 Hz.
1040—Amplitude values of RUL-significant data from device B, illustrated in dB or dBm, but may in Volts, microvolts, microwatts, etc. and associated with and found at the corresponding frequency values of 1030.
1050—An example row showing possible RUL-significant Amplitude data for two devices both acquired at frequency 32.000949 MHz for device ‘A’ and also device ‘B’ for later RUL comparison analysis processing, RULam calculation, and/or statistics gathering. Device ‘A’ acquired RF emission data in the row of 32.000949 MHz is-65 dBm whereas Device ‘B’ acquired RF emission data at the same 32.000949 MHz row is-64 dBm.
1100—Example in table form of RUL-related data variables, value ranges, and/or values which may be stored, placed in a matrix, sparse matrix, and/or may be used to generate RUL result estimations.
1110—Time and/or date data was taken.
1120—Area under the curve (dB*Hz) at the frequency location where it was taken as seen in example table as ‘Carrier Frequency (Hz)’ column.
1130—Width at 10 dB down (Hz)-frequency width of peak (at frequency taken) and at 10 dB down from highest point on peak.
1140—Skewness—measure of skewness or ‘lopsidedness’ or non-symmetry of peak at peak frequency taken.
1150—Kurtosis—measure of atypical heaviness or atypical thickness of the tails of the peak shape profile or atypical thinness of the tails or atypical sharpness of the peak or atypical thickness or width of the peak at the frequency taken.
1160—Number of peaks in set-number of total peaks (one or multiple peaks) associated with or near to the peak at the carrier frequency in the same row including carrier frequency peak (peak at carrier frequency).
1170—Modulation frequency found (Hz)—This row of the table represents a set of peaks that appear to be generated to form a dB and frequency profile in the shape of a Bessel function. This typically includes one or more sets of peaks that are substantially symmetrical, equidistant in frequency from the highest center frequency peak, and located on both sides of this peak. If such a pattern is observed, the value in this row signifies the frequency separation from the center peak, usually measured in Hz. This is typically achieved by modulating the center peak frequency with a much lower frequency such as when non-linear mixing occurs as an artifact of non-linearities in its associated circuits generally.
1180—Carrier Freq (Hz)—Typically the frequency of the highest peak's highest frequency location, usually located in its center but not always.
1200—Illustration of time domain and frequency domain graphs of pure square wave and degraded, distorted or smoothed square wave which may typically occur as a circuit or electrical device ages.
1210—time domain graph of pure square wave and degraded, distorted, or smoothed square wave.
1220—Y-axis amplitude in volts of time domain graph.
1230—X-axis time in nanoseconds of time domain graph.
1240—Pure square wave.
1244—degraded, distorted or smoothed square wave.
1250—frequency domain graph of pure square wave and degraded, distorted, or smoothed square wave.
1260—Y-axis amplitude in dBm or dB.
1270—X-axis frequency in Mhz.
1280—frequency domain graph of pure square wave.
1290—frequency domain graph of degraded, distorted, or smoothed square wave.
1300—illustration of typical aging phenomena around a peak found to be RUL-significant.
1302—illustrates frequency separation distance decrease of a lower sideband peak or lower sideband device indicative of aging in a device after 12 hours accelerated aging time.
1304—illustrates frequency separation distance decrease of an upper sideband peak or upper sideband device indicative of aging in a device after 12 hours accelerated aging time.
1305—illustrates shift in frequency of a center peak indicative of aging in an exemplary device after 12 hours accelerated aging time.
1306—illustrates a center peak found to be of RUL-significance and which may be used to determine degradation, RUL, or age and seen after 12 hours of accelerated aging.
1308—illustrates a lower sideband peak found to be of RUL-significance and which may be used to determine degradation, RUL, or age and seen after 12 hours of accelerated aging.
1309—illustrates a upper sideband peak found to be of RUL-significance and which may be used to determine degradation, RUL, or age and seen after 12 hours of accelerated aging
1310—illustrative amplitude vs. frequency graph of center peak and two sideband peaks found to be of RUL-significance located in the 52 Mhz region and seen after 12 hours of accelerated aging.
1316—illustrates a center peak found to be of RUL-significance and which may be used to determine degradation, RUL, or age and seen after 35 hours of accelerated aging.
1317—illustrates a center peak increase in amplitude found to be of RUL-significance and which may be used to determine degradation, RUL, or age and seen after 35 hours of accelerated aging.
1318—illustrates a lower sideband peak increase in amplitude found to be of RUL-significance and which may be used to determine degradation, RUL, or age and seen after 35 hours of accelerated aging.
1319—illustrates a upper sideband peak increase in amplitude found to be of RUL-significance and which may be used to determine degradation, RUL, or age and seen after 35 hours of accelerated aging.
1320—illustrative amplitude vs. frequency graph of center peak and two sideband peaks found to be of RUL-significance located in the 52 Mhz region and seen after 35 hours of accelerated aging.
1326—illustrative newly emerging above noise floor and now visible lower sideband peak found to be of RUL-significance located in the 52 MHz region and seen after 35 hours of accelerated aging.
1328—illustrative newly emerging above noise floor and now visible upper sideband peak found to be of RUL-significance located in the 52 MHz region and seen after 35 hours of accelerated aging.
1330—illustrative table or matrix containing RUL-significant abstracted artifact data of aging time, Center frequency, sideband frequency(s) separation distance from center frequency, and number of RUL-significant peaks in region.
1400—Illustrative graphs showing area under the peak curve as a RUL-significant artifact which may be used to inform a more accurate RUL estimate.
1406—frequency region above noise floor with shape content information used to calculate area under the peak curve as a RUL-significant artifact before any aging occurs
1408—calculated noise floor level.
1410—graph of spectrum of a RUL-significant peak and surrounding region before any aging occurred.
1412—Center peak with its dB height and frequency location.
1420—Y-axis dB or dBm measurement.
1430—X-axis frequency.
1450—illustrated graph of spectrum of a RUL-significant peak and surrounding region after 31 hours aging occurred. Illustrated aging may be accelerated or normal operation conditions.
1452—Center peak with its dB height and frequency location after 31 hours aging.
1456—frequency region above noise floor with shape content information used to calculate area under the peak curve as a RUL-significant artifact after 31 hours aging occurs.
1458—calculated noise floor level after 31 hours aging.
1460—Y-axis dB or dBm measurement.
1462—X-axis frequency.
1470—device age column data within illustrative table or matrix containing RUL-significant abstracted artifact data.
1472—center frequency of peak column data within illustrative table or matrix containing RUL-significant abstracted artifact data.
1474—area under the curve of peak column data at peak frequency row recorded in 1472 within illustrative table or matrix containing RUL-significant abstracted artifact data.
1476—peak power in dB or dBm as peak column data at peak frequency row recorded in 1472 within illustrative table or matrix containing RUL-significant abstracted artifact data. Alternatively, all amplitudes or powers here or herein may be in other units such as voltage, microwatts, watts or the like.
1478—Width at 10 dB down in Hz as peak column data at peak frequency row recorded in 1472 within illustrative table or matrix containing RUL-significant abstracted artifact data.
1480—Skewness of peak as column data at peak frequency row recorded in 1472 within illustrative table or matrix containing RUL-significant abstracted artifact data.
1482—Kurtosis of peak as column data at peak frequency row recorded in 1472 within illustrative table or matrix containing RUL-significant abstracted artifact data.
1484—Peak span in Hz at base just above noise floor as peak column data at peak frequency row recorded in 1472 within illustrative table or matrix containing RUL-significant abstracted artifact data.
1490—illustrative table or matrix containing RUL-significant abstracted artifact data of aging time, Center frequency, sideband frequency(s) separation distance from center frequency, and number of RUL-significant peaks in region.
1500—illustrates broadband (ex. 30 MHz to 1 GHz) spectrum and narrowband (ex. 660.011 MHz to 660.012 MHz) spectrum RUL-significant artifacts which may occur before and after aging.
1510—illustrative spectra of broadband data (ex. 30 MHz to 1 GHz) before aging, after aging 2184 hours and after aging 2756 hours.
1520—Y-axis amplitude in dB.
1530—X-Axis frequency in MHz.
1540—illustrative Control data, spectrum taken before any aging.
1542—RUL-significant region of interest in unaged broadband spectrum which later shows changes after aging.
1544—illustrative spectrum taken after aging 2184 hours.
1545—RUL-significant region of interest in aged broadband spectrum which shows changes after aging 2184 hours.
1546—illustrative spectrum taken after aging 2756 hours.
1548—RUL-significant region of interest in aged broadband spectrum which shows changes after aging 2756 hours.
1550—illustrative spectra of narrowband data (ex. 660.011750 MHz and 660.012000 MHz) before aging, after aging 2184 hours and after aging 2756 hours.
1560—Y-axis amplitude in dB.
1562—X-Axis frequency in MHz.
1570—Illustrates spectra between 660.011750 MHz and 660.012000 MHz before any aging.
1571—Peak in RUL-region of interest at hour 0 which shifts in frequency after aging but does not substantially change in dB height above the noise floor and may play role in RUL calculation.
1572—top of peak dB 1577 above the noise floor.
1573—dB height of peak 1577 above the noise floor before aging.
1574—top of peak in dB 1579 above the noise floor.
1575—dB height of peak 1579 above the noise floor before aging.
1577—RUL-significant Peak in RUL-region of interest which may be used to play substantial role in RUL calculation.
1578—peak frequency separation distance in Hz between peak 1577 and peak 1579 before aging.
1579—largest Peak in RUL-region of interest before aging which plays substantial role in RUL calculation and is RUL-significant.
1580—Illustrates spectra between 660.011750 MHz and 660.012000 MHz after aging 2184 hours.
1581—Peak in RUL-region of interest at hour 2184 which shifts in frequency after aging but does not substantially change in dB height above the noise floor and may play role in RUL calculation.
1582—top of peak in dB 1587 above the noise floor.
1583—dB height of peak 1587 above the noise floor after aging 2184 hours.
1584—top of peak in dB 1589 above the noise floor.
1585—dB height of peak 1589 above the noise floor aging 2184 hours.
1586—amount of shift in frequency of peak 1571 to new peak location 1581 after aging 2184 hours.
1587—RUL-significant Peak in RUL-region of interest which may be used to play substantial role in RUL calculation.
1588—peak frequency separation distance in Hz between peak 1587 and peak 1589 after aging 2184 hours.
1589—largest Peak in RUL-region of interest after aging 2184 hours which plays substantial role in RUL calculation and is RUL-significant.
1590—Illustrates spectra between 660.011750 MHz and 660.012000 MHz after aging 2756 hours.
1591—Peak in RUL-region of interest at hour 2756 which shifts in frequency after aging but does not substantially change in dB height above the noise floor and may play role in RUL calculation.
1592—top of peak dB 1597 above the noise floor.
1593—dB height of peak 1597 above the noise floor after aging 2756 hours.
1594—top of peak in dB 1599 above the noise floor.
1595—dB height of peak 1599 above the noise floor aging 2756 hours.
1596—amount of shift in frequency of peak 1581 to new peak location 1591 after aging 2756 hours.
1597—RUL-significant Peak in RUL-region of interest which may be used to play substantial role in RUL calculation.
1598—peak frequency separation distance in Hz between peak 1597 and peak 1599 after aging 2756 hours.
1599—largest Peak in RUL-region of interest after aging 2756 hours which plays substantial role in RUL calculation and is RUL-significant.
1600—narrowband Frequency vs. dB spectra changes of GPS device undergoing stages of aging.
1620—unaged narrowband Frequency vs. dB spectra of GPS device.
1622—Region of RUL-significance later found to indicate aging level showing non-linear mixing products.
1630—X-axis frequency.
1634—Y-axis dBm.
1640—narrowband Frequency vs. dB spectra of GPS device aged 3 weeks.
1642—Region of RUL-significance after 3 weeks aging showing loss and broadening of non-linear mixing products.
1644—second Region of RUL-significance after 3 weeks aging showing loss of non-linear mixing products.
1660—narrowband Frequency vs. dB spectra of GPS device aged 6 weeks.
1662—Region of RUL-significance after 6 weeks aging showing substantial suppression of non-linear mixing products.
1680—narrowband Frequency vs. dB spectra of GPS device aged 10 weeks.
1682—primary peak of RUL-significance around which other RUL-significant features are seen.
1684—Region of RUL-significance after 10 weeks aging showing phase noise attachment and feature coarsening of non-linear mixing products.
1700—narrowband progression of spectrum of two devices with same manufacturer's device number showing similar aging features.
1710—Device ‘A’ illustrating RUL-significant features after more substantial aging.
1712—Device ‘A’ RUL-significant region of changes due to aging.
1714—Device ‘A’ RUL-significant peak feature within RUL-significant region of changes 1712 due to aging.
1716—Second Device ‘A’ RUL-significant peak feature within RUL-significant region of changes 1712 due to aging.
1720—Device ‘B’ illustrating RUL-significant features after more substantial aging.
1722—Device ‘B’ RUL-significant region of changes due to aging.
1724—Device ‘B’ RUL-significant peak feature within RUL-significant region of changes
1722 due to aging.
1726—Second Device ‘B’ RUL-significant peak feature within RUL-significant region of changes 1722 due to aging.
1732—Device ‘A’ RUL-significant region of changes after some aging.
1730—Device ‘A’ illustrating RUL-significant features after some aging.
1740—Device ‘B’ illustrating RUL-significant features after some aging.
1742—Device ‘B’ RUL-significant region of changes after some aging.
1750—Device ‘A’ illustrating no RUL-significant features before any aging.
1760—Device ‘B’ illustrating no RUL-significant features before any aging.
1800—illustrates spectrum changes due to degradation on a single device and composite probability distribution of probability vs. power in authentic devices differing from distribution in degraded or suspect devices.
1802—peak in unaged device's RUL-significant narrowband frequency region
1804—peak 1802 of RUL-significance shifted to higher frequency in aged device's RUL-significant narrowband frequency region.
1810—unaged device's narrowband frequency region.
1818—Y-axis dB.
1820—aged device's narrowband frequency region.
1822—region of RUL-significance within RUL-significant narrowband frequency region containing a substantial number and degree of spectral changes after aging.
1824—X-axis frequency.
1830—visibly expanded region of RUL-significance within RUL-significant narrowband frequency region containing a substantial number and degree of spectral changes after aging.
1832—regions around central peak 1804 containing a more detailed view of additional non-linear mixing content within peaks 1833 which is RUL-significant.
1833—peaks containing RUL-significant detailed structure of non-linear mixing content as areas under their curves.
1833A—peaks containing RUL-significant detailed structure of non-linear mixing content but not as visible due to less magnification.
1834—X-axis frequency.
1836—region 1822 but seen in more detail in visibly expanded region 1830.
1838—Y-axis dB.
1850—probability distribution of probability vs. power metric showing a differing distribution with good devices vs. degraded or suspect devices.
1852—Y-axis probability.
1854—X-axis Power Metric.
1860—distribution generated from multiple authentic devices.
1870—distribution generated from multiple degraded or suspect devices.
1900—Method of accumulating or updating device data.
1960—Database access software capable of transferring data and/or Metrics to or from GUI and Matrix of Metrics 990.
1996—Software to enable updated/new data to be selected, annotated to be added to Accumulated model data 980 by user 1999 selectively, or automatically.
1999—Operator deciding criteria for data suitability to update Accumulated model data 980 and/or annotate data.
2000—Flowchart of exemplary processing of a batch of devices.
2004—Step of acquisition of broadband RF emissions data on one or more of the acquired devices.
2008—Step of naturally or artificially aging device used in Step 2004. May be alternatively performed by acquiring and using a separate already aged device instead of aging a device or waiting for it to age, the aged device replacing a device to be aged.
2012—Step of acquisition of broadband RF emissions data on one or more of the aged devices.
2016—Step of comparing aged broadband RF emissions data with unaged or lesser aged broadband RF emissions data for differences as candidate regions of RUL-significance.
2020—Determine with more certainty the frequency regions of RUL-significance of the acquired devices on candidate regions identified in Step 2016.
2030—Step of acquisition of more narrowband RF emissions data from the frequency regions of RUL-significance identified in Step 2020 on one or more of the acquired devices.
2034—Optionally further or additionally age or accelerated aging of devices, preferentially of those devices whose data has previously been acquired.
2038—Optional Step of acquisition of more narrowband RF emissions data from the frequency regions of RUL-significance identified in Step 2020 on one or more of the further aged devices. This may then enable establishing a set containing a series of acquisition data associated with varied differing aging levels as a basis for determining age of device based on RF emissions data.
2042—Step of comparing further aged narrowband RF emissions data with unaged or lesser aged narrowband RF emissions data in regions of RUL-significance to determine features of aging significance within those regions which may arise or be reinforced.
2046—Step of determining algorithms to use to extract RUL-significant Metrics from features identified in Step 2042.
2050—Step of using algorithms identified in Step 2046 to generate Metrics on device data acquired.
2060—Optional step of repeatedly gathering data from devices in the frequency regions of RUL-significance and using the determined algorithms to generate the Metrics for the devices. This may be done for differing devices and/or at differing aging levels or even at failure levels.
2064—Step of archiving Device Data and its Metrics acquired from some or all of Steps 2004 to 2060 in a database.
2068—Step of using archived Device Data and its Metrics to determine RUL of devices already in the database or of determining RUL of newly acquired devices, typically of the same device number.
2100—Example of a 3-D Sparse Matrix whose dimensions are different device metrics and whose elements indexed to Matrix device metrics co-ordinates' contain occurrence counts or statistical values of device metric combinations at those coordinates.
2110—3-D Sparse Matrix element located at indexes (1,4,3) corresponding to X-axis value of age between 0-1000, Y-axis value corresponding to value between 0.00 and 0.08 of Skewness and Z-axis value of Modulation Frequency between 700 and 800 Hz.
2120—Y-axis of example 3-D Sparse Matrix which represents Skewness ranges for each Skewness index.
2122—Specific Y-axis example value of a device having 0.15 Skewness which is within range of 0.08 to 0.16 Skewness which falls into Skewness Y-axis index=3.
2124—Points to a plane of 16 Matrix elements within the Matrix 2100 all having a Skewness between 0.08 and 0.16 and all having a Skewness index=3.
2130—X-axis of example 3-D Sparse Matrix which represents age range for each age index.
2132—Specific X-axis example value of a device having age of 1001 hours which is within range of 1000.001 to 2000 hours Skewness which falls into age X-axis index=2.
2134—Points to a plane of 16 Matrix elements within the Matrix 2100 all having an age between 1000.001 hours and 2000 hours and all having a age X-axis index=2.
2140—Z-axis of example 3-D Sparse Matrix which represents Modulation Frequency ranges for each Modulation Frequency index.
2142—Specific Z-axis example value of a device having Modulation Frequency of 695 Hz which is within range of 600 to 700 Hz and which falls into Modulation Frequency Z-axis index=2.
2144—Points to a plane of 16 Matrix elements within the Matrix 2100 all having a Modulation Frequency between 600 Hz and 700 Hz and all having a Modulation Frequency index=2.
2150—Points to a line of sequential 4 Matrix elements intersecting specific Age and Skewness ranges with respective associated indexes within the Matrix 2100 all having a Skewness between 0.08 and 0.16 with a Skewness Y-axis index=3 and also all having Age within range of 1000.001 to 2000 hours which falls into age X-axis index=2.
2160—Points to a line of sequential 4 Matrix elements intersecting specific Skewness and Modulation Frequency ranges with respective associated indexes within the Matrix 2100 all having a Modulation Frequency between 600 Hz and 700 Hz with a Z-axis index=2 and also all having Skewness within range of 0.08 to 0.16 which falls into Skewness Y-axis index=3.
2170—Points to a line of sequential 4 Matrix elements intersecting specific Age and Modulation Frequency ranges with respective associated indexes within the Matrix 2100 all having a Modulation Frequency between 600 Hz and 700 Hz with a Z-axis index=2 and also all having Age within range of 1000.001 hours to 2000 hours which falls into Age X-axis index=2.
2180—Points to a Matrix element within the Matrix 2100 at index location (X=2, Y=3, Z=2) associated with a device's Age within range of 1000.001 to 2000 hours which falls into age X-axis index=2, and with that device having 0.15 Skewness which is within range of 0.08 to 0.16 Skewness which falls into Skewness Y-axis index=3, and with that device having a Modulation Frequency between 600 Hz and 700 Hz with a Z-axis index=2. It's element's value content=1 at that specific index location (X=2, Y=3, Z=2) meaning there has been 1 occurrence of a device measured thus far within and constrained to all 3 of those ranges associated index values.
2190—Points to a Matrix element within the Matrix 2100 at index location (X=4, Y=1, Z=1) containing 0 occurrences of any devices measured thus far within and constrained to all 3 of those ranges associated index values. It is possible no device will ever be measured to result in values associated with that matrix element and that element may never rise above=0.
2200—Example of a 2-D Sparse Matrix whose dimensions are different device metrics and whose elements indexed to Matrix device metrics co-ordinates' contain occurrence counts or statistical values of device metric combinations at those coordinates.
2210—Y-Axis of Skewness value ranges.
2212—Row 4 of Skewness whose value ranges from 0.00 to 0.08 Skewness.
2214—Row 3 of Skewness whose value ranges from 0.080001 to 0.16 Skewness.
2216—Row 2 of Skewness whose value ranges from 0.160001 to 0.24 Skewness.
2218—Row 1 of Skewness whose value ranges from 0.240001 to 0.32 Skewness.
2219—Example value of a device's skewness=0.14993 and thus associated with Row 3's value range of Matrix 2200.
2220—X-Axis of Age value ranges. May be age at failure or age thus far.
2222—Column 1 of Age from 0 to 1000 hours aging.
2224—Column 2 of Age from 1000.001 hours to 2000 hours aging.
2228—Column 4 of Age from 3000.001 hours to 4000 hours aging.
2229—Example value of a device's age=1001 hours and thus associated with Column 2's (Column 2224) value range of Matrix 2200.
2230—Matrix 2200 element at (Row=3, Column=2) containing count or statistical value as device metrics data is added and accumulated. In this example, the 1^{st} device's data is shown added to the Matrix 2200 and its metrics are associated with this matrix element and the value within that matrix element is =1.
2232—Matrix 2200 element at (Row=3, Column=2) containing count or statistical value=1. It has been incremented from 0 occurrences to contain and reflect the occurrence of the 1^{st} device's associated metrics in its associated row and column's index location range. Likely additional subsequent other device's associated metrics will increment that same matrix element or elements near or adjacent it. Also likely is that elements further away or at matrix extreme edges will never get an occurrence and never get incremented above a value of 0.
2234—Matrix 2200 element at (Row=4, Column=3) containing count or statistical value=0. No devices thus far have fallen into this element's combination of Skewness and time value. Its possible that no devices ever will be found to index into this element's combination of Skewness and time value.
2236—Matrix 2200 element's count or statistical value=0 (at Row=4, Column=3).

### DETAILED DESCRIPTION OF THE SUBJECT MATTER

The following description is of exemplary embodiments that are presently contemplated for implementing the present subject matter. This description is not to be taken in a limiting sense but is made merely for the purpose of describing the general principles and features of various aspects of the present Subject matter. The scope of the present subject matter is not limited by this description.

Prior to proceeding to the more detailed description of the present subject matter, it should be noted that, for the sake of clarity and understanding, identical devices which have identical functions have been identified with identical reference numerals throughout the several views illustrated in the drawing figures.

It is to be understood that the singular forms “a,” “an,” and “the” include plural referents unless the context clearly dictates otherwise or expressly specified otherwise. Thus, for example, reference to “a device surface” includes reference to one or more of such surfaces.

For purposes here, the conjunction “or” is to be construed inclusively (e.g., “a dog or a cat” would be interpreted as “a dog, or a cat, or both”; e.g., “a dog, a cat, or a mouse” would be interpreted as “a dog, or a cat, or a mouse, or any two, or all three”), unless: (i) it is explicitly stated otherwise, e.g., by use of “either . . . or,” “only one of,” or similar language; or (ii) two or more of the listed alternatives are mutually exclusive within the particular context, in which case “or” would encompass only those combinations involving non-mutually-exclusive alternatives.

The verb “may” is used to designate optionality/noncompulsoriness. In other words, something that “may” can, but need not.

Before elucidating the subject matter shown in the Figures, the present disclosure will be first described in general terms.

Electrical devices are employed in a variety of applications. Electrical devices may include an electronic device. Electrical devices may include an assembly of electronic devices. The electronic device may be manufactured from a semiconductor material. The semiconductor material may include any one of silicon, graphite and germanium. The electronic device may be available in a microelectronic equivalent suitable for a surface mount application. This may include a transistor, a capacitor, an inductor, a resistor, a diode, an insulator and a conductor.

The electronic device may be an integrated circuit (IC). IC, also called microelectronic circuit, microchip, or chip, an assembly of electrical devices, is generally fabricated as a single unit, in which miniaturized active devices (e.g., transistors and diodes) and passive devices (e.g., capacitors and resistors) are interconnected and built up on a thin slice of a semiconductor material.

The electrical device may be a microcontroller. The microcontroller may be used as a central hub for computing operations, communication and signal processing. The microcontroller may be used as space grade digital output temperature sensor.

The electronic device may be a binary counter. Binary counter applications may include a general timing application. Binary counter applications may include tracking the timing of bit streams for each input. Binary counter applications may include taking in multiple complex inputs and compression to four timed outputs. Binary counter applications may include filtering of bit streams.

The electronic device may be a shift register. The shift register may use cascading flip flops to support a variety of digital circuits. The shift register may be used to convert from serial and parallel interfaces. The shift register may be used to create simple delay circuits. The shift register may be used for utilization of a stack, such First In, First Out (FIFO). The shift register may be used in bit stream filtering. The shift register may be used in timing of communication circuits.

The electrical device may be a field-programmable gate array (FPGA).

The electrical device may be a processor.

The electronic device may be a metal-oxide-semiconductor field-effect transistor (MOSFET).

The electronic device may be a complementary metal oxide silicon (CMOS) transistor.

The electrical device may be a circuit assembly.

The electrical device is designed to perform a function. The electrical device may be designed to output a signal at an output pin. This signal may be referred to as an output signal. The output signal may be generated when the electrical device is energized. The output signal may be generated when the electrical device performed a designed function. The output signal may be a voltage. The output signal may be a current. The output signal may be a wave. The output signal may be a wave with a specific RF frequency. The output signal may be a combination of any one of a voltage, a current and a sinusoidal wave.

The electrical device may be exposed to stress during operation or use. The stress may be related to an environment that the electrical device must function within and may be referred to as environmental stress.

The stress may be related to accelerated testing of the electrical device. The accelerated testing may be performed in a test chamber configured to fluctuate the temperature between two extremes.

Every electrical device gives off electromagnetic emissions when operating or when being simply energized into a powered state where the electric energy from an energy source is connected to various circuits and/or devices within such electrical device. When the electrical device is simply powered on, the electromagnetic energy emanates from any one of wires, inter-device connections, and junctions within the electrical device. When the electrical device is energized, current flows through internal circuitry of the electrical device. Current flow changes through the circuitry generates emissions of electromagnetic energy. It may be sufficient to energize the electrical device by connecting an energy source to a power pin of the electrical device to generate unintended emissions. The energy source may be referred to as a power supply.

In this document, unintended emission(s) may be considered herein to be not only emissions emitted unintentionally by the electrical device contrary to the intent and objective of the electrical device, but also unintended properties of intended emissions of the electrical device. Unintended emissions refer to electromagnetic energy that is captured and analyzed which is not directly produced by the intended functionality of the electrical device. Conversely, intended emissions refers to electromagnetic energy that is captured and analyzed which is a direct result of the intended functionality of the electrical device, such as for example the carrier signal of an FM transmitter. Therefore, the intended digital data contained in an intended digital transmission would not be considered unintended, however other aspects of the intended signal such as harmonics, phase noise, frequency stability, out-of-band signal content, amplitude deviation, bit duration times, etc. could be deliberately used by the system for information content to be conveyed to the user.

Exemplary embodiments operate by analyzing the unintended and/or intended emissions of the electrical device.

Emissions phenomenology, especially unintended emissions, is causally dependent on an internal circuitry of the electrical device, layout of ICs and traces, material composition, physical state of the device, firmware and software operating on the device.

The emission(s) of electromagnetic energy may be in a Radio Frequency (RF) spectrum, which is typically referred to in the art as frequencies above 3 kHz and below 300 GHZ. This emission may be referred to as an RF emission. Infrared, infrasonic, and other emissions may be also contemplated by the exemplary embodiments. The forgoing description may be focused on intended emissions, unintended emissions and unintended features of intended emission(s) of electromagnetic energy. Electromagnetic energy may be in a radio frequency (RF) spectrum.

Emission phenomenology may manifest as an emission signature in a time domain. Emission phenomenology may manifest as an emission signature in a frequency domain. Emission phenomenology may manifest as an emission signature in both time and frequency domains. The emission signature may be classified by identifying an emission signature parameter or a characteristic.

The parameter may be chosen as a characteristic of RF emission signal. This parameter may be referred to as an emission signature parameter. The emission signature parameter may include a frequency. The emission signature parameter may include a wavelength. The emission signature parameter may include an amplitude. The emission signature parameter may include a phase. The emission signature parameter may include a peak width. The emission signature parameter may include a Full-Width-Half-Maximum (FWHM). The emission signature parameter may include harmonic indices. Emission signature parameter may include a harmonic spacing. The emission signature parameter may include a peak position. The emission signature parameter may include skewness of a peak. The emission signature parameter may include a cross modulation peak parameter. The emission signature parameter may include a magnitude of the noise floor. The emission signature parameter may include power differences between peaks. The emission signature parameter may include a frequency shift of emissions. The emission signature parameter may include a Harmonic correlation (changes in harmonic content spacing, envelope, etc.). The emission signature parameter may include non-linear mixing products appearance, disappearance, relative spacing and envelope evolution. The emission signature parameter may include a time correlation (the substantially repeated pattern of evolution of signatures over time). The emission signature parameter may include a change in total emission energy. The emission signature parameter may include a change in emitted energy distribution symmetry and information content (Shannon Entropy). The emission signature parameter may include a non-harmonic signature correlation.

The emission signature parameter may include any combination of the above described emission parameter types. Emission signature parameter may be referred to as emission signature element.

A health of an electrical device may change over time as the electrical device ages during operation. The electrical device may degrade over a designed lifetime. When electrical devices degrade over their lifetime, they become more susceptible to reduced performance, increased faults, and eventual failure. Rapid progress in the microelectronics field may often outpace development of new systems. This may result in increasingly long device lifecycles and storage cycles. Legacy devices which are no longer manufactured may be acquired through third electrical devices and non-original equipment manufacturers (OEM) vendors which creates vulnerabilities in the supply chain. This may increase device exposure to environmental and operational risk factors, which raises the risk of increased failure rates and unexpected maintenance costs. Failure of electrical devices, especially in safety-critical systems, could have disastrous consequences. These failures can be mitigated with a device measurement technology that can quickly determine the device's health state; thus, a robust solution which assesses device health, age, and Remaining Useful Life (RUL), defined as the remaining lifetime for which a device will operate reliably is needed. The ability to determine the health of the electrical devices and accurately report their health is a known critical gap in supply chain and operational assurance. The ability to provide RUL prognostication and/or determine aging may provide a breakthrough capability for maintenance initiatives and failure prevention.

The health of the electric al device may be also referred to as a condition of the electrical device. The condition may be a degraded condition. The condition may be an aged condition. The condition may be a RUL. Thus, determining the health of the electrical device may be referred to as a determining the condition of the electrical device. Determining the condition may be by way of measuring at least one emission signature parameter. Determining the condition may be by way of calculating at least one emission signature parameter. Determining the condition may be by way of visually observing at least one emission signature parameter displayed on a display. Determining the condition may be by way of populating at least a two-dimensional matrix with at least one emission signature parameter. Determining the condition may be by way of populating at least a three-dimensional matrix with at least two emission signature parameters.

As the technological complexity of high-performance electronics become increasingly more crucial, the reliability of all electrical devices becomes essential. Mission-critical electrical devices require exceptional operational reliability to ensure high confidence operation. Devices, such as microprocessors, Programmable Logic Devices (PLDs) including Field Programmable Gate Arrays (FPGAs), Application-Specific Integrated Circuits (ASICs), munition fuses, memory, and a myriad of other devices are vulnerable to environmental and operational stresses which contribute to natural device degradation over time. As electronics degrade over their lifetime, they become susceptible to reduced performance, increased faults, and eventual failure. Some applications of equipment result in varied amounts of stress over time and thus operating duration may not be sufficient knowledge to determine RUL. An example would be a mobile transmitter operating at varied power levels over its life due to location changes and thus variations in distance to a remote base station.

Rapid progress in the microelectronics field may outpace development of new systems. This may be exacerbated by increasingly long system lifecycles, which increases device exposure to environmental and operational risk factors, thereby increasing failure rates and maintenance costs. Failure of electrical devices during operation could have disastrous consequences. These failures can be mitigated with device measurement technology that can quickly determine the device's health. These failures can be mitigated with a more sensitive, accurate, and robust solution which assesses device health and RUL. The ability to determine the health of electrical devices and accurately report their health may provide a maintenance assurance. The ability to determine the health of electrical devices and accurately report their health may provide an operational assurance.

Any one of a degradation, an aging and a RUL of the electrical device may be determined by analyzing an emission of electromagnetic energy in RF spectrum.

The RULAS software tool may leverage RF emissions characterization for RUL assessment and predictions of electronics in critical assets, for example a personal computer (PC).

Steps in performing this may include acquiring foundational phenomenology supporting subsequent analysis using hardware supporting emission collection and methods and tools for signature assessment, analysis and signature file creation such as an ADEC system.

Exploiting unintended RF emissions from electrical systems, emission signatures characteristic to system and sub-system functionality, electronics health status and device programming may be acquired. Changes observed in the RF signatures may be detected in real-time to enable characterization of individual devices, circuit card assemblies or sub-system devices.

At the most basic level, a change in current flow propagates through circuitry and creates emissions. The unintended emissions of an electronic device are causally related to the device's internal circuitry, layout of Integrated Circuits (ICs) and traces, material composition, physical state of the device, firmware and software operating on the device. The power of the technology may arise from the combination of ultra-sensitive RF sensing capability, such as (−170 dBm) sensitivity, orthogonal algorithms, and machine learning analytics to process and catalog the equipment's current state. RF emissions may be leveraged to identify a wide variety of electrical characteristics. Emission signature characteristics and features may then be used to establish this characterization including but not limited to the following:
Frequency shift of emissions
Harmonic correlation (changes in harmonic content spacing, envelope, etc.)
Non-linear mixing products appearance, disappearance, relative spacing and envelope evolution
Time correlation (the evolution of signatures over time during cyber events)
Changes in total emission energy
Changes in emitted energy distribution symmetry and information content (Shannon Entropy)
Non-harmonic signature correlation

A possible method of device characterization the emission may process RF data collection which may occur at two scales; one being a broadband sweep over a 30 MHz to 1 GHZ spectrum such as at 1 Hz Resolution Bandwidth (RBW) and the second scale being a selection of data within a narrower frequency range that may allow for multiple data acquisition to be collected over narrower specific regions found to be of RUL relevance in a more rapid amount of time. These forms of collection may be to gain valuable information about exemplary devices, systems, sub-systems, or device under test (DUT) and identify their key regions of interest.

Multiple narrowband regions may be ideal to collect aging characterization of a PLC asset under test. For each region, multiple data acquisitions may be performed to study regions for potential areas of RF emissions variation over time.

Signature Analysis Suite (SAS) software may be developed to provide algorithms and tools to quantitatively characterize spectral signatures. The available algorithms may be grouped into two classes: Signature Statistics, and Advanced Signature Analysis. These tools may quantify integrative and differentiative metrics of spectrum allowing extraction of unique features to make a quantitative description of the spectrum. Table 1 below is an exemplary list of some of the metrics and/or modules which may be provided by SAS.

TABLE 1
Software metrics which may be implemented
by a set of RUL estimating methods

| Analysis | | |
|---|---|---|
| Type | Module | Description |
| Signature | Principal | PCA is a statistical technique used for |
| Statistics | Device | dimensionality reduction. It transforms |
| | Analysis | high-dimensional data into a new |
| | (PCA) | coordinate system (principal devices) to |
| | | maximize data variability, simplifying |
| | | complex datasets while preserving |
| | | essential patterns and trends. It is |
| | | commonly used for data visualization, |
| | | noise reduction, and feature extraction. |
| | Signature | Calculates the probability distribution of |
| | Metric | the calculated metric that has been |
| | Distribution | extracted from raw spectral data. |
| Advanced | Advanced | The advanced curve fit module extracts the |
| Signature | Curve Fit | area under the curve, width at 10 dB down, |
| Analysis | | skewness and kurtosis from the |
| | | selected peak(s) by analyzing the structure |
| | | and shape of the curve. |
| | Time | This module analysis how similar or related |
| | Correlation | the data collected at different time points |
| | | is for a specific range of frequencies of |
| | | interest |
| | Harmonic | This module aims to isolate and identify |
| | Extraction | specific harmonic frequencies present in |
| | | a complex waveform and it involves |
| | | analyzing a signal and separating its |
| | | constituent harmonic devices. These harmonic |
| | | devices are integer multiples of a fundamental |
| | | frequency. |
| | Advanced | This module identifies elements that are |
| | Non-Linear | related to th emodulation frequency that is |
| | Product | superimposed onto the carrier wave. The |
| | (NLP) | modulation frequency determines how rapidly |
| | | the signal changes over time, and it |
| | | corresponds to the frequency of the information |
| | | or data being encoded onto the carrier wave. |

The SAS software may be a component of the RULAS software tool.

The following capabilities may be offered by the RULAS software. This list may include, but may not be limited to:
Allow for the import of collected data
Allow for the periodic collection of RF signatures from devices, subsystems, or boards.
Provide assessments, functionality, operability, degradation and/or RUL interactively at each collection analysis interval or collectively based on combined measurements taken at varied times, locations, or under varied conditions.
Provide levels of user-friendly, user-understandable, and/or user-knowledge-level-appropriate degradation and/or RUL assessments on devices of interest
Provide means to upgrade the methods and modules implementing the methods for faster execution, enhanced prediction capability, additional prognostication methods, additional analysis methods, more sophisticated means of combining methods results to yield more accurate degradation and/or RUL results, provide more detailed or more understandable user-outputs, provide maintenance recommendations, provide data collection recommendations including additional RF data samples and/or when to acquire them, provide alarms or alerts regarding problematic trends or possible suspicious data acquisition outliers, provide summaries and/or graphics to convey the results certainty or probability, device characteristics, and/or results comparisons across sets of devices
Provide an enhanced Graphic User Interface

The typical sequence of determining RUL and/or degradation of a device, sub-system, system, assembly, or sub-assembly may include the following steps:
Identify and collect signatures from devices of interest
Extract metrics from signatures collected.
Leverage extracted metrics for RUL/Age model building.
Generate user-understandable results based on RUL/degradation metrics model results

For example, an Allen-Bradley (Rockwell Automation) MicroLogix-1100 Programmable Controller (PLC) may be used as an exemplary asset to be tested to determine its RUL. The PLC is a specialized computer system designed to control numerous input and output signals. In many cases, it is implemented in a “headless” configuration, without an attached keyboard or display. In other situations, remote displays with touch screen input (typically water resistant) are utilized instead of discrete input controls and status displays. The PLC product line ranges from very small units-capable of interfacing with just a handful of input and output signals, to larger units capable of controlling and evaluating dozens or hundreds of signals. When operations become more complex, multiple PLCs can be networked together, to handle an almost endless number of signals and electrical devices.

The automated RULAS software may include advanced algorithms and automation, including Non-Linear Product, Advanced Curve Fit, Time Correlation, and Harmonic Extraction. This may ascertain the degradation trends detected in the data collected from aged PLCs which have been precisely quantified and metricized. These sophisticated algorithms may provide a comprehensive framework for analyzing the collected data, enabling accurate characterization of degradation patterns, and uncovering subtle correlations. Leveraging the full potential of these proprietary algorithms enhances the depth and accuracy of the analysis, empowering informed decision-making and facilitating proactive maintenance strategies, these metrics may provide statistical insights across multiple frequency regions, enabling precise characterization of degradation and aging in electrical devices. The resulting statistical trends and data points may be instrumental in calculating the RUL of the electrical devices.

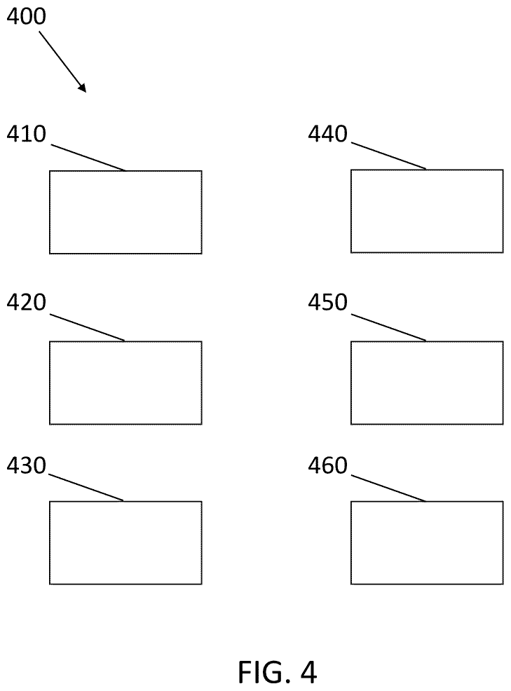

The selection of specific frequency regions and metrics is rooted in the intricate interplay of the electronics' internal devices, such as clocks, relay switches, communication connections, and more. These regions arise from the system's architecture and its fundamental operating frequencies. Characteristics of each electrical device may be meticulously analyzed the to ascertain their frequency response and transient behavior to verify feasibility. By doing this, regions may be selected that represent device health based on the resulting emitted RF signals. An exemplary list of potential electrical devices of interest for a typical PLC is shown in FIG. 4. Any or all these electrical devices may separately emit specific unintentional RF emissions at differing frequencies useful to determine their degradation status and RUL. These typically multiple separate emissions from each device typically offer measurable change over time as the device ages and degrades and may be used to determine their degradation and/or RUL or may be used to determine the equipment's overall degradation and expected RUL. Some devices may be expected to degrade or age faster than others and therefore are expected to fail first and thus be the expected cause of failure of the overall equipment. These electrical devices thus may be the determining factor in the degradation or RUL of a piece of equipment such as a PLC. Each device may degrade or age at a different rate depending on the equipment's history of use. For example, a transceiver which spent most of the time transmitting out an RF signal with its associated RF transmission power wattage level would be expected to degrade its transmission power devices and circuitry faster than a transceiver used mostly to listen to incoming signals. Thus, a transceiver transmitting a signal most of the time may have a resultant faster degradation, shorter RUL, or shorter overall lifespan than the same transceiver used only for receiving a signal. In both cases the degradation or RUL determining methods may typically take into account differing unintended emission features or frequencies from the differing respective devices to determine the overall degradation of the equipment and expected RUL of the equipment piece as a whole.

The RULAS software may automatically extract from RF peaks found in the acquired emissions, the following: area under the curve (dB*Hz), Width at 10 dB down (Hz), Skewness, and Kurtosis metrics from raw emissions data. Those metrics may be used to generate representative models for the spectra features comparison portion of the software. The model may represent the aging trends of the metric vs time to correlate the observed metrics with device age/health.

The Kernel Function, given by the Equation 1 below, may be used to assist in this determination.

$$K ( x , t ) = \frac{{e}^{( \frac{- ( {x}^{2} + {t}^{2} )}{2} )}}{\sqrt{2 π}} \qquad ( 1 )$$

where:
K (x,t)—kernel functionx—a metric value,
t—a time value, and
h—a bandwidth parameter that controls the spread of the kernel.

This bivariate kernel estimator generates a heat map that has metrics on the y-axis, time on the x-axis, and probability on the z-axis and has the form and that may be represented by a Probability Density Function in Equation 2 below

$$Probability Density ( x , t ) = \frac{1}{n} {\sum }_{i = 1}^{n} K ( \frac{( x , t ) - ( {x}_{i} , {t}_{i} )}{H} ) \qquad ( 2 )$$

where:
n is the total number of data points in the data set,
K is the kernel function, and
H is the smoothing matrix.

The probability density estimator may be used to create a 3D heat map that will be used as a model for comparison.

Calculating PDF may be by using a non-parametric kernel density estimation. The basic kernel estimator is given below by equation (3):

$$\hat{f} ( x ) = \frac{1}{nh} {\sum }_{i = 1}^{n} K ( \frac{x - {x}_{i}}{h} ) = \frac{1}{n} {\sum }_{i = 1}^{n} {K}_{h} ( x - {x}_{I} ) \qquad ( 3 )$$

where:

$${K}_{h} ( t ) = K ( \frac{t}{h} ) / h$$

f(x)—density function
h—bandwidth or window width
n—number of points within the bandwidth
K—kernel
Kₕ—kernel K scaled by bandwidth h
(x-xᵢ)—Euclidean distance between each point i and the location where the density estimator is worked out center point of a cube
t—a point.

The kernel estimator is the arithmetic mean of n independent and identically distributed random variables. The kernel is then normalized to ensure that the probability is 1 when integrated over the entire function. At a given measurement of the metric, a 2-D probability distribution may be readily calculated and may provide a most likely value for RUL.

Once estimated device status is calculated, RUL can then be determined. A logarithmic functional relationship is determined, and for each potential parameter set the likelihood that those parameters describe the measured data is calculated. A 2-dimensional PDF is created based on those likelihoods, with a 1-dimensional PDF calculated based on the amount of time the device has been aged.

In an example, there may be 30 regions identified, and there may be 4 separate metrics derived from the curve fit software which means that there are 120 representative models that have been generated for use in the health assessment/RUL portion of the software.

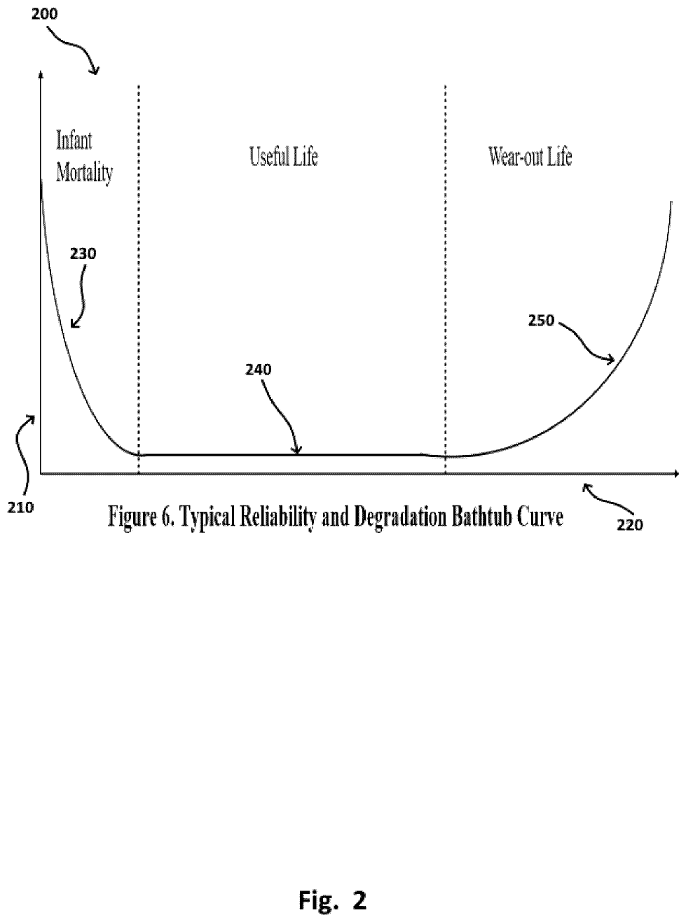

The models generated from the metrics extracted typically do not exhibit a linear trend, but instead, they may reveal a pattern known as the “bathtub curve”, as seen in FIG. 2. This curve represents the various stages an electrical device goes through during its lifecycle. At the initial phase, known as the burn-in period or setting period, the curve exhibits a high rate as the device undergoes stress testing and stabilizes. This phase helps identify any early failures or weaknesses in the device.

Following the burn-in phase, a significant portion of the trend remains relatively flat. This flat region indicates that the electrical device is operating within good operational conditions and experiencing normal wear and tear. This stable period may suggest that the electrical device is functioning reliably without a high degree of significant degradation. However, any deviation from this flat trend may serve as a valuable indicator that something might be amiss. An abrupt change or departure from the stable region may signify an emerging issue or an impending failure. This deviation may alert maintenance personnel to take proactive measures, such as conducting inspections, performing repairs, early replacement, or implementing appropriate countermeasures, to address the potential problem before it escalates.

The flat portion of the trend, therefore, may serve as a benchmark for the normal operational behavior of the electrical device. It may act as a reference point against which deviations may be measured, providing valuable insights for timely maintenance actions, and may ensure the overall reliability and longevity of the equipment.

Three potential methods may be used for comparing extracted metric data for the age comparator section of the code; these methods are as follows:
Method 1—Pooling age estimates from comparisons to distribution at each time stamp of emissions data
Method 2—Mahalanobis Distance to combine metric models into single curve
Method 3—2D bivariate kernel estimation to obtain probability density function (PDF) for each metric

The results may be used to create a method for a 2D Kernel Estimation workflow.

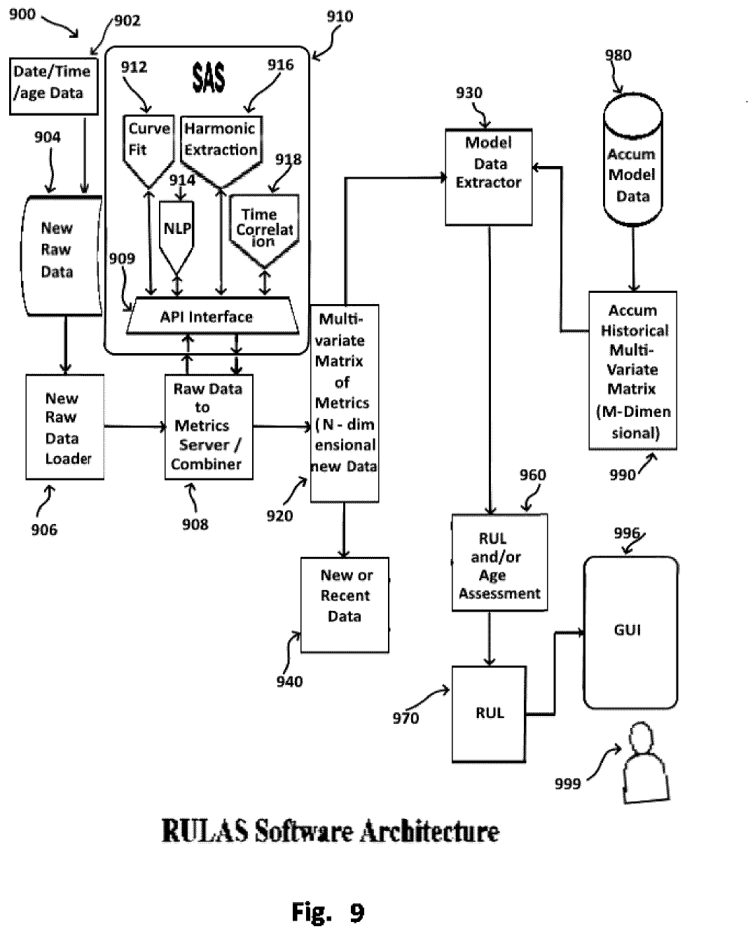

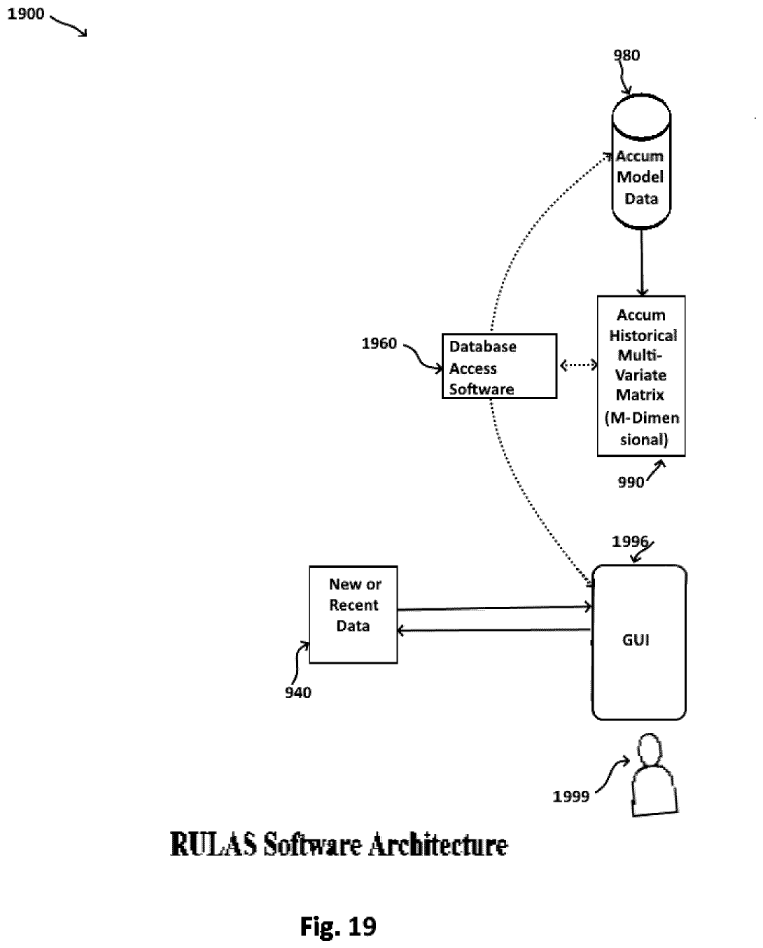

The following illustrates an exemplary design of a RULAS software tool that may allow users to compare collected data from an asset to an aging model, as well as collect periodic data from assets to build an aging model as device of in-situ solutions. The software architecture is outlined in FIG. 9 and FIG. 19.

The RULAS software developed may allow for automatic metric extraction from the SAS modular algorithms. The processed metrics may be processed to form the multivariate models for age comparison via a 2-D kernel estimator process. A code may be developed to allow this process to occur with the SAS software.

The sub sections of model architecture design may be generated to be used during processing. The subsections may include Raw Data Loader, Automatic Metric Extraction and Multi-Variant Data Storage, Multi-Variant Matrix Organizer, Aging Model (Data Storage), and Age Comparator (2-D Kernel Estimate).

The Automatic Metric Extraction and Multi-Variant Data Storage sections of the code may be done in parallel due to their connected nature of processing. The Automatic Metric Extraction module may be used to accurately capture essential metrics from the raw spectral data. Simultaneously, the Multi-Variant Data Storage system may manage diverse data inputs with varying complexities. The software may handle different data formats and sources.

A Multi-Variant Matrix Organizer of the RULAS software may accurately store extracted metrics data, and properly retain metric for region identifiers and associated original data from which the metrics were derived.

Exemplary rows and columns of a multi-variate matrix output by the RULAS software may align with specific regions of prognosticative value and metrics that are specified. This correspondence serves as a function of the Multi-Variant Matrix Organizer within the software. The precise mapping of the specified region and metrics to the corresponding rows and columns effectively stores and organizes data in a well-structured manner.

The last section of the code may be the age comparator (2-D kernel estimation). This section of the code is responsible for generating the 3D probability density function to display the results of the collection compared to the model data.

The Raw Data Loader, Automatic Metric Extraction Tool, Multi-Variant Data Storage Tool, Aging Model Data Storage Tool, and Age Comparator tool of the RULAS software's may be used as a dependable tool for prognostics, health management, and predictive maintenance across various industries. This may generally be applied to the field of predictive analytics and condition-based maintenance.

An Allan Bradly PLC may be used for accelerated life testing via thermal cycling. A thermal chamber may be used to perform the thermal cycling and to conduct a thermal cycling procedure. The implemented procedure followed industry standards for accelerated age testing, such as stressing the device at the maximum and minimum operating temperatures, having the device active and operational during cycling to induce wear representative failures, and maximizing the number of cycles between high and low temperatures.

An accelerated aging procedure which may be used may be as follows, the temperature cycling profile sets a high temperature of about 65° C. and a low temperature of about −20° C. (operating temperature as stated in the exemplary PLC's data sheet). The ramp time to high, ramp time to low as well as high and low soak times are each set at 1 hour to maximize the number of cycles based on the temperature rate of the chamber. Simultaneous to the thermal cycling, the PLC may be running an operation; this operation controls all inputs and outputs simultaneously operating in parallel with a switching rate of 10% of the maximum switching rate (10 msec). The inputs are connected to the outputs via a wiring harness to have the inputs read in the output values to leverage multiple functions within the PLC.

Using the NLP algorithm, a trend has been found where as the PLC ages, the number of modulation components increases. This trend occurs at several frequencies' regions, including those regions related to the driving clocks of the PLC. A region related to a non-clock function of the PLC may also exist where a consistent and definitive increase in the number of modulation devices has occurred which may also indicate an increased variance in the value of the modulation frequency.

The variance in the modulation frequency may be a key detail in the unaged state of the PLC as there is no modulation expected. The source of this new modulation frequency, which is strengthening as aging time increases, is related to the aging effects that are impacting the electrical circuitry. Modulation frequency causes intentional or unintentional mixing of signals via bit stream messages on a clock signal or cross talking of wires. Therefore, the presence of a new modulation feature can be correlated to unintentional cross talking arising within the circuitry.

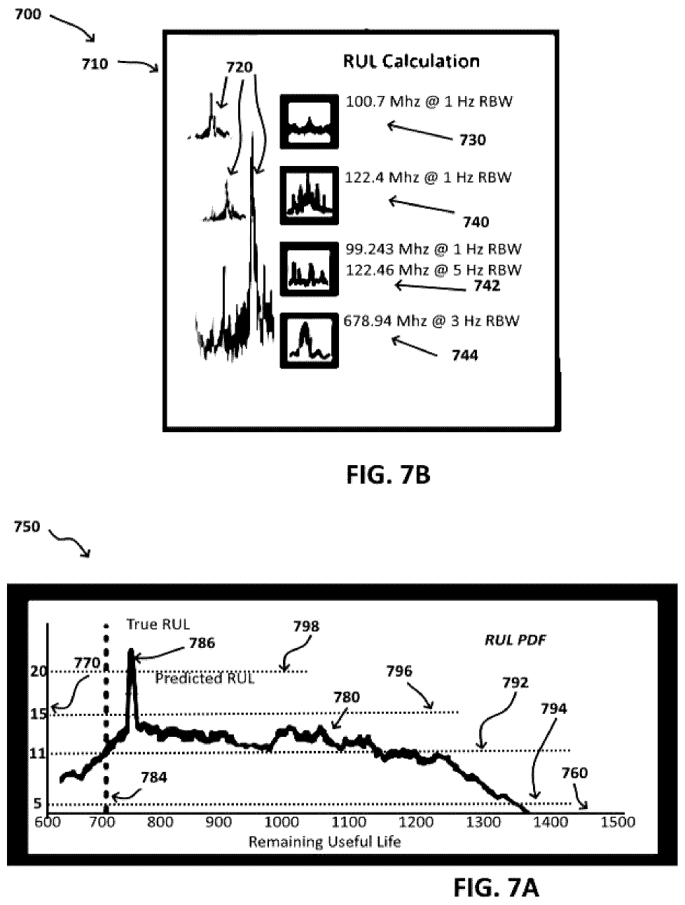

A typical emission feature may be a peak or frequency-width broader peak-like region within a frequency region. The Advanced Curve Fit module may output four useful metrics in the form of area under the curve (dB*Hz), Width at 10 dB down (Hz), Skewness, and Kurtosis. This may detect frequency regions where the structure of a harmonic peak has changed with increased aging time. In the emissions data of the frequency regions, the key metrics for observing the aging trend may be the area of a peak's region under the curve and the span or width of characterized peak emission feature above the noise floor. When degradation occurs to a peak's structure noise is being unintentionally generated somewhere within the source of the emission. As it is well known that the two emissions shown are related to clock functions it is evident that though the clock of the PLC is still operational the clock signal is becoming noisy. A noisy clock signal can cause several undesired effects that propagate throughout the PLC's circuitry. FIGS. 7A-7B illustrate possible exemplary RULAS Graphical User Interface (GUI) information for a user.

RULAS may offer Condition Based Maintenance Plus (CMB+) and many other enhanced and automation assisted prognostic maintenance approaches such as RF signature analysis for both device health and RUL prognostication.

### Electrical Health Monitoring of Avionic Systems

Electrical health and prediction of remaining useful life have been successfully determined based on real time analysis of signature changes that occur because of device aging on electronics scaling from individual devices to fully populated avionics. High accuracy has been achieved in electronics health status determination for multiple types of LRUs, demonstrating the robustness of the developed method for analyzing changes in electrical device emissions. Characteristic signature changes observed with device aging and circuit degradation have been found such as the progressive degradation of the non-linear mixing products and phase noise evolution of a Global Positioning System (GPS) unit beginning from its unaged state through the tenth week of aging.

### Electronics Reliability Assessment

An emission signature analysis may be successfully utilized for assessment of electrical device reliability. Changes in emission signature metrics from baseline values were tied to degradation in device performance, reliability, and expected useful lifetime. This technical approach was additionally applied to anomalous devices detected through testing performed at a site of a contractor. An example from these results may be where a shift in distribution for non-linear mixing product characteristics and emitted power is key indicator of reduced device performance and reliability. In general, a broadening of metric distributions was found to indicate reduced device reliability while a shift in mean value was linked to changes in device performance or timing.

The analysis may focus on more than one parameter of the RF emission. The parameter may be chosen as an output signal at an output pin of the electrical device. The parameter may be chosen as a functional performance of the electrical device at each iteration. Functional performance of the electrical device may be tested at each iteration. Functional performance testing may include determination of whether or not stress changed functional performance. The test may continue until the electrical device has been stressed with all relevant or predetermined doses or levels. The test may continue until the electrical device exhibits changes in the electrical device's operation or emissions. The changes in the electrical device may include general tolerance allowances from device design to function degradation due to stress.

The parameter of the electrical device not exposed to stress may be chosen as a baseline parameter when an operation of the electrical device is not modified from its original design and when the electrical device is not stressed by external factors. The same parameter of the electrical device exposed to stress may be compared with the baseline parameter.

The testing may be performed by testing the electrical device in a fixture. The fixture may be referred to as a test fixture. The fixture may be designed with a socket to receive the electrical device. The fixture may be designed as a test device that is coupled to the electrical device via connectors. This design may be suitable to test a board-level assembly.

The fixture may be designed to energize the electrical device. The fixture may be designed to energize the electrical device with a power signal connected to a power input pin of the electrical device. The power signal may be provided as a voltage supply. The power supply may be provided through a step-down transformer when the electrical is designed to operate at a lower voltage than a voltage available from a power grid. The power signal may be provided as a power supply with a modulation, i.e. modulated power input. Modulated power input may help to generate additional signature characteristics as well as provide a known source of signal for examination of device functionality changes.

The fixture may be designed to energize the electrical device with a clock signal connected to a clock input pin of the electrical device. The clock signal source may be generated by an external oscillator. The clock input may be provided as a sinusoidal input. The clock input may be provided as a high precision oscillator sinusoidal input, using a high precision clock as a clock signal source. The clock input may be provided as a high precision oscillator sinusoidal input, using a rubidium clock as a clock signal source.

The fixture may be designed to energize the electrical device with a combination of a power signal and a clock signal, as described above. The fixture may be designed to energize the electrical device with a combination of a power signal and a coded instruction to utilize an internal oscillator function of the electrical device. In an example, a microcontroller is typically designed with an internal oscillator.

The fixture may be positioned within a hollow interior of a shielded enclosure during test of the electrical device. The shielded enclosure may shield the electrical device from external noise during testing. The shielded enclosure may reduce influence of a noise external to the enclosure from affecting capture of RF emission. The shielded enclosure may eliminate influence of a noise external to the enclosure from affecting capture of RF emission.

A plurality of electrical devices may operate within the chamber. Each electrical device from the plurality of electrical devices may be removed from the chamber at a different time from removal of other electrical devices for analysis of their RF emission. This arrangement provides for an incremental or iterative analysis to determine the effects of operation onto the electrical device. The incremental analysis may also be used to determine an age of the electrical device associated with the loss of functionality.

The analysis may include capturing the RF emission. The RF emission may be captured while the electrical device is positioned within the fixture and energized, as described above. The fixture may be positioned within an irradiated chamber during testing of the electrical device. In other words, the RF emission may be captured during changing conditions within the device operation time chamber. The RF emission may be captured while the electrical device is positioned within the device operation time chamber and energized, as described above. The RF emission may be captured while the electrical device is positioned within the device operation time chamber, energized and cycled, as described above.

The RF emission may be captured as a raw signal with an antenna. The antenna may be integrated into the shielded enclosure. The antenna may be integrated into the irradiated chamber. The analysis includes converting the raw signal into a digital signal. Conversion may be performed by a receiver coupled to the antenna. The analysis includes processing a signature of the digital signal. The processing may be performed by a signal processing unit coupled to the receiver. The receiver and the signal processing unit may be integrated into a single unit. The receiver and the signal processing unit may be designed and provided independently from each other.

The receiver may be disposed within the shielded enclosure. The receiver may be disposed external to the shielded enclosure. The signal processing unit may be disposed within the shielded enclosure. The signal processing unit may be disposed external to the shielded enclosure. The receiver may be disposed within the irradiated chamber. The receiver may be disposed external to the irradiated chamber. The signal processing unit may be disposed within the irradiated chamber. The signal processing unit may be disposed external to the irradiated chamber.

The receiver may be designed with a sensitivity of a −145 decibel-milliwatts (dBm). The receiver may be designed with a sensitivity of a −150 decibel-milliwatts (dBm). The receiver may be designed with a sensitivity of a −160 decibel-milliwatts (dBm). The receiver may be designed with a sensitivity of a −170 decibel-milliwatts (dBm).

The receiver may be designed with a low noise amplifier (LNA). The LNA may be coupled directly to the antenna. The LNA may have a noise factor of under 2 dB. The LNA may be designed or selected to operate within a specific range, for example between 40 MHz and 100 MHz or within any increment thereof. The LNA may also operate at frequencies below 40 MHz or above 100 MHz. The LNA may be of the type as manufactured by Hittite Microwave of Chelmsford MA manufactured under model number HMC549MSBG. The LNA may be of the type as manufactured by RF-Lambda of San Diego CA manufactured under model number R04M96MSA.

The receiver may be designed with a filter disposed between the antenna and LNA and designed and operable to pass a specific or desired frequency range or band from the antenna to the LNA and at least reduce if not completely eliminate saturation, clipping and/or distortion of the signal from the antenna to the LNA. The filter may be a band pass filter. The filter may be an LC circuit. The filter may be a ceramic resonator, configured or selected to operate in a specific frequency range. The filter may be a band-stop filter configured to eliminate an undesired band of frequencies, a low-pass filter configured to allow passage only of frequencies below cut-off frequency or high-pass filter configured to allow passage only of frequencies above cut-off frequency.

The receiver may be designed with an analog to digital converter (ADC). The ADC may be designed and operable to transform received analog signal from the LNA to digital signal for further analysis and processing by the signal processing unit. The ADC may be of a RF ADC type as manufactured by Texas Instruments of TX under model number ADS5482. The receiver may be designed with a filter disposed between the LNA and ADC. This filter may be provided as a selectable filter bank. The selectable filter bank may comprise one or more filters, each configured and operable to separate the frequency signal from the LNA into devices. Each device carrying a single frequency sub-band of the frequency signal. The filter bank may be of a bandpass SAW wave type as manufactured by API Technologies of the United Kingdom.

The signal processing unit may be a computer. The signal processing unit may be designed as a custom controller. The signal processing unit may be designed with the FPGA. The signal processing unit may be designed with a processor and a non-transitory tangible computer readable medium and/or tangible computational medium comprising algorithms and/or executable instructions (computer program code) that when executed by the processor cause the processor to perform various method steps as disclosed in this document. The instruction may include instructions to process the signal in a frequency domain. The instruction may include instructions to process the signal in a time domain. The signal processing unit may be designed as a combination of the FPGA, the processor and the non-transitory tangible computer readable medium and/or tangible computational medium.

Tangible computer readable medium means any physical object or computer element that can store and/or execute computer instructions. Examples of tangible computer readable medium include, but not limited to, a compact disc (CD), digital versatile disc (DVD), blu-ray disc (BD), usb floppy drive, floppy disk, random access memory (RAM), read-only memory (ROM), erasable programmable read-only memory (EPROM), optical fiber, etc. It should be noted that the tangible computer readable medium may even be paper or other suitable medium in which the instructions can be electronically captured, such as optical scanning. Where optical scanning occurs, the instructions may be compiled, interpreted, or otherwise processed in a suitable manner, if necessary, and then stored in computer memory.

Alternatively, it may be a plugin or device of a software code that can be included in, or downloaded and installed into a computer application. As a plugin, it may be embeddable in any kind of computer document, such as a webpage, word document, pdf file, mp3 file, etc.

The antenna, receiver and the signal processing unit, as described above, may be integrated into a single apparatus. The single unit may include an enclosure. The single apparatus may be designed with a capability to collect uniquely high acuity electromagnetic emissions signature data for electrical devices, boards, and systems. The single apparatus may comprise a Real-Time Spectrum Analyzer and may also provide capability to power, provide clock signal, and substantially shield electronics under test from external RF noise. The single apparatus most may be designed to achieve a sensitivity of −170 dBm. Collected data can then be processed and used to detect device degradation and, more importantly, can be used for aging assessments and RUL prognostication. The method used to determine aging assessments and RUL prognostication may be called RULAS herein. The RULAS capability in association with apparatus may provide improved operational readiness and reduce the costs of maintenance. A spectrum analyzer or Real-Time Spectrum Analyzer (RTSA) may also be used to collect the electromagnetic emissions signature data but may not achieve as high degree of accuracy, sensitivity, or evaluation speed throughput.

The apparatus may be used to nondestructively analyze the unintended radiated electromagnetic emission signatures of a variety of electrical devices. Unintended emissions occur naturally when any electrical device is powered. Emission signature characteristics change when the device degrades, is used, or is otherwise altered. The analysis of these changes can assess the overall state of device health and isolate contributions associated with specific signatures of potential damage, fatigue, and other reliability issues. Emissions detected and assessed by RULAS may be causally dependent on the layout and integrity of the integrated circuit. As a device ages, emissions signatures change in a predictable and deterministic manner. This results in a reliable assessment of device readiness and, therefore, RUL. This may thus provide a revolutionary, multi-function tool capable of prognostication of device RUL.

Analysis of the emission signal may be performed on a digitized emission waveform, as may be exhibited by a spectrum analyzer. The spectrum analyzer may be designed as a combination of a circuit assembly and a display. The user may use the display to visually select RF signature parameter of interest from the waveform. The user may use the display to visually select a frequency region of interest from the waveform. The signal processing unit may be designed with the spectrum analyzer. The signal processing unit may be designed to output the waveform as a print file.

In this document, functionality of the electrical device may be described as a working condition of the electrical device, and may be referred to as operational, irradiated to a degree, likely to imminently fail, or beyond useful life. Operational here may mean that the electrical device is in full specified working order, with no functional hardware flaws and fully functioning sub-devices and/or components. Altered or additional functionality may refer to deviations from operational status that damage, degrade, or otherwise change the performance of the electrical device. A comparison may be made to a baseline measurement of a known electrical device with designed functionality and being in an unaltered condition.

Analysis may include frequency changes of a modulated signal where the modulating signal's frequency in occurrence for a given time interval. This frequency change may be observed as a measured spacing between the side band peaks shown in the figure. A signal change may be related to an alteration of a clean precise clock frequency, where as a clock ages in the case of an oscillator or degrades in other cases, the shape of the resulting clock harmonics in the frequency domain will undergo two changes. The first change is that the base of the frequency signal will widen because of increased phase noise, while the second is a movement of the harmonic peak in absolute frequency. For the case of crystal oscillators, the frequency of the clock will change with device operation time on a small scale (kHz), which is magnified as the harmonic index increase (as absolute frequency position increases). For other cases of degradation, the clock signal may degrade from one state to a new state, resulting in a dramatic change in the RF spectrum and in device functionality.

The electrical device may be tested by capturing and analyzing RF emissions in a frequency domain.

The electrical device may be tested by measuring/determining an operational output from the electrical device in a time domain.

The electrical device may be tested by capturing and analyzing RF emissions in a frequency domain and measuring/determining an operational output from the electrical device in a time domain.

Analysis of captured RF emission data may provide a threshold indication of transition and/or an evolution of degradation as doses of the environmental stress increase and effects of the exposure to the environmental stress accumulate.

The analysis may include identifying changes in the designed output as measured on the output pin. The analysis may include measuring changes in the designed output at the output pin. When the output is chosen for analysis, the output at the output pin may be monitored for toggling between the intended duty cycle and a new unintended duty cycle. When the output is chosen for monitoring, the output may be monitored for a change as device operation time increases. When the output is chosen for monitoring, the baseline steady state output may be monitored for a change to a new state where the output toggles between the intended duty cycle and a new unintended duty cycle. Change to the new state may indicate a degraded performance of the electrical device. When the output is chosen for monitoring, the output may be monitored for stabilizing at the applied device operation time where the output will not change due to stress of the electrical device with a next higher dose or level. In an example of a device operation time degraded shift, functional performance testing may include a determination of whether or not the device operation time degraded shift register misses data events in operation. In an example of a device operation time degraded shift, functional performance testing may include determination of whether or not the device operation time degraded shift register is associated with an increased bit error rate.

Degraded performance may include an output voltage that is above or below a designed range. Degraded performance may include an output frequency that is above or below a designed range. Degraded performance may include an output frequency that fluctuates in a new range between a first value outside of a designed lower range value and a second value being outside of a designed upper range value and is thus unstable. Degraded performance may include an output frequency that drifted from its fundamental value. Degraded performance may include a change in the envelope of an output signal waveform.

The output may be monitored in a time domain. The output may be monitored in a frequency domain. The output may be monitored in both time domain and frequency domain.

In the frequency domain, an absolute frequency position in the waveform may be measured by indicating the frequency value of the highest point of a peak or structure from a given spectrum. For harmonic outputs, an exact value of the position may aid in determining if a peak or structure belongs to a harmonic series. A harmonic series is defined by a fundamental value, this fundamental value is the first frequency value in the series. For example, for a harmonic series where the fundamental is 2.5 MHz the first peak in this series will appear at the frequency value of 2.5 MHz in a spectrum graph. Other peaks in the harmonic series are defined as indices multiples of the fundamental, for example 35 MHz is device of the 2.5 MHz harmonics series since 2.5 MHz times 14 is 35 MHz, while a peak at 35.3 MHz would not be a device of the 2.5 MHz harmonic series since 35.3 MHz divided by 2.5 MHz is not an index value. Furthermore, it is noted that the frequency difference, that may be referred to as delta “f”, between two harmonic peaks will be that fundamental value. The measurement from peak to peak in this case is an absolute difference from one absolute frequency position to the next. It is noted that evenly spaced peaks may not belong to a harmonic series where the spacing value X divided into the absolute frequency position of a given peak does not produce an index value. This set of evenly spaced peaks may be caused cause by another phenomenon.

Analysis of RF emissions from a stressed electrical device may be used to determine an operational threshold at a given dose or level of the stress. The operational threshold may be defined by a requirement that the output frequency does not toggle (change) to a new state. The operational threshold may be defined by a requirement that the output frequency may toggle to a new state where this new state is sufficient for at least limited operation of the circuit employing the electrical device.

While a single wideband frequency scan may be used to gain a high-level understanding of the effects of the irradiation, a repeated narrowband frequency scan may be performed on a frequency region over a period of time to gain more acuity on states of the output frequency.

A resolution bandwidth of the scan may be selected as 0.1 seconds. A resolution bandwidth of the scan may be selected as 1 second.

The signal processing unit may be designed to execute a curve fit algorithm on the emission signal. Spectral emissions from electronics are very rarely spectrally pure. Phase noise and jitter are two examples in real-life systems that force emissions in the frequency domain to have shape. This may be evident at the base of the emissions signature and the higher the sensitivity of the system the more this effect is prevalent.

Curve fit algorithm may be used to measure a peak amplitude at the center of a peak curve. Curve fit algorithm may be used to measure, in a frequency domain, a shape of a peak curve in a digital waveform of an emission signal. Curve fit algorithm may be used to measure, in a frequency domain, an area under a peak curve in a digital waveform of an emission signal. Curve fit algorithm may be used to measure, in a frequency domain, a shrinking of the curve over time. Curve fit algorithm may be used to measure, in a frequency domain, the sharpness of a peak curve in a digital waveform of an emission signal.

A curve fit algorithm may be utilized to investigate toggling of the output frequency states. The curve fit algorithm may discern a kurtosis outlier, an area under a curve outlier, and a selected width outlier to examine changes of the RF spectrum in a transition state of the output frequency between exposure to two subsequent levels of the stress. Curve fit may provide a measure of phase noise or jitter evolution as the electrical device is exposed to stress and ages or degrades as the result of the exposure.

The signal processing unit may be designed to extract metrics of the harmonically related emissions of the electrical device. The emission may be related to a clock of the electrical device. The emission may be related to switching metal-oxide-semiconductor field-effect transistor (MOSFET). The signal processing unit may be designed to execute a harmonic analysis. The character of the harmonic content and the fall-off of the harmonics are directly related to the shape of the clock or the digital waveform an electrical system generates. As the electrical device ages or degrades, the propagation of the clock through the electrical device due to degradation or device operation time of the junctions of the electrical device may cause the rise time or fall time slope of a waveform to become rounded, which results in a fall off the harmonic spectrum.

The signal processing unit may be designed to execute a non-harmonic analysis. The electrical device may be designed with numerous blocks of circuits (IP blocks in ICs) that have different functions and often reference different signals. By measuring the drift of signatures of one block compared to other blocks it may be possible to gain insight into how circuits are degrading or aging.

The signal processing unit may be designed to execute a time correlation algorithm. The emission signature may drift over time. Time correlation algorithm may be used to determine a consistently related frequency or amplitude drift of any two adjacent peaks in a digital waveform in the time or frequency domain of an emission signal. Time correlation algorithm may be used to determine a drift of a peak in a digital waveform of an emission signal over time. Time correlation algorithm may be used to determine a location of a first peak with a baseline frequency location and then its subsequent frequency change and correlate this change to a second peak's frequency drift.

Depending on the underlying circuit design, the emission frequency may drift from its specified fundamental frequency. A change in the drift may be indicative of irradiation. Measuring and tracking the drift may be used as an indicator of aging. A change in the drift may be indicative of degradation of the underlying electronics. Measuring and tracking the drift may be used as a measurement of degradation.

Frequency drift may be specified as a frequency tolerance for the electrical device. The tolerance may be specified as a curve. Plotting of a measured drift versus tolerance drift may aid in determining a remaining useful life (RUL) condition of the electrical device.

Time correlation may also provide a view into functionality of the electrical device. In this technique, the duration of time at which the output frequency may be in a toggling state until a new output frequency stabilizes is identified.

The time correlation may be used to establish an operational or a functional threshold for the electrical device. The threshold states of the electrical device may be used to improve a functional design of the electrical device when used in circuit applications. The threshold states of the electrical device may be used to design a circuit or improve a design of an existing circuit that may only operate at a lower output frequency than desired. The threshold states of the electrical device may be also used to determine applications where a given electrical device may not be used by comparing a dose of the environmental stress that the circuit may be exposed against testing of the electrical device at that specific dose.

The signal processing unit may be designed to analyze non-linear products (NPLs) which may arise from within the electrical device that comprises non-linear mixing of emission signals from the two adjacent traces in a time domain and then measuring a frequency modulation of the resulting emission. NLPs are sometimes the result of unintended non-linear mixing of signals within an electrical device or an assembly (board) of electrical devices due to their interaction with other clocks or signals within the device. One mechanism for NLPs may be a cross modulation, which occurs when two nearby wire traces carrying different signals interact. Crosstalk is induced when both signals are active, causing a modulation between a lower-frequency signal and a higher frequency signal. Modulation may be related to an unintended amplitude modulation in the waveform. Modulation may be related to an unintended frequency modulation in the waveform. Modulation may be classified as amplitude modulation or frequency modulation.

### a Non-Linear Product can be Briefly Described by Three Parameters:

The carrier frequency, f_{c}—a clock or other propagating primary signal being unintentionally modulated by another electrical signal within the electrical device, the carrier frequency may be also a frequency of a central peak;
The modulation frequency, f_{mod}—which is also the spacing between peaks; and
The number of peaks, n.

The NLP extraction algorithm may be designed to search the broadband spectrum for sets of peaks that fit this description and report the list of found NLPs to the user. The algorithm may also report the results to other software processing modules for further examination, processing and use which may include extracting metrics and statistics on the NLPs found such as number of peaks above noise floor, dB height of peaks, spacing of peaks, dB height relationships between peaks, and/or changes in the preceding over short or longer periods of time. If the user selects an NLP from a list, its devices may be identified visually on the displayed spectrum with a set of blue dots, and metric information extracted from that NLP may be displayed to the user. Additional metric information such as modulation indices (M-indices) may be also displayed. The user may then have the ability to sort, filter, or export the list of found NLPs.

The phrase RUL-artifact-metrics (RULam) refers to scalar or multidimensional value or values found to be of significance in determining RUL. They may include a frequency of a peak, a peak separation frequency distance, a peak height, a peak height range, a change in peak height, a first, second, third, or fourth derivative of peak location vs. another factor such as time or power level applied, or may be any other metric of significance found or derived from other RULam described herein or may be later found prospectively or retrospectively to be of RUL prognosticative value.

In view of the above, at least a method is provided for determining RUL for all electrical devices generally, especially semiconductor devices which may have been operating in circuits under unknown electrical conditions such as supply voltage variations or at current levels, for an unknown duration, under unknown loading, and under unknown environmental conditions such as temperatures and humidities.

In view of the above, at least a method is provided for a more sensitive, accurate, comprehensive, and robust solution which assesses an unlimited variety of semiconductor devices or subsystem health and RUL.

In view of the above, at least a method is provided for determining RUL on a periodic, sporadic or even one-time basis and not only by continuously monitoring equipment or devices under use.

In view of the above, at least a method is provided for determining RUL without the interruption of normal operation of such devices or systems.

### Now, in a Reference to FIGURES.

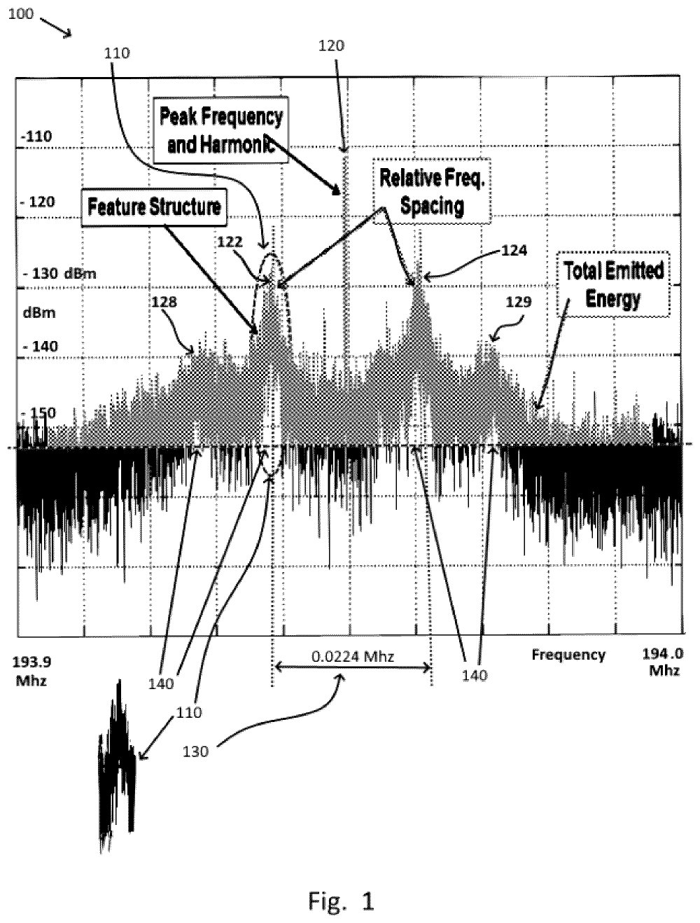

Referring to FIG. 1, a specifically chosen exemplary unintended RF emissions spectrum is illustrated which may exhibit characteristics useful in determining RUL, aging, degradation, device accumulated life, a cybersecurity attack, or a device compromised for cybersecurity intrusion purposes. Features seen which may be of value include the feature shape or structure 110, peak frequency separation distance 130, number of symmetrical peaks within region by counting 128, 129, 122, 124, and 120 to yield a metric=5, and/or total area under the curve above the noise floor 140.

Referring to FIG. 2, graph 200 illustrates the ‘Bathtub Curve’ of device lifetime wherein many devices fail early as seen in section 230 of the curve, the remaining devices continue to function as seen in section 240 of the curve, and gradually begin to fail at end of life as seen in section 250 of the curve. Element 220 is the X-Axis time and Y-axis element 210 is the quantity, percentage, or probability of failure. This curve shows typical failure profile seen in devices examined by the Subject Matter methods.

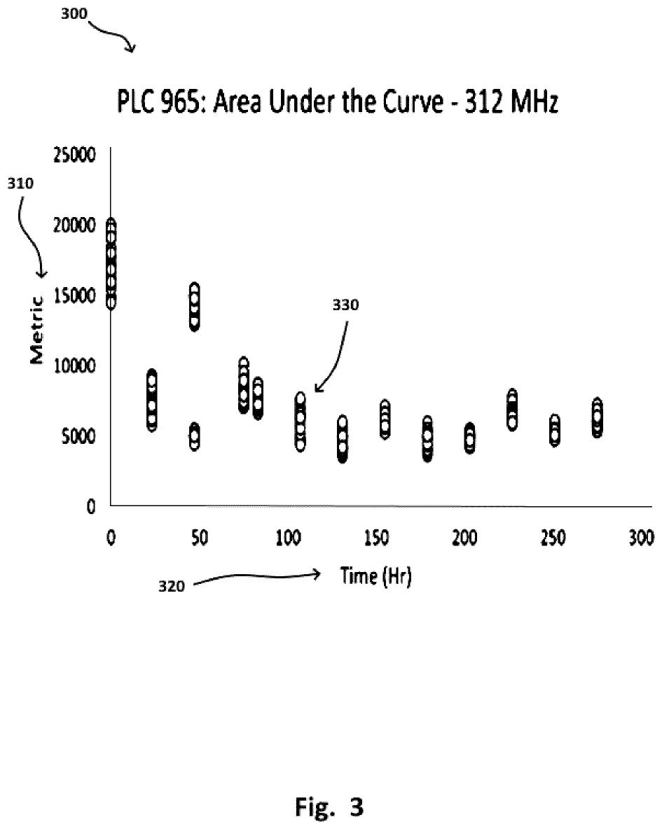

FIG. 3 illustrates a sample set of distribution of Device metrics data points 330 vs. time 320 which typically may be gathered for a device. The time 320 may be known age of device, accelerated aging time, estimated time form acceleration process, or age at failure. Device metrics data points 330 may be derived from specific devices under test.

FIG. 4 illustrates devices within a system such as a PLC which may degrade, age, or fail over time. The Subject Matter may be used to predict RUL, aging, or degradation of not only a single device, but also a board, assembly of devices, or a whole system. FIG. 4 also illustrates a vast amount of signature content 400 present in the PLC. The major components within the PLC include but are not limited to those illustrated in FIG. 4. More specifically, the content 400 is illustrated as including a sub-content 410 directed to a microcontroller which reads in the following clocks-8 MHz, 16 MHz, Binary clock, and controls all input/output (I/O) functions and controls the clock dividers of the 4 MHz. The content 400 is also illustrated as including a sub-content 420 directed to switching power supplies that includes metal-oxide-semiconductor field-effect transistor (MOSFET) and other high-powered circuits. The content 400 is also illustrated as including a sub-content 430 directed to solid state and manual relays to control inputs and outputs of the PLC for regulated system operation. The content 400 is also illustrated as including a sub-content 440 directed to non-volatile random access memory (RAM) that stores programming code, stores logic and stores measured output values. The content 400 is also illustrated as including a sub-content 450 directed to communication including universal serial bus (USB), serial, RS232C serial, WiFi, and ethernet. The content 400 is also illustrated as including a sub-content 460 directed to display screen for controls and programming controls.

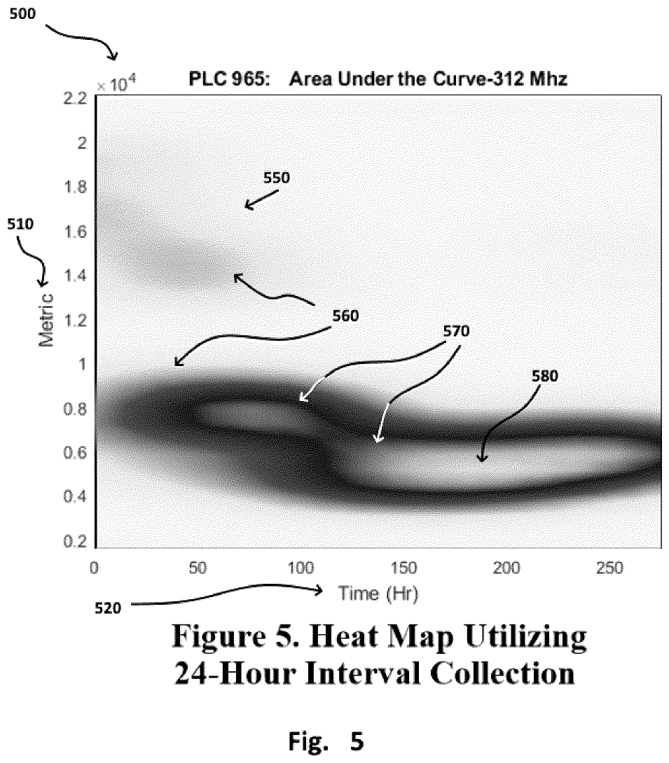

FIG. 5 illustrates a heat map 500 generated from acquired device data wherein Y-axis 510 represents the RULam metric derived from spectrum data, X-axis 520 represents the time or duration of device operation such as time point of failure, total time of operation thus far, or known RUL found for the device in the future. Region 550 is an outlier region with a lower probability density. Element 560 points to all probability density regions, wherein the integrated density should or will approach 100% (except for the region's far right edge which is not shown). Devices which lie beyond the far-right edge limit of the graph may not be known because they have not failed yet nor failed within the test time data gathering period. Region 570 is regions of higher probability density and the point at 580 is the likeliest Metric and associated time for a device.

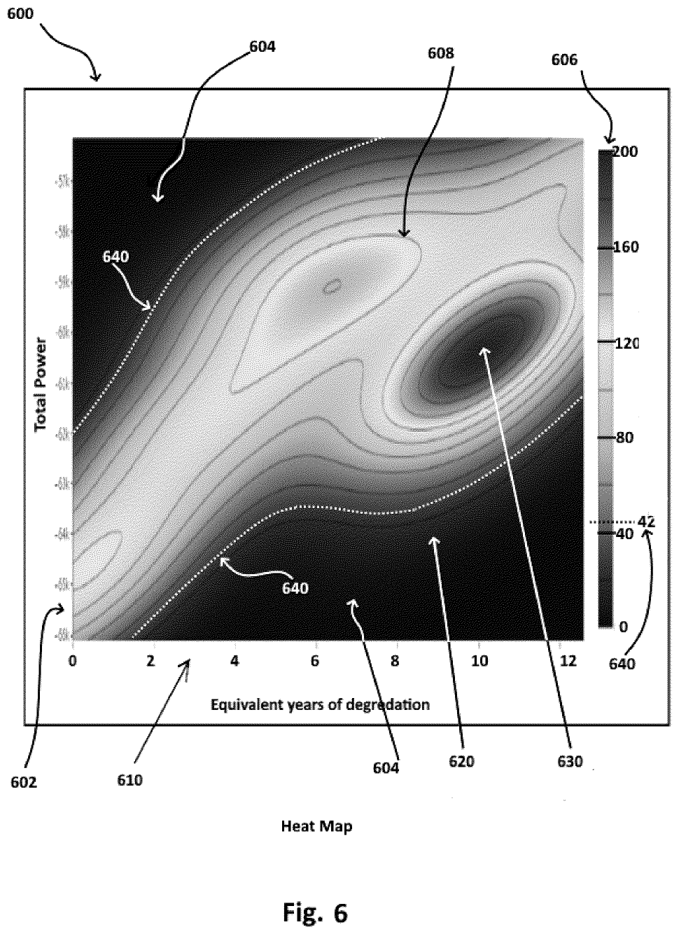

FIG. 6 illustrates a heat map 600 generated from acquired device data wherein Y-axis 602 may represent the spectrum data such as dBm value from −57 dBm to −66 dBm, alternatively, the Y-axis may represent a derived calculated spectrum data artifact such as peak separation in a specific frequency region or a composite calculation of multiple calculated spectrum data artifacts combined. Alternatively, Y-axis 602 may represent Total Power applied to a device or total load into a device in watts. X-axis 610 may represent the time or duration of device years of degradation thru actual age or calculated accelerated aging. Density coloration or Z-axis 606 may represent the probability density of occurrence of a device at those X, Y axes coordinate region, or represent a probable RULam metric derived from a single RULam or a combined RULam calculation such as a sum, weighted average, polynomial calculation, output of a Neural Network, or other means of combining multiple RULam metrics into a single number. Individual RULam values may be peak spacing at a specific frequency region which has been found to be of device aging significance, Area under the curve at a specific frequency region which has been found to be of device aging significance, Harmonic Correlation at specific frequency regions which have been found to be of device aging significance, or other measurements of aging significance described herein. Element 604 may point to a region of no device occurrence or zero probability whereas 620 may point to the region where the majority or a substantial number of the devices are found to exist. Element 640 may point to a probability density of 0.42% or alternatively may mean a RULam value of 42 which is seen to be distributed in the heatmap and corresponds to a specific derived RULam value occurring such as a peak separation frequency distance value. Element 630 may point to the region of highest probability density or where the devices are most likely to occur, possibly in percentage, probability density, RULam dBm. Here, if the chart Z-axis is probability, most sampled devices are seen to be about 10 years old. Alternatively, if the chart Z-axis is a RULam metric, most sampled devices are seen to have a RULam metric of almost 200 corresponding to about 10 years old.

Referring to FIGS. 7A-7B, FIG. 7A illustrates a method 700 and FIG. 7B illustrates 750 results for calculating individual RULam. Element 710 illustrates 4 frequency regions of RUL-significance. Element 720 illustrates spectrum features which may be found within broadband or narrowband data and examined for RUL-significance, which may or may not later be determined to be of significance as the device ages. Element 730 illustrates a region of RUL-significance and its outline and characteristics including frequency location, dB level, and measurement parameters used to find and/or best capture its data. In this case, ‘best’ may be a tradeoff of acquisition speed vs RUL-significance usefulness judgement. Similarly, Elements 740, 742, and 744 illustrate other separate regions of RUL-significance and their outline and characteristics including frequency location, dB level, and measurement parameters used to find and/or best capture their features and data. Element 750 illustrates a result of the Technical Subject in graph form wherein Element 760 is the RUL, Element 770 is the RULam or a calculated aggregated result metric of multiple RULams for the device, Element 780 is the resulting graph of RUL from a group of exemplary historical set of devices, Element 784 is single device ground truth, or point in time that a device may be currently at within its predicted Remining Useful Life and generating a RULam of 11. Element 786 is a region and point of greatest probability for RUL. Elements 792, 794, 796 and 798 are RUL-extracted associated-metrics at various shown values. As can be seen from this, any devices with a RULam above 15 are most likely to have an RUL of about 760.

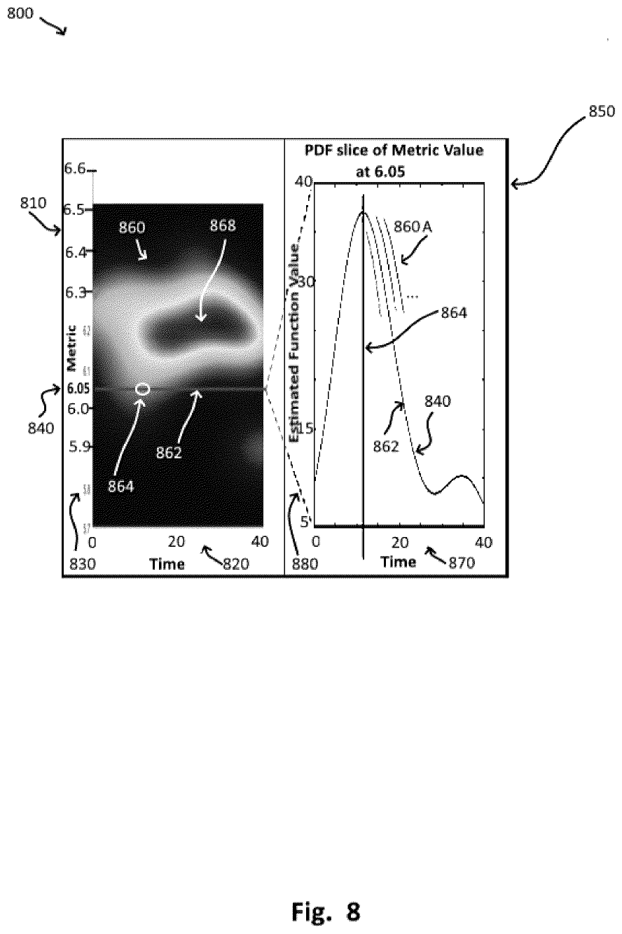

FIG. 8 illustrates a 2-D Kernal method, a heat map and interpretation thereof wherein a heatmap and slice of heatmap 800 illustrates the 2-D kernel method applied to determine a RUL probability distribution of time vs. a given RUL-significant metric value. A cross-section of the heat map provides a probability distribution for a given metric value. FIG. 8 also illustrates a maximum likelihood of 11 hours with a probability of 0.036. A likelihood function is determined for each matric based on measured parameter value. This determines the most probable time (age) value. Heatmap 810 illustrates a heatmap of an exemplary device aged to failure wherein failure time is on the X-axis Failure Time 820 and may have been aged in accelerated aging time or in real age time before the device failed. The Y-axis results Metric 830 may be a derived RUL-significant metric such as peak separation frequency distance in kHz between two peaks found to be RUL-related. RUL metric region slice 840 at value about 6.05 selects a Cross Section 862 of values within the derived Heatmap 860. Heatmap Co-ordinate region 864 at about 12 hours aging and RUL metric value about 6.05 contains a specific heatmap region value of a probability of 0.038. Heatmap highest probability region 868 at about 25 hours aging and RUL metric about 6.25 has a region value of a probability of about 0.092. If this heatmap 810 were displayed on a Gui such as Gui 1996, the Heatmap would likely be in color and its gradients more discernable than the Black and White illustration 810 seen in FIG. 8 for patent application content purposes.

Further in FIG. 8, chart 850 shows heatmap PDF and slice of Metric Value 840 at Metric about 6.05 illustrates RUL metric region as slice 840 in detail. The Cross Section of curve 862 whose axes are X-axis Failure Time 870 and Y-axis probability range 880 of 0.005 to 0.040 show the RUL metric region slice 840 probabilities clearly where Heatmap Co-ordinate region 864 at about 12 hours aging shows the highest likelihood of failure probability of 0.038 for the RUL metric region slice 840 at value about 6.05. Conceptually, other RUL metric region slices represented by 860A would represent other slices of heatmap 810 each with a different unique RUL metric region slice value.

FIG. 9 illustrates a software architecture which may be used to determine RUL, aging, degradation, or the like. System 900 illustrates a possible design for the Software Architecture as a whole. Subsystem 902 illustrates a means to capture relevant device data such as device date, time, storage location, test equipment and equipment characteristics used to acquire the RF emission data, equipment from which it came, and/or device age which may be key to gathering device metrics associated with RUL, the environmental conditions under which the device was stored or operated, device usage or utilization data, or key to determining when the device data was taken. Other data which may be collected and may be associated with the device may include device number, batch number, supplier, serial number, or a photo of the device's case. Data 904 illustrates a data storage location where any of the data collected in Subsystem 902 and RF emissions broadband and/or narrowband data may be stored, searched, and/or accessed such as a database. Data loader subsystem 906 illustrates software which may be used to search, select, or access the data in 904 and transfer the resulting data to another storage location and/or software module. Element 908 illustrates a software module which acquires the data from 906 and uses SAS 910 to find and extract RUL-significant metrics from the data from 906. The Metrics found are then added to the Matrix 920 which may contain other recently extracted metrics. Element SAS 910 illustrates a software module capable of processing and searching RF spectrum data to find RUL-relevant features and then generating derived metrics to quantify those features. Processing within Element SAS 910 may include Curve Fit 912, Non-linear Products NLP 914, Harmonic Extraction 916, and Time Correlation 918. Element database 980 illustrates a data storage or database containing accumulated and/or historical data of exemplary devices previously processed. This data may include the corresponding relationships or correspondence between device age, degradation, or RUL and the spectrum features and/or metrics found to be associated with them. The database 980 then is used to periodically, occasionally, sporadically, and/or immediately build, populate, or update the immediately or eventually needed devices' RUL-related information or load all devices to be within the Historical Multi-Variate Matrix 990. The Historical Multi-Variate Matrix 990 contains all accepted and exemplary devices' RUL-related information needed to determine RUL, age, authenticity, or degradation level of a device of the same type or model number. The database 980 and then Historical Multi-Variate Matrix 990 are refined, updated, or populated with new devices' data as illustrated in FIG. 19. The Model Data Extractor 930 then pulls the new data's Metrics from the Matrix 920 of Metrics, finds and pulls the device's corresponding exemplary data from the Historical Multi-Variate Matrix 990, and prepares the data for RUL determination. The RUL, age, and/or degradation Assessor 960 then processes and compares the metrics of the new device with the exemplary metrics from the Historical Multi-Variate Matrix 990 to determine RUL results data 970. Other information such as device serial number, RUL probability, RUL percentile, Device manufacturer, device batch number may also be retained to be passed forward. The results of the RUL, age, and/or degradation Assessor 960 contained in the RUL results data 970 may then be accessed by the GUI 996 as directed by its operator 999 for further devices related actions such as placement in an acceptable devices bin, rejected devices bin, further examination arts bin, or may be immediately or eventually added to the existing device's database 980 as illustrated in FIG. 19.

The Historical Multi-Variate Matrix 990 may also be a Multi-Dimensional Matrix with an arbitrary number of dimensions depending on the criteria found underlying anomalies or emission artifacts related to aging or degradation in a device, sub-system, or system. The Matrix 990 is necessary to describe or contain RUL-related information contained in the much more voluminous contents of the possible broadband data from a device or devices. As a slower, more proprietary, or more complex alternative, a Database, Clustering Analysis, Regression Analysis, Multivariate analysis, or the many types of statistical metrics may be used in addition to the Matrix approach illustrated in the Subject Matter, or as a parallel equivalent approach with their own idiosyncrasies and complexity trade-offs.

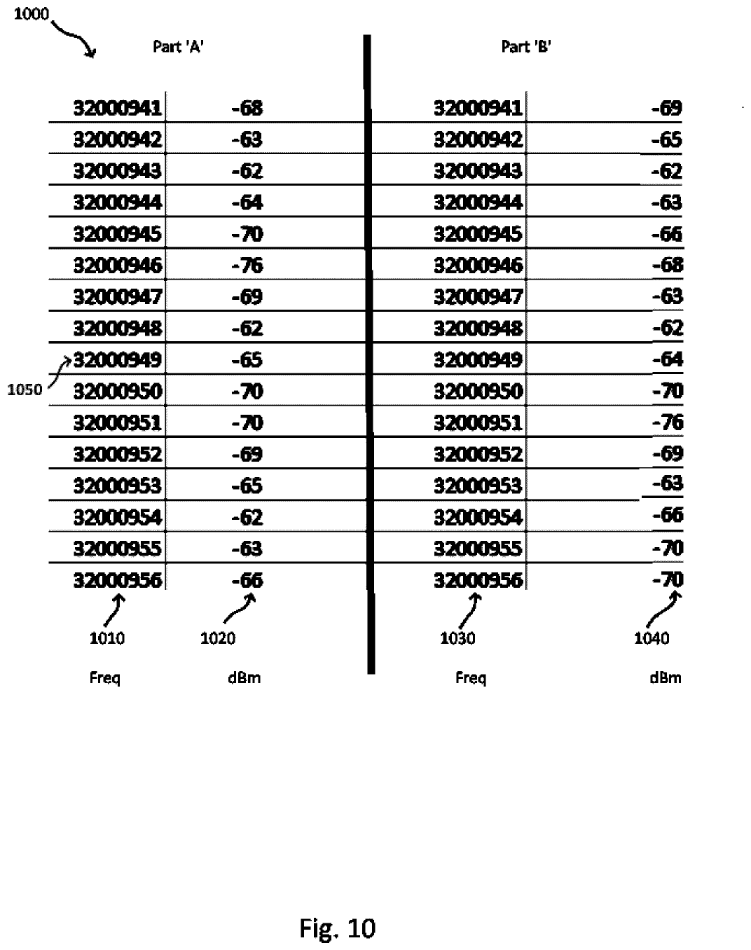

FIG. 10 illustrates details (data samples) of two separate device's spectrum data for the same frequency which may populate the database 980. Column 1010 illustrates frequencies or frequency regions for Device A taken at 1 Hz RBW and column 1030 illustrates frequencies or frequency regions for Device B taken at 1 Hz RBW. Column 1020 illustrates exemplary dB or dBm values found at the corresponding frequency point shown in column 1010 for that device, Device A. Similarly, column 1040 illustrates exemplary dB or dBm values found at the corresponding frequency point shown in column 1030 for that device, Device B. Row 1050 at frequency 32000949 Hz is seen to contain −65 dBm for Device A but-64 dBm for Device B. Many such frequency regions 1000 to be used as RUL-significant data for a device may comprise database 980. Exemplar data points collected and loaded into RULAS (frequency versus dBm).

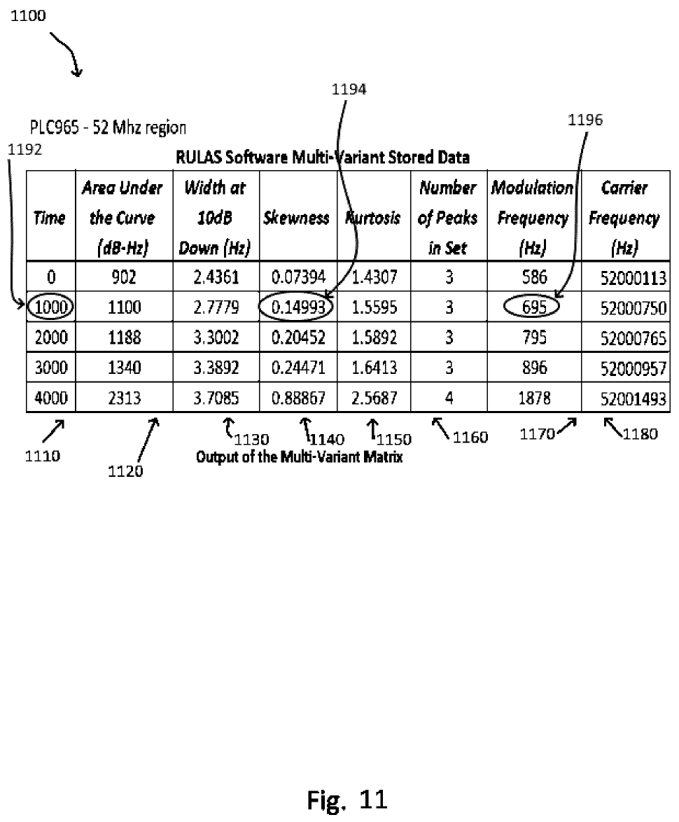

Referring to FIG. 11, illustrated is a Multi-variate Matrix 1100 of 5 devices with the same device number which may contain the Time 1110 metric which may be date and time, seconds past a date such as Jan. 1, 1970, or other time measurements such as milliseconds past device being powered for the first time. Multiple time columns may exist such as time of device purchase, time of device failure, duration time of operation, time of initial operation, time of RF emission spectrum acquisition and/or characterization, time of exposure to a condition, and so forth. Time may be a duration, point in time, accumulated time under a condition, time of failure, time of observation, RUL time determined at end of life, time when a device exceeded a degradation limit value, or timetable of degradation measured vs. exposure time accumulated.

Area-Under-The-Curve 1120 metric may be total area in dB*Hz of area above the calculated noise floor of a frequency region consistently found to be of RUL-significance.

Width-at-10 dB Down 1130 metric may be in Hz and may be a feature of a RF peak above the noise floor at a frequency location found to consistently be of RUL-significance.

Skewness 1140 metric may be unitless and may be a feature of a RF peak above the noise floor at a frequency location found to consistently be of RUL-significance.

Kurtosis 1150 metric may be unitless and may be a feature of a RF peak above the noise floor at a frequency location found to consistently be of RUL-significance.

Number-of-Peaks-In-Set 1160 metric may be a feature of a set of related RF peaks above the noise floor at adjacent frequency locations found to consistently be of RUL-significance.

Modulation Frequency 1170 in Hz metric may be a feature of a set of related RF peaks above the noise floor separated consistently by that amount in Hz at sequential frequency locations found to consistently be of RUL-significance.

Carrier Frequency 1180 in Hz metric may be the center frequency or the frequency at the highest dB peak of a feature of above the noise floor found to consistently be of RUL-significance

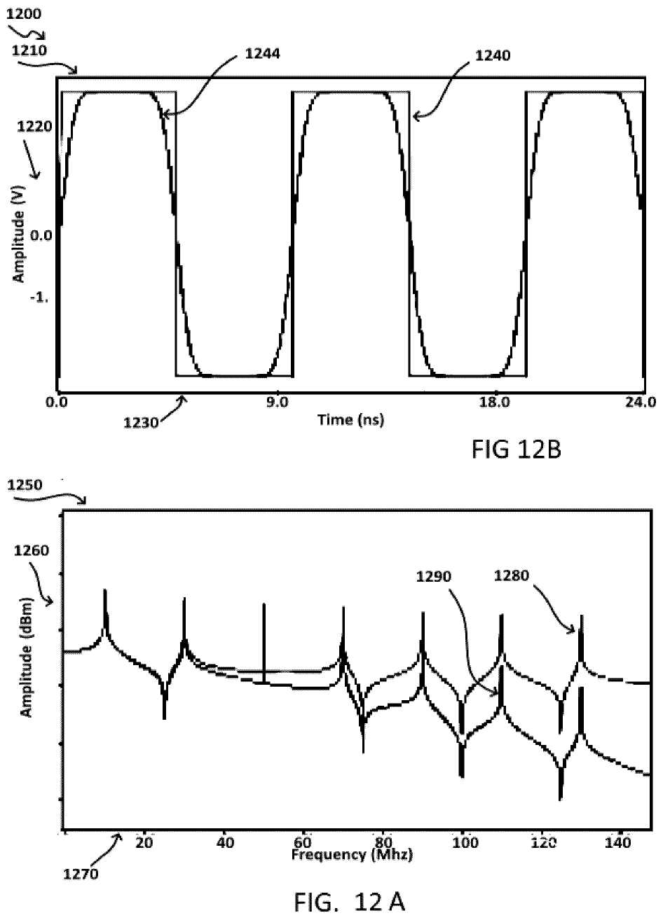

FIGS. 12A-12B illustrate the time domain and frequency domain amplitude characteristics of a square wave and a smoothed square wave distorted by a slower risetime and falltime in its leading and/or trailing edges. More specifically, FIG. 12A illustrates a frequency domain vs. dBm amplitude of a substantially perfect square wave versus a degraded square wave FIG. 12B. illustrates a time domain versus volts amplitude of a substantially perfect square wave vs. a degraded square wave.

FIGS. 12A-12B further illustrate the changes in peak height caused by the distortion, such as reduced peak height and reduced energy or amplitude of the square wave distorted by a slower risetime and falltime. Such distortion may be caused by an increase in resistance within a device or circuit due to age which may be the result of such things as Electromigration which is the movement of ions caused by momentum from the transfer of electrons in the conductor. This results in degradation of the material and eventual failure. This is related to on-resistance degradation, or Rdson, an increase in the resistance of a transistor due to use. Graph 1210 shows the time domain characteristics of perfect square wave 1240 and distorted square wave 1244. Y-axis 1220 may be in volts or millivolts, etc. X-axis 1230 is shown in nanoseconds. Graph 1250 shows the frequency domain characteristics of perfect square wave 1240 and distorted square wave 1244 as square wave spectrum 1280 and distorted square wave spectrum 1290. Y-axis 1260 may be in dB, dBm, watts, or other power levels. X-axis 1270 is shown in MHz.

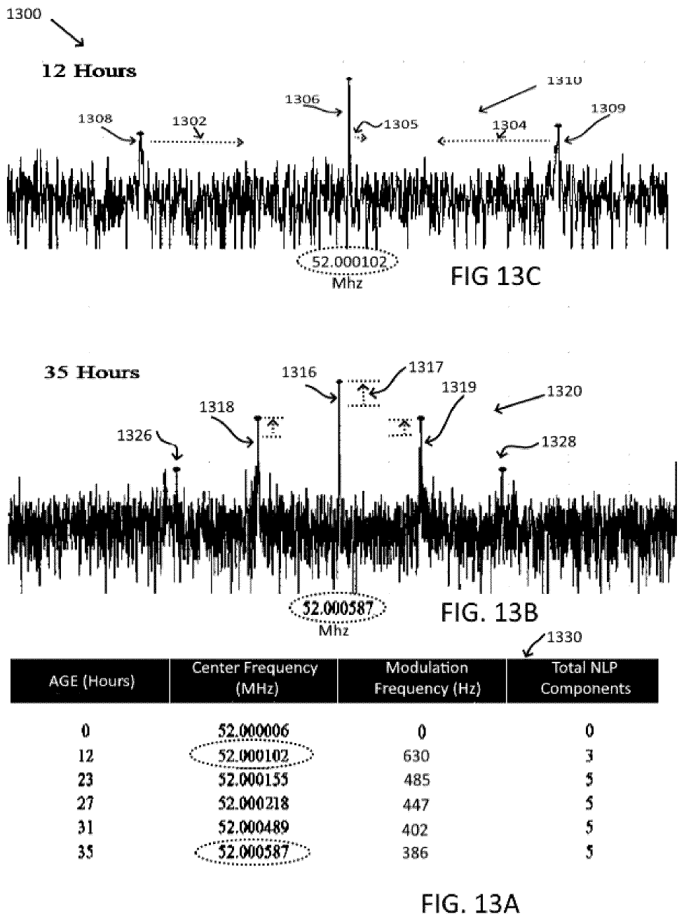

Referring to FIGS. 13A-13C, illustrated therein is spectral content features 1300 within a specific frequency region found to be of RUL-significance. Aging table 1330 shows that at time=0 only one center frequency peak is seen at 52.000006 MHz. More specifically, Non-Linear Products (NLP) peak devices are illustrated as a device ages from 12 hours to 35 hours under an accelerated aging regimen.

More specifically, FIG. 13A illustrates a numerical table of center frequency peaks and modulation frequencies associated with cross-modulation peaks as a part is aged. FIG. 13B illustrates a frequency domain vs. amplitude spectrum of a part aged 35 hours as seen in table of FIG. 13A. FIG. 13C illustrates a frequency domain vs. amplitude spectrum of a part aged 12 hours as seen in table of FIG. 13A.

At 12 hours three peaks 1308, 1306, and 1309 are detectable above the noise floor. The center and highest peak 1306 is now located at a frequency of 52.000102 MHz, a shift from its original location at 52.000006 MHz. Center peak feature 1305 shows the frequency direction the peak moves as the device ages. Non-Linear Products (NLP) peak devices 1308 and 1309 are seen as equidistant from the highest center peak 1306 and indicate non-linear mixing or modulation of the center frequency by a much lower frequency such as 60 Hz power supply noise caused by power supply DC-ripple filter degradation which causes an increase in 60 Hz noise on the DC voltage used to power the devices. This 60 Hz noise mixes with the center peak frequency in the inherently non-linear (not perfectly linear) semiconductors used in the circuits in the device, and especially any amplifiers in the device. In this way amplitude modulation of the center peak occurs and the side peaks 1308 and 1309 energy increase at the modulation frequency of 60 Hz. This is a simple example of two frequencies' intermodulation. More complex examples include a device with two or more separate oscillators whose frequency stability may be temperature dependent or may drift over time due to aging. In such cases, not only a center frequency may drift but also the peak separation distances may drift as both oscillators drift independently. Modulation peaks 1308 and 1309 are seen to drift towards center peak 1306 as shown by peak frequency drift elements 1302 and 1304 as the device ages. After 35 hours the center peak 1306 is at a new frequency 1316 and its height has increased in dB as seen by dB change 1317. Also, peaks 1308 and 1309 have moved in frequency to new locations 1318 and 1319 closer to the center peak. They have also increased in dB height. Also, peaks 1326 and 1328 have risen above the noise floor and are now detectable. They are also equidistant from the center peak 1316 and in a harmonic relationship to the other peaks 1318 and 1319, all separated by the same frequency distance in Hz.

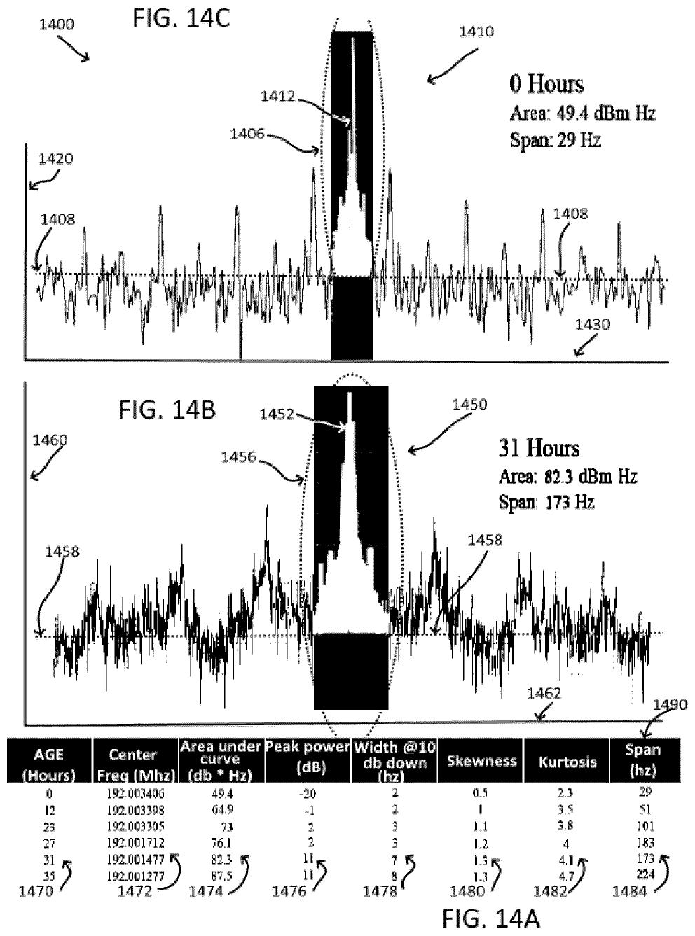

Referring to FIGS. 14A-14C, illustrated is spectral content features 1400 within a specific frequency region found to be of RUL-significance. More specifically, FIG. 14A illustrates a numerical table of center frequency peaks and associated metrics which may be used to determine aging, FIG. 14B illustrates a spectrum of a part aged 31 hours with particular emphasis on the area under the peak curve, and FIG. 14C illustrates a spectrum of a part aged 0 hours with particular emphasis on the area under the peak curve for visual comparison purposes.

Aging table 1490 shows that at time=0 as seen in column Age 1470 the Center Frequency 1472 of the center peak of a discovered RUL-significant region is 192.003406 MHz. This is also illustrated as peak 1412 in spectrum 1410. Column Area-Under-the-Curve 1474 of the table at time=0 shows a dB*Hz area value of 49.4. Column Peak Power 1476 of the table at time=0 shows a relative dB value of −20 dB. Column Width @ 10 dB down (Hz) 1478 of the table at time=0 shows a Hz width value of 2 Hz. Column Skewness 1480 of the table at time=0 shows a value of 0.5. Column Kurtosis 1482 of the table at time=0 shows a value of 2.3. Column Span 1484 of the table at time=0 shows a value of 29 Hz at the base of the center peak illustrated in region 1406 at the noise floor base 1408.

Further referring to FIGS. 14A-14C, illustrated is spectral content features of the same device after aging 31 hours within the same general specific frequency region found to be of RUL-significance. Aging table 1490 shows that at time=31 as seen in column Age 1470 the Center Frequency 1472 of the center peak of a discovered RUL-significant region has shifted to 192.001477 MHz. This is also illustrated as peak 1452 in spectrum 1450. Column Arca-Under-the-Curve 1474 of the table at time=31 now shows a dB*Hz area value of 82.3. Column Peak Power 1476 of the table at time=31 shows a relative dB value of 11 dB. Column Width @ 10 dB down (Hz) 1478 of the table at time=31 now shows a Hz width value of 7 Hz. Column Skewness 1480 of the table at time=31 shows a value of 1.3. Column Kurtosis 1482 of the table at time=31 now shows a value of 4.1. Column Span 1484 of the table at time=31 now shows a value of 173 Hz at the base of the center peak illustrated in region 1456 at the noise floor base 1458. Thus FIGS. 14A-14C illustrate a general metrics progression found in a RUL-significant region which may be used to determine age using at least the described methods.

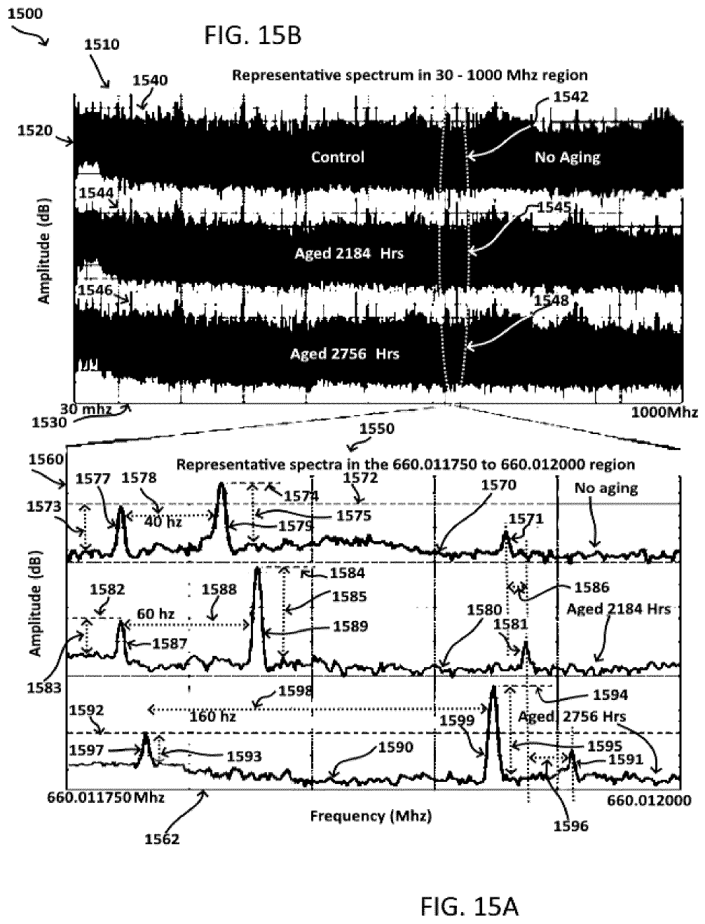

Referring to FIGS. 15A-15B, illustrated therein is another narrowband RUL-significant spectra region 1550 in detail within a broadband data region spanning 30 MHz to 1 Ghz and which may be used to determine Age. More specifically, FIG. 15A illustrates changes in narrowband frequency region spectrum features observed at different part ages and FIG. 15B illustrates changes in narrowband frequency region spectrum features observed at different part ages from which the narrowband regions are presented.

The narrowband region of RUL-significance may be a different Frequency region as the region shown in FIG. 14 but may be data taken for the same device. The region's data 1500 shows 3 broadband spectrum acquisitions 1510, more specifically acquisition of spectra 1540 was taken without aging, 1544 was taken after aging 2184 hours, and 1546 taken after aging 2756 hours. Within the broadband region, narrowband regions illustrated is region 1542 taken at 0 hours aging, region 1545 taken at 2184 hours aging, and region 1548 taken at 2756 hours aging. All three illustrated narrowband regions were taken at 660 MHz at different aging times and after study have been found to illustrate features of RUL-significance which may be found to change over time and used to determine RUL. X-axis 1530 represents a frequency span of 30 MHz to 1000 MHz and Y-axis 1520 represents a relative dB for each of the spectra 1540, 1544, and 1546.

RUL-significant aged narrowband spectrum around 660 MHz from the same device illustrated in spectra region 1550 contain narrowband spectra at 3 levels of aging, narrowband spectrum illustrated as 1570 contain narrowband spectra at 0 hours aging from region 1542, narrowband spectrum illustrated as 1580 contain narrowband spectra at 2184 hours aging from region 1545, and narrowband spectrum illustrated as 1590 contain narrowband spectra at 2756 hours aging from region 1548. The narrowband data may be taken at the same RBW as the broadband data, or it may be a different RBW and hence a different resolution. Often it is advantageous to acquire the narrowband spectra at a higher resolution using a lower RBW such as 0.1 Hz or 0.01 Hz instead of the lower resolution 1.0 Hz. This lower RBW may provide more feature details in peak structure such as peak width and may show additional peaks or peak features of RUL-significance distinguishable above the noise floor. Note that a higher RBW corresponds to a lower resolution and a lower RBW corresponds to a higher resolution. X-axis 1562 represents a frequency span between 660.011750 MHz and 660.012000 MHz and Y-axis 1560 represents a relative dB for each of the spectra 1570, 1580, and 1590.

More specifically, the three spectra 1550 illustrates narrowband data of 3 peaks which have later been found to have RUL-significance. Aged 0 hours spectra 1570 illustrates 3 peaks, peak 1571, peak 1577 and peak 1579 captured initially. Aged 2184 hours spectra 1580 illustrates the same 3 peaks, peak 1581, peak 1587 and peak 1589 captured after aging. Aged 2756 hours spectra 1590 illustrates the same 3 peaks, peak 1591, peak 1597 and peak 1599 captured after more aging.

Peak 1577 at 0 hours aging has dB level 1572 and height 1573 above the noise floor. Peak 1587 at 2184 hours aging located substantially at or near the same frequency location as earlier peak 1577 has dB level 1582 and height 1583 above the noise floor, illustrating a decrease in relative dB from earlier peak 1577 which had a previous height 1573 above the noise floor. As seen in a reduction of dB distance to the noise floor, a RUL-significant metric has been identified whereby the original peak 1577 height and height 1573 above the noise floor decreases over time as the device it is associated with ages.

Similarly, the Furthermore, trend continues as Peak 1597 at 2756 hours aging located substantially at or near the same frequency location as earlier peaks 1577 and 1587 has relative dB height 1593 above the noise floor, illustrating a continued decrease in relative dB from earlier peak 1577 and peak 1587 which had previous heights of 1573 and 1583 above the noise floor respectively. This is also seen in a reduction of height of the peak 1582 height relative to peak 1592 height and after aging, the RUL-significant metric trend continues and remains identified.

Thus, the RUL-related original peak 1577 height decreases over time as the device it is associated with ages.

Furthermore, another RUL-significant peak has been found in the same region, namely Peak 1579 at 0 hours aging has dB level 1574 and height 1575 above the noise floor. Later, the same peak 1589 at 2184 hours aging located substantially at or near the same frequency location as earlier peak 1579 has dB level 1584 and height 1585 above the noise floor, illustrating a increase in relative dB from earlier peak 1579 which had a previous height 1575 above the noise floor. As seen in a increase of dB distance to the noise floor, another RUL-significant metric has been identified in the same region whereby the original peak 1579 height and height 1575 above the noise floor increases over time as the device it is associated with ages.

Similarly, the RUL-related trend continues as Peak 1599 at 2756 hours aging located substantially at or near the same frequency location as earlier peaks 1579 and 1589 has relative dB height 1595 above the noise floor, illustrating a continued increase in relative dB from earlier peak 1579 and peak 1589 which had previous heights of 1575 and 1585 above the noise floor respectively. This is also seen in a increase of height of the peak 1589 height relative to peak 1599 height and after aging, the RUL-significant metric trend continues and remains identified.

Thus, the RUL-related original peak 1579 height increases over time as the device it is associated with ages.

Similarly, another RUL-significant feature has been illustrated in the Peak 1579 frequency location. Frequency changes of Peak 1579 are seen to be of RUL-significance as its associated device ages. Peak 1579 frequency location and its frequency distance to Peak 1577 increases with aging. Initially the frequency distance between Peak 1579 frequency location and Peak 1577 frequency location seen as frequency distance 1578 is 40 Hz. After device aging of 2184 hours, the frequency distance between aged Peak 1589 and aged Peak 1587 frequency location seen as frequency distance 1588 has increased to 60 Hz.

This RUL-significant trend continues after further aging as after device aging of 2756 hours, the frequency distance between aged Peak 1599 and aged Peak 1597 frequency location seen as frequency distance 1598 has increased to 160 Hz.

In this same narrowband frequency region, a smaller Peak 1571 is seen to be of RUL-significance. Its height does not change substantially but its frequency location does change. Illustrated is its new aged peak location of 1581 with frequency increase 1586 after aging 2184 hours and more aged peak location 1591 with a further frequency increase 1596 after aging 2756 hours.

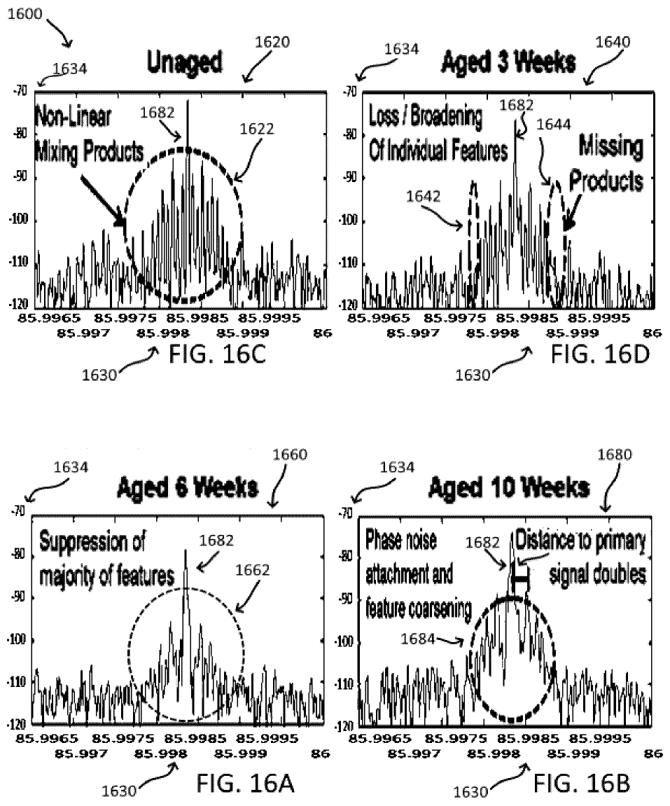

FIGS. 16A-16D illustrate exemplary RUL-related narrowband spectrum signature changes 1600 observed for a GPS device while aging. More specifically, FIG. 16A illustrates exemplary spectrum features observed at 6 weeks, FIG. 16B illustrates key spectrum features observed at 10 weeks, FIG. 16C illustrates exemplary spectrum features observed at 0 weeks (unaged), and FIG. 16D illustrates exemplary spectrum features observed at 3 weeks.

Unaged spectrum 1620 illustrates the existence of non-linear mixing products 1622 located around central peak 1682. X-axis 1630 illustrates a frequency span from 65.9965 MHz to 66.0000 Mhz. Y-axis 1634 may illustrate a relative dB level or an absolute dBm level range from −70 dB or −70 dBm to −120 dB or −120 dBm. Spectrum 1640 aged 3 weeks illustrates the RUL-significant loss or reduction of non-linear mixing products in frequency regions 1642 and 1644 still located around central peak 1682. Spectrum 1660 aged 6 weeks illustrates the RUL-significant further reduction of non-linear mixing products in frequency and amplitude region 1662 still located around central peak 1682. Finally, Spectrum 1680 aged 10 weeks illustrates the RUL-significant phenomena of phase noise attachment and feature coarsening in frequency and amplitude region 1684 still located around central peak 1682. This phase noise attachment and feature coarsening may be quantified into metrics using the SAS software's area under the curve, curve-fit 912, kurtosis, and/or skewness measurement methods.

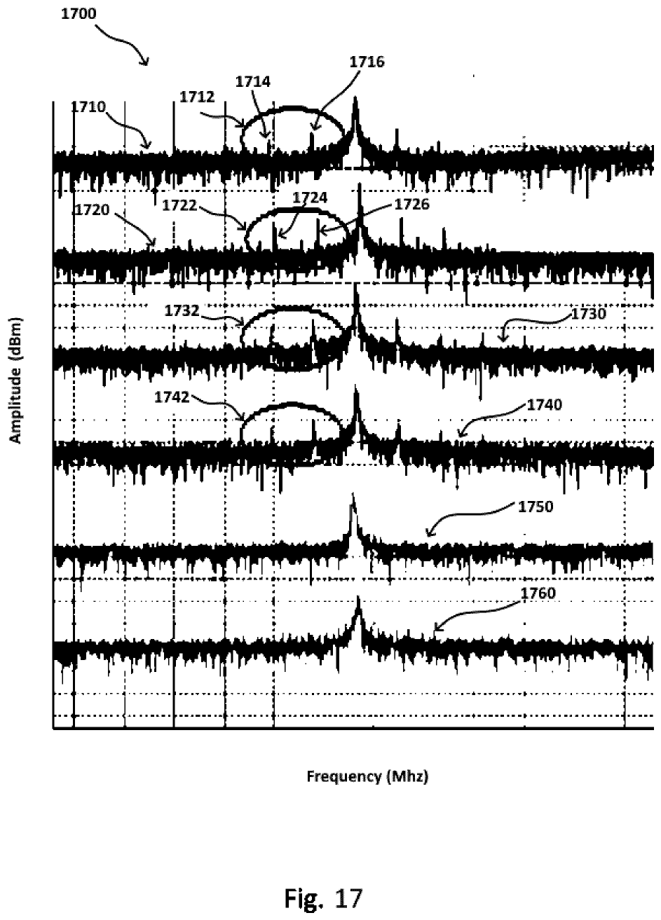

Referring to FIG. 17, illustrated therein is a progression of narrowband spectra 1700 of 2 devices of same device number from no aging to during and after 2 periods of aging, and found to have exhibited similar common RUL-significant spectrum changes and RUL-significant manifest features. Spectrum 1760 illustrates spectrum from unaged baseline Device A. Spectrum 1750 illustrates spectrum from unaged baseline Device B. Spectrum 1740 illustrates spectrum from baseline Device A after aging a specific 1st increment of amount of time. Similarly, Spectrum 1730 illustrates spectrum from baseline Device B after aging the same specific 1st increment of amount of time Device A was aged in spectrum 1740. Spectral region 1742 shows new RUL-significant features arising from aging Device A and spectral region 1732 shows similar new RUL-significant features arising from aging Device B as a result of aging. Spectrum 1710 illustrates spectrum from baseline Device B after aging a same 2nd increment of specific amount of time that Device A was aged in spectrum 1720. Spectral region 1722 shows further changes in new RUL-significant features arising from further aging Device A and spectral region 1712 shows similar further changes in new RUL-significant features arising from aging Device B as a result of further aging. Note that RUL-significant peak 1716 of Device B and RUL-significant peak 1726 of Device A appear of similar height after further aging but RUL-significant peak 1714 of Device B and RUL-significant peak 1724 of Device A appear of differing heights which may occur occasionally for some devices. This reinforces the value of more than one and multiple RUL-significant metrics from devices to determine aging more accurately and/or to overcome individual spectrum regions which may not show added aging features or may show a backtracking in aging in that region.

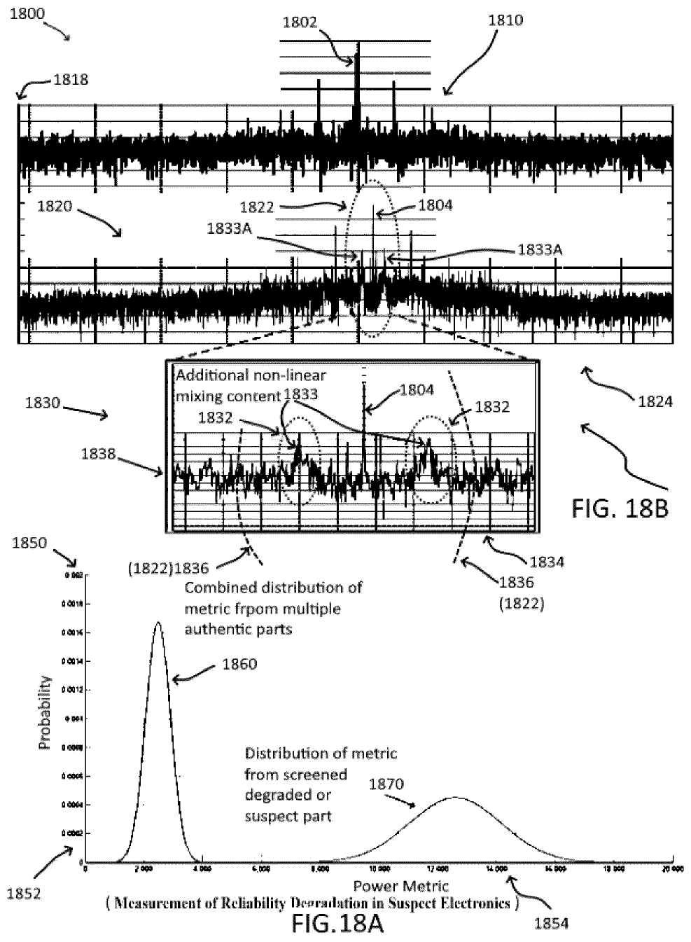

Referring to FIGS. 18A-18B, illustrated therein is RUL-significant spectrum changes from a device in detail and an exemplary distribution of similar RUL-significant metrics features from multiple authentic devices 1860 in contrast to substantially differing RUL-significant metric values features from degraded or suspect devices 1870. More specifically, FIG. 18A illustrates power vs. probability distribution for an exemplary part's specifically chosen metric and specific metric value. FIG. 18B illustrates spectrum content from which the characteristics of FIG. 18A are derived.

As can be seen metric values features from degraded or suspect devices 1870 have a broader distribution of X-axis Power metric 1854 than the distribution from a group of authentic devices 1860. Y-axis probability 1852 further reinforces the authentic devices 1860 distribution narrowness relative to suspect devices 1870.

FIG. 18B also illustrates a spectrum 1810 which may be from a device of lesser age and Spectrum 1820 which may be from the same device but of greater age. Visible are RUL-significant spectrum changes of frequency thickness of a central peak at substantially the same frequency location of the broader older central peak 1804 from the narrower younger central peak 1802. Y-axis 1818 is relative dB in Spectrum 1810, Spectrum 1820, and Spectrum 1830. X-axes 1824 and 1834 represent specific narrowband frequency locations wherein X-axes 1834 is located within the narrower narrowband frequency region 1822 zoomed in as region 1836 for greater clarity. The narrower narrowband frequency region 1822 may be acquired at a lower RBW and higher resolution in Spectrum 1830 than the Spectrum 1820 or Spectrum 1810. Spectrum 1820 shows RUL-significant sidebands 1833A which may contain more detailed features within them. For example, visible in the zoomed in region 1836 are two aging related new regions of RUL-significant sidebands 1832 equidistant and on either side of central peak 1804 and whose more detailed peaks 1833 than RUL-significant sidebands 1833A at the same frequency location contain new RUL-significant additional non-linear mixing content seen as greater peak frequency width. These peaks 1833 may be quantified into a RUL-related metric such as Area under the Curve 1102 or Width at 10 dB Down 1130 using the curve fit software 912.

Referring to FIG. 19, illustrated therein is a software architecture 1900 which may be used to populate or update a database of devices data comprising Accumulated Model Data 980. Here, a user 1999 may be a human, an AI-based, or an automated and may use software 1996 which may be a Graphical User Interface (GUI) or run unsupervised, and determine if the New or Recent Data's 940 metrics for the devices within it demonstrate a sufficiently satisfactory degree of discrimination to determine levels of aging, degradation, authenticity, counterfeit, and/or RUL with a sufficiently satisfactory degree of certainty or probability with reference to the desired accuracy of determination outcomes.

Discretion of the user 1999 may selectively include rejection of data due to mislabeled devices, defective or non-representative devices, bad data acquisition, poor subsequent actual RUL results, better quality data availability more recently, noisy data, or other reasons. The discretion of the user 1999 may include acceptance and integration of New or Recent Data 940 by performing updating in software 1960 the Accumulated devices Data database 980 which may immediately or later be used to create or re-create the Matrix 990. The user 1999 may add annotation information at this point such as adding manufacturer batch number, devices storage conditions such as temperature or humidity of storage, operator information regarding who took the original spectrum acquisitions or spectrum acquisitions equipment used, or supplier information to the devices data being added.

These accuracies of determination outcomes may be subjective or objectively defined such as a required minimum Mahalanobis distance between metrics determining initial aging and final RUL age, or other statistical measures such as a required maximum standard deviation of measurement raw values or derived metrics between devices for a given aging duration. Purely as an example, a decision to require a maximum standard deviation of 2.0 between devices aged or age equivalents thru accelerated aging methods of 1 year may be established and applied as a criterion. If the results of the subject matter do not achieve that standard deviation level of 2.0 for associated metrics discrimination between any one or more year's aging duration, then the software 1996 may automatically reject the data and/or metrics for inclusion into the database 980, or it may display to a possible user 1999 this outcome for the user's 1999 further consideration to refine the criteria or override the criteria.

Software 1996 may also be used to edit, update, augment, refine or delete data in database 980 such as deleting device's data no longer needed, deleting devices data which has been archived for possible future use only, deleting devices data which has been later found to be invalid due to reasons such as mislabeled or misidentified devices, adding additional data and/or metrics associated with a batch of new devices of a known specific age, adding additional data and/or metrics associated with newly acquired spectral narrowband regions of previously processed devices, or adding data and/or metrics gathered as a result of re-running the Subject Matter on previously processed devices to increase the sample size and/or increase the level of certainty of age determination or increase the RUL accuracy. This may be done using database access software 1960. Batches of devices may be resampled at the same previous frequencies but at a lower RBW within previously discovered narrowband RUL-significant frequencies to further refine the data and/or metrics and determine a more accurate result. Such methods may also be used to determine and identify variations in batch runs of the same device number or determine characteristics of different batches of the same device number but sourced from differing manufacturers.

Also, such methods may be used to determine which devices within a batch of devices are better or have a longer RUL and thus those devices may be set aside for inclusion into high-value systems in which RUL is important or critical. Such methods may be used to determine a differing economic value based on which devices within a batch of devices are better or have a longer RUL and thus those devices may be sold at a higher price. The higher price calculation criteria may be calculated using means such as a linear, logarithmic, or exponential curve wherein the RUL amount above the average RUL for a device is used to determine a higher cost percentage above the average device cost. As an example, a device of a batch of devices estimated to have a RUL 30% higher than the average RUL of the group may have a price 30% higher than the price for devices within an average RUL range. Alternatively for example, a device estimated to have an RUL 30% higher than the average RUL device may have a price approximately 2× higher than the price for devices within an average RUL range if the chosen example exponent base is 10, as 10 to the 0.3 power=10E 0.30=10^{0.3}=1.995. This price calculation criteria may be included in database 980 and related economic value calculation methods and constants may be chosen and entered by user 1999 using GUI 1996 before, during, or after device data is added to database 980.

The Matrix 990 may be loaded from database 980 on demand, periodically, or only when new data is added to database 980. The Matrix 990 may be available to user 1999 using the GUI 1996 for viewing or change such as changing any device associated metrics weighting.

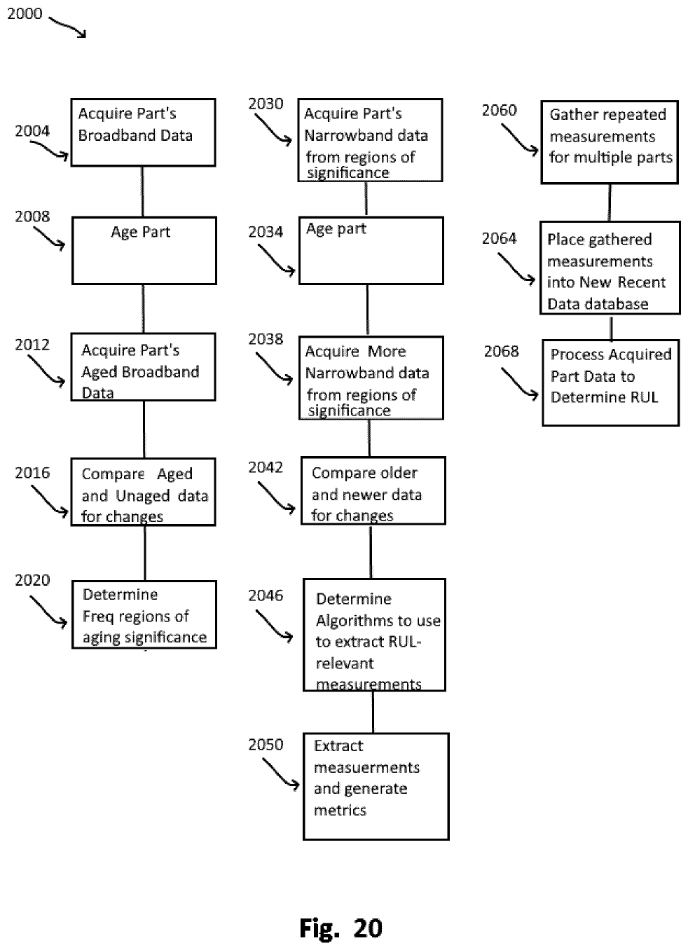

Referring to FIG. 20, illustrated is a flowchart of exemplary processing of a batch of devices. Step 2004 illustrates the initial acquisition of broadband RF emissions data on one or more of the acquired devices. This may be done in a frequency range between 30 MHz and 1 Ghz and is also illustrated in FIG. 15 shown as Spectrum 1510. This may be done at an RBW of 1 Hz as an acceptable trade-off between acquisition time and resolution. Step 2008 naturally or artificially ages the device used in Step 2004, enabling the acquisition of aged device data in a future step. Natural aging means simply running a device for a period of time. Alternatively, it may be performed by acquiring and using a separate already aged device instead of aging the device or waiting for it to age, the already aged device replacing a device to be aged. If this is the case, the aged device's spectrum is also taken and is used as representative of a device aged by the age amount. Thus, Step 2012 of acquisition of broadband RF emissions data on one or more of the aged devices may be done on a different device aged a known amount. Therefore, Step 2004 and Step 2012 may be simultaneous or concurrent if an aged and unaged device is used and separate spectrum acquisition equipment is available to separately acquire spectrum data on.

Step 2016 compares the aged broadband RF emissions data with unaged or lesser aged broadband RF emissions data acquired in Steps 2004 and 2012 for differences as candidate regions of RUL-significance. Comparisons include discerning changes or differences in features between aged and unaged spectrum described in the Subject Matter such as new peaks, disappearing peaks, changes on peak heights, changes in peak frequency location, etc. Step 2020 selects or determines with more certainty the frequency regions of RUL-significance of the acquired devices on candidate regions identified in Step 2016. This step balances the reduction in overall spectrum width and amount of data to be taken with the likelihood that there may later be RUL-related features adjacent outside the region narrowed down and later be missed or overlooked.

Step 2030 acquires additional emissions data from devices in narrowband RF acquisitions from the frequency regions of RUL-significance identified in Step 2020 on one or more of the acquired devices. These acquisitions may be taken at a different RBW to increase acuity, increase amount of RUL-significant data details acquired, or optimize speed of process and total processing time required. A reduction in RBW in various regions resulting in more data in volume and more dB accurate data is often of value in gathering more discriminating features to be used to determine RUL more accurately such as with more time precision or with more certainty such as the accurate probability of the age being correctly predicted. This is valuable when RUL processing is done later.

Step 2034 optionally further or additionally ages or performs accelerated aging of devices, preferentially of those devices whose data has previously been acquired. Alternatively, it may be in the same spectral regions from other devices which are known to be aged further. Optional Step 2038 acquires more narrowband RF emissions data from the frequency regions of RUL-significance identified in Step 2020 on one or more of the further aged devices. This may then enable establishing a set containing a series of examples of acquisition data associated with varied differing aging levels as a basis for determining age of device based on RF emissions data. Multiple devices are useful to get more sample data for a better representation of the statistics underlying the device behavior. Also, more samples from the same device or set of devices is useful. Averaging spectrum data or performing non-coherent integration on the spectral data of the same device is a means of gathering more data from the same device and useful in determining more accurate dB measurements of features above the noise floor resulting in more accurate comparison calculations and more accurate metrics.

Step 2042 compares further aged narrowband RF emissions data with unaged or lesser aged narrowband RF emissions data acquired in Steps 2038 and 2030 in regions of RUL-significance to further determine features of aging significance within those regions. Some new features may only arise after significant further aging and may only then be found.

Step 2046 determines algorithms to use to extract RUL-significant Metrics from features in regions identified in Step 2042. Candidate algorithms for consideration include those mentioned herein such as Curve Fit, Peak Location, Peak Height, Frequency Harmonics of peaks, Noise floor height, Peak separation, additional peaks, less peaks, Non-linear products peaks locations, Harmonic Extraction, and measured dB or frequency changes of these as aging occurs.

Step 2050 uses algorithms identified in Step 2046 to generate Metrics on device data acquired. Metrics may be represented as numerical values representing Skewness, Kurtosis, averages, statistical quantities, distances in Hz or dB, a linear or non-linear combination of the preceding values, or counts for example. Metrics may be integer, floating point values, or complex numbers.

Optional step 2060 repeatedly gathers more data from devices in the frequency regions of RUL-significance and uses the algorithms determined in Step 2046 to generate more total Metrics data for the devices. Additional data may increase probability accuracy, increase probability certainty, or increase age accuracy results by acquiring a larger and/or more representative sample size. This may be done for differing devices and/or at differing aging levels or even at failure levels.

Step 2064 archives Device Data and its Metrics acquired from some or all of Steps 2004 to 2060 in a database. The database may include only the Metrics for some devices, both Metrics and Raw data, or only the Raw data, although both Metrics and Raw data is preferred. Multiple Batches of devices of Multiple device numbers are envisioned to be contained therein. Also envisioned is the potential to refine device data by integrating more metrics from more added devices of a batch within a device number at a later time as more devices and devices of differing ages are acquired.

Step 2068 uses archived Device Data and its Metrics to determine RUL of devices already in the database or more importantly of determining RUL of newly acquired devices, typically of the same device number as detailed in the steps of FIG. 9.

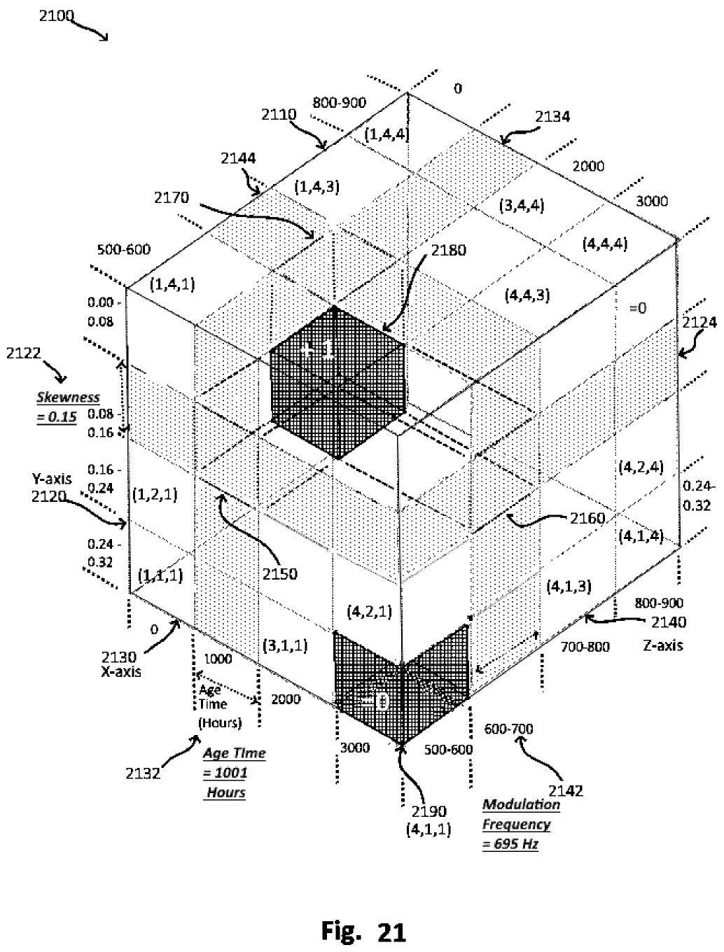

Referring to FIG. 21, illustrated is an example of a 3-D Sparse Matrix whose dimensions are device metrics and whose matrix elements index using device metrics derived co-ordinates' which contain occurrence counts or statistical values of device metric combinations at those coordinates. In practice, a higher dimension matrix may be chosen such as a 5-D, 6-D, 7-D or higher dimension matrix wherein each dimension is associated with a specific device metric and whose indexes are defined by a narrower numerical low and high value limit range within that metric.

Element 2110 is a 3-D Sparse Matrix element located at indexes (1,4,3) and whose metrics correspond to X-axis value of age between 0-1000 and Y-axis value metrics correspond to a value between 0.00 and 0.08 of Skewness and a Z-axis value metrics correspond to a Modulation Frequency between 700 and 800 Hz.

Y-axis 2120 of example 3-D Sparse Matrix represents Skewness ranges for each Y-axis Skewness index, wherein a Skewness of 0.00 to 0.08 corresponds to a Y-axis index of 4, a Skewness of 0.080001 to 0.16 corresponds to a Y-axis index of 3, a Skewness of 0.160001 to 0.24 corresponds to a Y-axis index of 2, and a Skewness of 0.240001 to 0.32 corresponds to a Y-axis index of 1.

Specific Y-axis Skewness example 2122 illustrates the result of a value of a device having 0.15 Skewness which is within range of 0.08 to 0.16 Skewness which falls into Skewness Y-axis index=3.

Figure identifier 2124 points to a plane of 16 Matrix elements within the Matrix 2100 all having a Skewness between 0.08 and 0.16 and all having a Skewness index=3. This Skewness plane intersects other planes of Age and Modulation Frequency, the intersection matrix element being a value range combining all the specific narrow 3 axes value ranges and contains a total or statistical value for the number of devices with that specific combination of value ranges for the 3 metrics comprising the 3-D matrix.

X-axis 2130 of example 3-D Sparse Matrix 2100 represents a unique age range associated with each age index, index 1 encompasses 0-1000 hours aging, index 2 encompasses 1000.001-2000 hours aging, index 3 encompasses 2000.001-3000 hours aging, and index 4 encompasses 3000.001-4000 hours aging.

Specific X-axis value example 2132 illustrates a device having a specific age of 1001 hours which is within range of 1000.001 to 2000 hours Age which falls into age X-axis index=2.

Plane 2134 of 16 Matrix elements within the Matrix 2100 all have elements with an age between 1000.001 hours and 2000 hours and all having an age X-axis index=2.

Z-axis 2140 of example 3-D Sparse Matrix 2100 represents unique Modulation Frequency ranges for each Modulation Frequency index, index 1 encompasses 500-600 Hz, index 2 encompasses 600-700 Hz, index 3 encompasses 700-800 Hz, and index 4 encompasses 800-900 Hz.

Specific Z-axis example 2142 is of a device having Modulation Frequency value of 695 Hz which is within range of 600 to 700 Hz and falls into Modulation Frequency Z-axis index=2.

Plane 2144 is a Matrix of 16 elements within the Matrix 2100 all having a Modulation Frequency between 600 Hz and 700 Hz and all having a Modulation Frequency index=2.

Sequential line of 4 Matrix elements 2150 is a line of elements of intersecting specific Age and Skewness ranges with respective associated indexes within the Matrix 2100 all having a Skewness between 0.08 and 0.16 with a Skewness Y-axis index=3 and also all having Age within range of 1000.001 to 2000 hours which falls into age X-axis index=2.

Sequential line of 4 Matrix elements 2160 is a line of sequential 4 Matrix elements intersecting specific Skewness and Modulation Frequency ranges with respective associated indexes within the Matrix 2100 all having a Modulation Frequency between 600 Hz and 700 Hz with a Z-axis index=2 and also all having Skewness within range of 0.08 to 0.16 which falls into Skewness Y-axis index=3.

Sequential line of 4 Matrix elements 2170 is a line of sequential 4 Matrix elements intersecting specific Age and Modulation Frequency ranges with respective associated indexes within the Matrix 2100 all having a Modulation Frequency between 600 Hz and 700 Hz with a Z-axis index=2 and also all having Age within range of 1000.001 hours to 2000 hours which falls into Age X-axis index=2.

Matrix element 2180 is a Matrix element within the Matrix 2100 at index location (X=2, Y=3, Z=2) associated with a device's Age of 1001 hours which is within range of 1000.001 to 2000 hours and thus which falls into age X-axis index=2. That device also has a 0.15 Skewness which is within range of 0.08 to 0.16 Skewness which falls into Skewness Y-axis index=3. That device also has a Modulation Frequency of 695 Hz and between 600 Hz and 700 Hz associated with a Z-axis index=2. At that specific index location (X=2, Y=3, Z=2) It's element's value content=1 meaning there has been 1 occurrence of a device measured within and constrained to all 3 of those ranges associated index values thus far. This Element 2180 has device metrics values pulled from a illustrative device entry in the table in FIG. 11 Row 2 and with a Time value metric entry 1192 of 1000 hours, a Skewness value metric entry 1194 of 0.14999, and Modulation Frequency metric entry 1196 in Hz of 695 Hz.

Matrix element 2190 within the Matrix 2100 at index location (X=4, Y=1, Z=1) contains 0 occurrences of any devices measured thus far within and constrained to all 3 of those ranges' associated index values, that is a age time between 3000 hours to 4000 hours associated with X-axis index=4, a skewness of 0.24 to 0.36 associated with Y-axis index=1, and a Modulation Frequency of 500 Hz to 600 Hz associated with Z-axis index=1. It is possible no device will ever be measured to result in values associated with that matrix element and that element may never rise above=0 for any device sample measured. It is envisioned that matrices with more than 3 Dimensions may be implemented in embodiments of the Subject Matter, and more than 3 metrics will be represented in elements within such matrices.

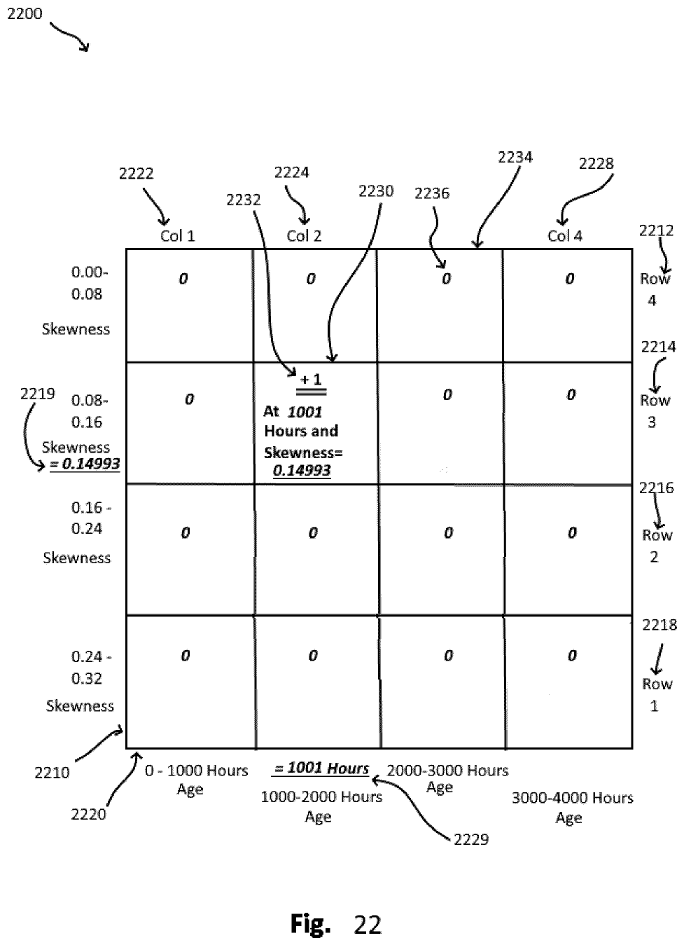

FIG. 22 illustrates an example of a 2-D Sparse Matrix 2200 whose dimensions are derived from device metrics and whose matrix elements are indexed using co-ordinates' derived from device metrics and whose contents are of integer occurrence counts or real number statistical values such as percentages of device metric occurrence combinations at those coordinates. This Element 2230 within 2-D Sparse Matrix 2200 has device metrics values pulled from an illustrative device entry in the table in FIG. 11 Row 2 and with a Time value metric entry 1192 of 1001 hours, and a Skewness value metric entry 1194 of 0.14999.

Axis 2210 of 2-D Sparse Matrix 2200 illustrates Skewness value in a total range of 0.00 to 0.32 and separated into 4 groups of index resolution giving 4 possible index entries. A Sparse Matrix of any dimensions may have a much higher index resolution, having the number of elements for an axis greater than 10, 100, or 1000 for more acuity.

Skewness Row 4 2212 is a row for devices with device metrics whose value ranges from 0.00 to 0.08 Skewness. Skewness Row 3 2214 is a row for devices with device metrics whose value ranges from 0.080001 to 0.16 Skewness. Skewness Row 2 2216 is a row for devices with device metrics whose value ranges from 0.160001 to 0.24 Skewness. Skewness Row 1 2218 is a row for devices with device metrics whose value ranges from 0.160001 to 0.24 Skewness.

Matrix 2200 Skewness Row 3 2219 illustrates an example value of a device's skewness=0.14993 and thus associated with Row 3's value range of 0.08 Skewness to 0.16 Skewness.

X-Axis 2220 of Age column value ranges may be age at failure or age thus far. This Matrix 2200 illustrates only 4 elements of resolution on the X-axis whose total range is from 0 hours aging to 4000 hours aging. Column 1 2222 is the index for Age from 0 to 1000 hours aging. Column 2 2224 is the index for Age from 1000.001 hours to 2000 hours aging. Column 4 2228 is the index for Age from 3000.001 hours to 4000 hours aging. Example value 2229 of a device's age at 1001 hours is thus associated with Column 2's (Column 2224) value range of Matrix 2200.

Matrix 2200 element 2230 at (Row=3, Column=2) contains a count or statistical value for device metrics data and is added or accumulated when a measured device has its metrics combination falling within the metrics ranges associated with each of the 2-dimensional index values. In this example, the 1^{st} device's data is shown added to the Matrix 2200 and its metrics are associated with this matrix element and the value within that matrix element is =1 indicating only 1 device has been found thus far with metrics values falling in a combination of those two metrics ranges, specifically 1000-2000 hours age metric and 0.08 to 0.16 Skewness metric.

Matrix 2200 element 2232 is at (Row=3, Column=2) and contains a count or statistical value=1. It has been incremented from 0 occurrences to contain and reflect the occurrence of one total device's associated metrics in its associated row and column's index location range. Likely additional subsequent other device's associated metrics will be measured in that range combination and increment that same matrix element or elements near or adjacent it. Also likely is that elements further away or at matrix extreme edges will never get an occurrence and never get incremented above a value of 0.

Matrix 2200 element 2234 is at (Row=4, Column=3) and illustrates a count or statistical value=0, as do other matrix elements. In the illustration, no devices thus far have fallen into this element's combination of Skewness and time value. In the illustration, it's possible that no devices ever will be found to index into this element's combination of Skewness and time value.

Matrix 2200 element 2234's count or statistical value 2236 is currently equal to 0 (at Row=4, Column=3) at that point in time the matrix has been updated by device metrics values measured thus far.

The index values may be calculated by an equation such as a linear, polynomial, or exponential equation. As an example, the computer code to calculate the integer Time index from the Time metric may be TimeIndex=int (timeMetric/1000)+1. The computer code to calculate the integer Modulation Frequency index from the its metric may be ModulationFrequencyIndex=int ((ModulationFrequencyMetric−500)/100)+1. The computer code to calculate the integer Skewness index from the its metric may be SkewnessIndex=int ((0.24−SkewnessMetric)/0.08)+1. The index values may be defined by a table of index value ranges for each index. This allows for a complex non-linear association between metrics and index values where groupings of metrics of values near each other are separated and groupings of metrics far devices are grouped together under the same index. For example, Kurtosis of −100.00 to −0.01 may be linked to index=1, Kurtosis of −0.01 to 0.02 may be linked to index=2, Kurtosis of 0.02 to 0.25 may be linked to index=3, Kurtosis of 0.25 to 0.30 may be linked to index=4, and Kurtosis of 0.30 to 100.00 may be linked to index=5. The metrics index groupings may be determined by human judgement after examining the groupings occurring in the data, it may be determined by a calculation, it may be determined by a Neural Net, or other means. It is anticipated that densely grouped metrics may use densely grouped indices to enable more discrimination between them such as in the Kurtosis example of index 3 and index 4 above. It is anticipated that this index calculation or index table would be associated with the device in the Database 980.

An equation to update a Multidimensional Matrix containing counts or probabilities associated with RUL, operating duration, or degradation such as 3-D Matrix 2100 is MatrixElement(TimeIndex, SkewnessIndex, TimeIndex)=MatrixElement (TimeIndex, SkewnessIndex, TimeIndex)+1. For example, using the equations above for a measured device with a X-axis AgeTime Metric 2132 of 1001 hours, and a Y-axis Skewness Metric 2122 of 0.15, and a ModulationFrequency Metric 2142 of 695 Hz as seen in FIG. 21 Matrix 2100, Matrix element (X=2, Y=3, Z=2) would be incremented by one from its previous value, updating the statistics and counts associated with devices falling within that range of values. Programmatically illustrated it is DeviceMatrix(2,3,2)=DeviceMatrix(2,3,2)+1.00. Multiple device metrics associated with devices with the same device number and processed using the Subject Matter may be combined into a single Multi-variate Matrix in this manner. Thus, the combined RF emission measurements and resulting metrics of a batch of devices may be counted or statistically accumulated into one or more Multi-dimensional Matrix for case of retrieval, analysis, and/or display such as in heat map form. Further, device metrics counts or statistics for a range of metrics or combinations of metrics may be quickly and conceptually easily referred to and accessed.

As an example of device metrics statistics retrieval from a Multivariate sparse matrix 2100, a program may scan all elements of the matrix 2100 and add their contents to accumulate total number of device samples in Matrix result.

The following code illustrates the counting of the number of total devices in the Matrix 2100:

```
  For X = 1 to 4 (scan all Ages using Age Index)
    For Y = 1 to 4 (scan all Skewnesses using Skewness Index)
      For Z = 1 to 4 (scan all Modulation Frequencies using
ModulationFrequency Index)
        TotalCount = TotalCount + Matrix(X,Y,Z) (accumulate count of
devices)
      Next Z
    Next Y
    Next X
```

The percentage of devices with an Age of 1000 to 2000 hours may be calculated using the following:

```
AgeIndex = 2 (Age Index associated with devices with 1000 to 2000 hours Age)
  For Y = 1 to 4 (scan all Skewnesses at AgeIndex=2 using Skewness Index)
    For Z = 1 to 4 (scan all Modulation Frequencies at AgeIndex=2 using
ModulationFrequency Index)
      TotalCountAtAge1000To2000 = TotalCountAtAge1000To2000 +
Matrix(AgeIndex, Y,Z) (accumulate count of devices at age 1000 hours to 2000 hours)
    Next Z
  Next Y
PercentageOfDevicesAtAge1000To2000 = 100 * TotalCountAtAge1000To2000 /
TotalCount
```

Similarly, the percentage of devices with an Age of 1000 to 2000 hours and Skewness between 0.08 and 0.16 may be calculated using the following:

```
TotalCountAtAge1000To2000 =0
AgeIndex = 2 (Age Index value associated with devices with 1000 to 2000 hours Age)
SkewnessIndex=3 (Skewness Index value associated with devices with 1000 to 2000
hours Age)
  For Z = 1 to 4 (scan all Modulation Frequencies at AgeIndex=2 and Skewness
  Index =3 using Z-axis ModulationFrequency Index)
    TotalCountAtAge1000To2000 = TotalCountAtAge1000To2000 +
    Matrix(AgeIndex, SkewnessIndex, Z) (accumulate count of devices at age
    1000 hours to 2000 hours and selected Skewness)
  Next Z
PercentageOfDevicesAtAge1000To2000 = 100 * TotalCountAtAge1000To2000 /
TotalCount
```

A Heat Map may gather data for display by accessing the counts in a Devices Matrix such as Matrix 2100. A heat map of Time vs. Skewness with the probability density being the accumulated values at all Modulation Frequency values for each combination of X-axis Age and Y-Axis Skewness may be calculated using the following:

```
  Dim TotalModFreqCounts ( 4, 4 )
  For X = 1 to 4 (scan all Ages using Age Index)
    For Y = 1 to 4 (scan all Skewnesses using Skewness Index)
      For Z = 1 to 4 (scan all Modulation Frequencies using
ModulationFrequency Index)
        TotalModFreqCounts(X,Y) = TotalModFreqCounts(X,Y) +
        Matrix(X,Y,Z) (accumulate count of devices)
      Next Z
    Next Y
  Next X
```

The above code accumulates the total occurrences of devices for each Age and Skewness combination. A heatmap may then display the Age on the X-axis and Skewness on the Y-axis with the accumulated values represented in grayscale for each X, Y point such as seen in FIG. 5 Regions 560, 570 and 580. Thus, the preceding code extracts probability data from Matrix 2100 based on all the Age and Skewness metrics as the X and Y axes, but across all Modulation Frequency Indices combined for that Age and Skewness parameter X, Y coordinate. The resulting probability may then be displayed in heat map form for further analysis.

When ground truth data or baseline data from a preferably large number of devices such as 30 or more devices has been used to populate the Matrix 2100, a newly analyzed electrical device with its metrics measured may be applied to the Matrix to determine its RUL or to display a range of RUL probabilities associated with their associated ages for the device's measured metrics. The following code line illustrates this:

$$NewDeviceProbability = Matrix ( NewDeviceAgeIndex , NewDeviceSkewnessIndex , NewDeviceModulationFrequencyIndex ) / TotalCount .$$

As an example, if the NewDeviceProbability determined above is found to be above a predefined probability threshold such as may be established by a customer, that electrical device may be deemed sellable to the customer at a prespecified amount.

The displayed heatmap may be used to determine if a device's likelihood of accurately determining RUL is high or low based on the spread or total area of a equally probable region of the heatmap. If a narrowly focused area region of equal probability is seen at a specific age for a given metrics, high confidence in the Age metric can be confirmed. If a broadly focused area region of equal probability is seen at a specific age for a given metrics, lower confidence in the Age metric derived from the other measured metrics can be asserted. As an example, if a Skewness metric of 0.21 of a device has been found to result in only a RUL of 2000-3000 hours, then confidence in RUL estimate based on the Skewness measurement of 0.21 is higher than if the Skewness measurement was found to result in RULs ranging from 100 hours to 4000 hours. This may be immediately determined visually by inspecting a heatmap displaying the related data in graphical form.

The Subject Matter may be used to determine if a device has a sufficient RUL to justify reuse or continued use of the device. The Subject Matter may be used to determine if a device has measurements typically associated with a new, unused device. The Subject Matter may be used to determine if an aircraft device or sub-assembly has a sufficient RUL to justify reuse or continued use of the device. The Subject Matter may be used to determine if an aircraft device or sub-assembly has a sufficient RUL to justify reuse or continued use of the device while performing the RF emission measurements in-situ.

Metrics used to populate a RUL-related database or matrix 2100, Database 980, New or Recent Data 940, or Historical Matrix 990 may also include:
narrowband frequency regions locations where feature detail metrics are observed (Ex. 610.001000 MHz to 610.003000 MHz) and/or RBWs used (cx. 0.2 Hz RBW)
equipment serial number from which device was used (ex. PLC #AB-2034)
equipment serial number from which data was gathered (Ex. ADEC Unit #5013)
equipment history of where device was used (ex. DEVICE XX-1013 WAS USED IN PLC #AB-2304 located at address and/or GPS coordinates between dates specified therein and under conditions such as temperature, humidity, device operation time levels, current levels, factory throughput levels, etc.)
Metrics ranges for metrics indices (ex. Index #1 of a peak location at narrowband region frequencies between 610.001514 MHz and 610.001524 MHz taken at 0.1 Hz RBW is a sub-region location between 610.001514 MHz and 610.001515 MHz, Index #2 is a sub-region location between 610.001515 MHz and 610.001516 MHz, Index #3 is a wider sub-region location between 610.001516 MHz and 610.001518 MHz, etc.)
Neural Network Node parameters used to create coefficients for metric ranges or metrics combining equations used to generate a RUL estimate (ex. Euclidean Distance coefficients to quantify certainty of a RUL instead of or in addition to Mahalanobis Distance)
Bessel function parameters related to Non-Linear Product (NLP) mixing
Harmonic frequency sequence locations found by Harmonic Extraction algorithm
Consistent Time correlation of changes in metrics illustrated herein vs. time
Bayesian Convolutional Neural Networks Node Weight parameters and Meta parameters

### OBJECTS OF EMBODIMENTS

It is an object to perform sequential captures of RF emissions data wherein the captures are performed at substantially different times and at least one of the time of the capture or the duration between captures is recorded or derived

It is an object to age an electrical device prior to capturing RF unintended emission data.

It is an object to accelerate aging of an electrical device prior to capturing the RF unintended emission data.

It is an object to age an electrical device until or beyond a failure condition.

It is an object to record a failure time or an operating duration of an electrical device.

It is an object to determine allocation of replacement electrical devices wherein the determination informs the placement or swapping of more aged replacements in systems with correspondingly older existing electrical devices and/or newer replacements in systems with correspondingly newer existing electrical devices.

It is an object to determine an economic value of a device based on its RUL.

It is an object to determine an economic value recommendation based on optimizing potential swapping candidates' combination of the systems.

It is an object to determine an economic value recommendation based on optimizing potential swapping candidates' combination of the systems wherein assessments of the costs associated with procuring, preparing, examining, and swapping are considered in determining said economic value recommendations.

It is an object to calculate probabilities associated with assessments which are then used to offer a set of possible recommended maintenance actions combination groupings.

It is an object to determine device metrics to be aggregated to determine the remaining useful life of the electrical device or used to detect cybersecurity threats.

It is an object to capture RF emissions data wherein the data comprises captured multiple device's data of the same type, same device number, or same product number.

It is an object to determine at least one metric or to determine at least one statistic associated with a device number.

It is an object to determine at least one of a degree of degradation, a degree of estimated prior usage, or a degree of age associated with a device with a known device number.

It is an object to store data and/or metrics associated with a device number wherein multiple devices data and/or metrics are combined or aggregated.

It is an object to combine or aggregate data from a populated multi-variate sparse Matrix to create a heatmap.

It is an object to populate a multi-variate sparse Matrix with data related to device metrics derived from unintended RF emissions spectra.

It is an object to populate a multi-variate sparse Matrix with data related to device metrics by incrementing elements of said Matrix at specific coordinate locations based on Matrix dimension index numbers based on measured RF emissions metrics.

It is an object to calculate probabilities of a populated multi-variate sparse Matrix based on data related to device metrics derived from unintended RF emissions spectra contained therein.

It is an object to calculate probabilities of a RUL of a new pat sample based on data related to device metrics derived from unintended RF emissions spectra contained therein.

It is an object to determine Matrix dimension index numbers based on measured RF emissions metrics.

It is an object to determine Matrix dimension index numbers based on measured RF emissions metrics using a linear or non-linear calculation.

It is an object to determine Matrix dimension index numbers based on measured RF emissions metrics using judgement.

It is an object to determine Matrix dimension index numbers based on measured RF emissions metrics using a neural-net.

It is an object to be used to select devices within a batch of devices are likely to have a longer RUL.

It is an object to determine which devices found are likely to have a longer RUL and set aside for inclusion into high-value systems in which RUL is important or critical.

It is an object of the Subject Matter to find devices likely to have a longer RUL to be valued and/or sold at a higher economic value.

It is an object to identify a bad device within a board, assembly, unit, sub-system, or device.

It is an object to monitor or detect a change from a known state of a device, board, sub-system, or system.

It is an object to monitor or detect anomalies in a device, board, sub-system, or system.

It is an object to monitor or detect intrusion into a device, board, sub-system, or system.

It is an object to monitor or detect a change in operation of a device, board, sub-system, or system.

It is an object to monitor or detect a change in intended operation of a device, board, sub-system, or system.

It is an object to provide a system, comprising:
one or more processors; and
a non-transitory machine-readable storage medium including instructions that, when executed by the one or more processors, configure the system to at least:
   measure unintended RF emissions data from a device;
   determine characteristic features within a spectrum of said data;
   age said device while operating the device under load;
   select characteristic features within a spectrum of said data which seem to change with device age;
   determine a plurality of metrics of spectrum data features associated with device age;
   determine a range of indices associated with the observed metrics of spectrum data features associated with device age;
   create a multi-dimensional matrix to store counts of occurrences of metrics within index ranges associated with indexed locations inside said matrix;
   populate said matrix with a plurality of devices' RF emission metrics;
   process an additional device of unknown age by using matrix to determine additional device's probable age;
   display said device's resulting age and or probable ages based on process performed; and
   make a decision based on age probability result.

It is an object to provide a receiver, comprising:
one or more processors;
a device under test; and
a non-transitory machine-readable storage medium including instructions that, when executed by the one or more processors, configure the system to at least:
display said device's resulting age and or probable ages; and
make a decision based on age probability result.

It is an object to provide a receiver, comprising:
an antenna;
a clock;
an analog-to-digital converter;
a device under test;
a fourier transform generating spectrum measurements;
a table of data;
wherein said table of data contains selected spectrum measurements of unintended rf emissions found to have been associated with the duration of operation of said device.

It is an object to provide a non-transitory machine-readable medium including instructions that when executed by one or more processors of a machine, cause the machine to perform operations comprising:
acquiring broadband data from a device's unintended RF emissions in a frequency region;
acquiring narrowband data from a device's unintended RF emissions within a sub-section of the previously acquired broadband data frequency region;
extract spectral measurement metrics from the narrowband data; and
populate a database with said spectral measurement metrics of the device.

It is an object to provide a method, at least including steps of:
capturing, with a broadband radio frequency (RF) receiver, a bandwidth of an RF unintended emission data from an electrical device under power;
metricizing the RF unintended emission data;
calculating metrics from metricized data; and filling a multivariate matrix with calculated metrics.

It is an object to provide a method aggregating calculated metrics to determine aging of the electrical device.

It is an object to provide a method step of aggregating calculated metrics to determine an operational health of the electrical device.

It is an object to provide a method step of aggregating calculated metrics to determine a degree of degradation of the electrical device.

It is an object to provide a method step of aggregating calculated metrics to determine a safety margin of the electrical device.

It is an object to provide a method step of aggregating calculated metrics to determine a maintenance scheduling of the electrical device.

It is an object to provide a method step of aggregating calculated metrics to determine a replacement action of the electrical device.

It is an object to provide a method step of aggregating calculated metrics to determine an economic value for the electrical device.

It is an object to provide a method step, wherein the metrics are combined to determine at least one of a most optimal system and a most suitable system to receive a replacement electrical device to match an overall age of other electrical devices in a system.

It is an object to provide a method step, wherein a broadband capture is followed by one or more narrowband captures of one or more frequency regions within a large bandwidth of RF unintended emissions data previously captured from the electrical device under operation.

It is an object to provide a method step, wherein a narrowband capture of a frequency region is performed at differing Resolution Bandwidth than the broadband capture.

It is an object to provide a method step, wherein a narrowband capture of a frequency region is performed at a lower Resolution Bandwidth than the broadband capture.

It is an object to provide a method step, wherein two or more narrowband captures are acquired for a same frequency region.

It is an object to provide a method step, wherein the two or more narrowband captures are acquired at least one of sequentially, concurrently, and simultaneously.

It is an object to provide a method step, wherein two or more narrowband captures of a same frequency region are averaged together in a frequency domain.

It is an object to provide a method step of aggregating calculated metrics to determine at least one of a generation of anomalies of an electrical device, a change in intended operation of the electrical device, a change in state of electronics of the electrical device, a change in health of the electrical device, a cyber-attack on the electrical device, a continued cyber-security of the electrical device, a possible compromise of cyber-security of a device, and a presence of a cyber-intrusion into the electrical device.

It is an object to provide a method step of aggregating calculated metrics to assess the electrical device, electrical devices, boards, assemblies, sub-systems, and/or system while separate or as an electrical device of a larger system while normally operating or not operational in normal use.

It is the intent to cover all such modifications and alternative embodiments as may come within the true scope of this Subject matter, which is to be given the full breadth thereof. Additionally, the disclosure of a range of values is the disclosure of every numerical value within that range, including the end points. Thus, while certain exemplary embodiments of the device and methods of making and using the same have been discussed and illustrated herein, it is to be distinctly understood that the Subject matter is not limited thereto but may be otherwise variously embodied and practiced within the scope of the following claims.

This disclosure specifically describes a method to extract large swaths of signature data and metricize the data in a manner useful to determining device RUL and/or degradation. The method may use unintended signature data from the electrical device.

The chosen embodiments of the subject matter have been described and illustrated, to plan and/or cross section illustrations that are schematic illustrations of idealized embodiments, for practical purposes so as to enable any person skilled in the art to which it pertains to make and use the same. As such, variations from the shapes of the illustrations as a result, for example, of manufacturing techniques and/or tolerances, are to be expected. It is therefore intended that all matters in the foregoing description and shown in the accompanying drawings be interpreted as illustrative and not in a limiting sense. For example, a region illustrated or described as flat may, typically, have rough and/or nonlinear features. Moreover, sharp angles that are illustrated may be rounded and rounded angles may be sharp. Thus, the regions illustrated in the figures are schematic in nature and their shapes are not intended to illustrate the precise shape of a region and are not intended to limit the scope of the present claims. It will be understood that variations, modifications, equivalents and substitutions for components of the specifically described embodiments may be made by those skilled in the art without departing from the spirit and scope of the invention as set forth in the appended claims.

Unless otherwise indicated, all numbers expressing quantities of elements, optical characteristic properties, and so forth used in the specification and claims are to be understood as being modified in all instances by the term “about.” The term “about” may be associated with a numerical value to indicate a margin of +/−20% of the value. Accordingly, unless indicated to the contrary, the numerical parameters set forth in the preceding specification and attached claims are approximations that can vary depending upon the desired properties sought to be obtained by those skilled in the art utilizing the teachings of the present subject matter. At the very least, and not as an attempt to limit the application of the doctrine of equivalents to the scope of the claims, each numerical parameter should at least be construed in light of the number of reported significant digits and by applying ordinary rounding techniques. Notwithstanding that the numerical ranges and parameters setting forth the broad scope of the claimed subject matter are approximations, the numerical values set forth in the specific examples are reported as precisely as possible.

Any numerical value, however, inherently contains certain errors necessarily resulting from the standard deviations found in their respective testing measurements.

To the extent that the appended claims have been drafted without multiple dependencies, this has been done only to accommodate formal requirements in jurisdictions which do not allow such multiple dependencies or require extra claim fees for such multiple dependencies. It should be noted that all possible combinations of features which would be implied by rendering the claims multiply dependent are explicitly envisaged and should be considered part of the invention.

Anywhere the term “comprising” is used, embodiments and components “consisting essentially of” and “consisting of” are expressly disclosed and described herein.”

Any element in a claim that does not explicitly state “means for” performing a specified function, or “step for” performing a specified function, is not to be interpreted as a “means” or “step” clause as specified in 35 U.S.C. § 112, ¶ 6. In particular, any use of “step of” in the claims is not intended to invoke the provision of 35 U.S.C. § 112, ¶ 6.

The Abstract is not intended to be limiting as to the scope of the claimed subject matter and is for the purpose of quickly determining the nature of the claimed subject matter.

What is claimed is:

1. A method, comprising:
analyzing an emission of electromagnetic energy in a radio frequency (RF) spectrum from an electrical device, the electrical device being powered, with at least one of a harmonic extraction, a non-linear product analysis, a time correlation, a signature energy distribution, a curve fit and a non-harmonic correlation; and
determining, based on an analysis of the emission, at least one of a degree of degradation of an electrical device and a remaining useful life of the electrical device.

2. The method of claim 1, wherein analyzing with the harmonic extraction comprises utilizing at least one of determining at least one harmonic series of the emission and at least one envelope of harmonic series.

3. The method of claim 1, wherein analyzing with the non-linear product analysis comprises determining whether a non-linear product is at least one of an amplitude modulated type, a frequency modulated type and a different modulation type.

4. The method of claim 1, wherein determining the at least one of a degree of degradation of an electrical device and the remaining useful life of the electrical device comprises populating at least a two-dimensional matrix with values of at least one signature parameter of the emission.

5. A method, comprising steps of:
capturing, with a radio frequency (RF) receiver, a frequency bandwidth of an RF unintended emission data from an electrical device under power;
calculating at least one emission signature parameter within the RF unintended emission data;
associating a condition of the electrical device with the at least one emission signature parameter; and
filling a matrix with calculated at least one emission signature parameter and an associated condition.

6. The method of claim 5, further comprising:
capturing unintended emission data from a plurality of electrical devices of an identical design type;
calculating at least one emission signature parameter for each electrical device from the plurality of electrical devices;
associating a condition of each electrical device with a corresponding at least one emission signature parameter; and
filling a matrix with calculated emission signature parameters and associated conditions.

7. The method of claim 6, further comprising determining a probability distribution of an associated condition in a relationship to the at least one emission signature parameter.

8. The method of claim 6, further comprising:
capturing unintended emission data from another electrical device of a same design as a design of the electrical device;
calculating the at least one emission signature parameter for another electrical device; and
determining, based on a filled matrix, a condition of the another electrical device.

9. The method of claim 5, further comprising:
capturing unintended emission data from another electrical device of a same design as a design of the electrical device;
calculating the at least one emission signature parameter for another electrical device; and
determining, based on a value of the at least one emission signature parameter in a filled matrix, an associated aging condition of the another electrical device.

10. The method of claim 5, further comprising:
capturing unintended emission data from another electrical device of a same design as a design of the electrical device;
calculating the at least one emission signature parameter for another electrical device; and
determining, based on a value of the at least one emission signature parameter in a filled matrix, an associated degraded condition of the another electrical device.

11. The method of claim 5, further comprising:
capturing unintended emission data from another electrical device of a same design as a design of the electrical device;
calculating the at least one emission signature parameter for another electrical device; and
determining, based on a value of the at least one emission signature parameter in a filled matrix, an associated remaining useful life (RUL) condition of the another electrical device.

12. The method of claim 5, further comprising:
capturing unintended emission data from another electrical device of a same design as a design of the electrical device;
calculating the at least one emission signature parameter for another electrical device; and
determining, based on a value of the at least one emission signature parameter in a filled matrix, an associated operational health condition of the another electrical device.

13. The method of claim 5, further comprising capturing the RF unintended emission data within at least one region of the frequency bandwidth.

14. The method of claim 13, wherein capturing the RF unintended emission data within at least one region of the frequency bandwidth comprises capturing the RF unintended emission data within the at least one region of the frequency bandwidth at a different resolution than a resolution of the RF unintended emission data captured within the frequency bandwidth.

15. The method of claim 13, wherein capturing the RF unintended emission data within at least one region of the frequency bandwidth comprises capturing the RF unintended emission data within the at least one region of the frequency bandwidth in a response to determining the at least one emission signature parameter within the frequency bandwidth.

16. The method of claim 15, further comprising calculating the at least one emission signature parameter within the at least one region.

17. The method of claim 5, further comprising aggregating calculated metrics to determine at least one of a generation of anomalies of an electrical device, a change in intended operation of the electrical device, a change in state of electronics of the electrical device, a change in health of the electrical device, a cyber-attack on the electrical device, a continued cyber-security of the electrical device, a possible compromise of cyber-security of a device, and a presence of a cyber-intrusion into the electrical device.

18. The method of claim 5, further comprising aggregating calculated metrics to assess the electrical device, electrical devices, boards, assemblies, sub-systems, and/or system while separate or as an electrical device of a larger system while normally operating or not operational in normal use.

19. The method of claim 5, wherein the RF receiver at least comprises an antenna.
